(19) United States
(12) Patent Application Publication
(10) Pub. No.: US 2026/0030242 A1
(43) Pub. Date: Jan. 29, 2026

(54) PARALLELIZED DATA INPUT SUB-SYSTEM OF A DATABASE SYSTEM

(71) Applicant: Ocient Inc., Chicago, IL (US)

(72) Inventors: Jason Arnold, Chicago, IL (US); George Kondiles, Highland Park, IL (US)

(73) Assignee: Ocient Inc., Chicago, IL (US)

(21) Appl. No.: 19/349,172

(22) Filed: Oct. 3, 2025

Related U.S. Application Data
(63) Continuation-in-part of application No. 18/648,342, filed on Apr. 27, 2024.
Application No. 18/648,342 is a continuation of application No. 16/267,608, filed on Feb. 5, 2019, now Pat. No. 11,977,545.
(60) Provisional application No. 62/745,787, filed on Oct. 15, 2018.

(51) Int. Cl. G06F 16/2453; G06F 3/06; G06F 7/24; G06F 9/4401; G06F 9/50; G06F 11/10; G06F 12/0893; G06F 12/109; G06F 16/17; G06F 16/22; G06F 16/23; G06F 16/242; G06F 16/2455; G06F 16/2457; G06F 16/2458; G06F 16/27; G06F 16/901; H03M 7/30; H04L 67/10

(52) U.S. Cl. CPC G06F 16/24542; G06F 3/0604; G06F 3/0647; G06F 3/068; G06F 7/24; G06F 9/4406; G06F 9/5016; G06F 9/5027; G06F 9/5061; G06F 11/1004; G06F 11/1044; G06F 11/1076; G06F 12/0893; G06F 12/109; G06F 16/1727; G06F 16/22; G06F 16/2246; G06F 16/2282; G06F 16/2365; G06F 16/244; G06F 16/2445; G06F 16/2453; G06F 16/24553; G06F 16/24573; G06F 16/2458; G06F 16/278; G06F 16/901; G06F 16/9017; H03M 7/30; H04L 67/10; G06F 3/067; G06F 16/24547; G06F 2211/1011; G06F 2212/608

(57) ABSTRACT

A parallelized data input sub-system of a database system includes a first set of loader nodes of pluralities of computing nodes of a plurality of computing device clusters. The first set of loader nodes includes a plurality of memory devices and a plurality of processing modules. The first set of loader node is operable to ingest at least a portion of a dataset (“data”), a set of the memory devices stores the data, and a set of the processing modules determines whether the data is regarding a query. When it is regarding the query, the set of processing modules provides the data to a query and response sub-system. When it is not regarding the query, the set of processing modules determines long term storage parameters, processes the data in accordance with the parameters to produce formatted data, and provides the formatted data to a store and compute sub-system.

### CROSS-REFERENCE TO RELATED APPLICATIONS

The present U.S. Utility Patent Application claims priority pursuant to 35 U.S.C. § 120 as a continuation-in-part of U.S. Utility application Ser. No. 18/648,342, entitled “DISTRIBUTED DATABASE SYSTEM,” filed Apr. 27, 2024, which claims priority pursuant to 35 U.S.C. § 120 as a continuation of U.S. Utility application Ser. No. 16/267,608, entitled “GENERATION OF AN OPTIMIZED QUERY PLAN IN A DATABASE SYSTEM,” filed Feb. 5, 2019, issued as U.S. Pat. No. 11,977,545 on May 7, 2024, which claims priority pursuant to 35 U.S.C. § 119(e) to U.S. Provisional Application No. 62/745,787, entitled “DATABASE SYSTEM AND OPERATION,” filed Oct. 15, 2018, all of which are hereby incorporated herein by reference in their entirety and made part of the present U.S. Utility Patent Application for all purposes.

### STATEMENT REGARDING FEDERALLY SPONSORED RESEARCH OR DEVELOPMENT

Not Applicable.

### INCORPORATION-BY-REFERENCE OF MATERIAL SUBMITTED ON A COMPACT DISC

Not Applicable.

### BACKGROUND OF INVENTION

### Technical Field of Invention

The disclosed subject matter relates to computer networking and more particularly to database system and operation.

### Description of Related Art

Computing devices are known to communicate data, process data, and/or store data. Such computing devices range from wireless smart phones, laptops, tablets, personal computers (PC), workstations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function.

Of the many applications a computer can perform, a database system is one of the largest and most complex applications. In general, a database system stores a large amount of data in a particular way for subsequent processing. In some situations, the hardware of the computer is a limiting factor regarding the speed at which a database system can process a particular function. In some other instances, the way in which the data is stored is a limiting factor regarding the speed of execution. In yet some other instances, restricted co-process options are a limiting factor regarding the speed of execution.

### BRIEF DESCRIPTION OF THE SEVERAL VIEWS OF THE DRAWING(S)

FIG. 1 is a schematic block diagram of an embodiment of a large scale data processing network that includes a database system:

FIG. 1A is a schematic block diagram of an embodiment of a database system;

FIG. 2 is a schematic block diagram of an embodiment of an administrative sub-system;

FIG. 3 is a schematic block diagram of an embodiment of a configuration sub-system;

FIG. 4 is a schematic block diagram of an embodiment of a parallelized data input sub-system;

FIG. 5 is a schematic block diagram of an embodiment of a parallelized query and response (Q&R) sub-system;

FIG. 6 is a schematic block diagram of an embodiment of a parallelized data store, retrieve, and/or process (IO& P) sub-system;

FIGS. 7A-7D are schematic block diagrams of various embodiments of a computing entity;

FIG. 7E is a schematic block diagram of an embodiment of a computing device;

FIG. 8 is a schematic block diagram of another embodiment of a computing device;

FIG. 9 is a schematic block diagram of another embodiment of a computing device;

FIGS. 9A-9G are schematic block diagrams of various embodiments of a computing device;

FIG. 10 is a schematic block diagram of an embodiment of a node of a computing device;

FIG. 11 is a schematic block diagram of an embodiment of a node of a computing device;

FIG. 12 is a schematic block diagram of an embodiment of a node of a computing device;

FIG. 13 is a schematic block diagram of an embodiment of a node of a computing device;

FIG. 14 is a schematic block diagram of an embodiment of operating systems of a computing device;

FIG. 15 is a schematic block diagram of an embodiment of operating systems for a node of a computing device;

FIG. 16 is a schematic block diagram of an embodiment of operating systems of a sub-system of the database system;

FIG. 17 is a schematic block diagram of an embodiment of operating systems of the database system;

FIG. 18 is a schematic block diagram of an embodiment of a node of a computing device;

FIGS. 19A and 19B are a logic diagram of an example of processing a table or data set for storage in the database system;

FIGS. 20-29 are schematic block diagrams of an example of processing a table or data set for storage in the database system;

FIGS. 30-32 are schematic block diagrams of an example of storing a processed table or data set in the database system;

FIG. 33 is a logic diagram of an example of creating a query plan for execution within the database system;

FIG. 34 is a logic diagram of another example of creating a query plan for execution within the database system;

FIGS. 35-36 are schematic block diagrams of an example of creating and distributing a query plan in the database system;

FIG. 37 is a schematic block diagram of an example of encoding a code line of data;

FIG. 38 is a schematic block diagram of an example of encoded code lines with distributed positioning of parity blocks;

FIG. 39 is a schematic block diagram of an example of memory of a cluster of nodes and/or of computing devices having a data storage section and a parity storage section;

FIG. 40 is a schematic block diagram of an example of storing data blocks in a data storage section and parity blocks in a parity storage section, with empty spaces in the data storage section;

FIG. 41 is a schematic block diagram of an example of filling the empty spaces in the data storage section of FIG. 40;

FIG. 42 is a schematic block diagram of another example of filling the empty spaces in the data storage section of FIG. 40;

FIG. 43 is a schematic block diagram of another example of filling the empty spaces in the data storage section of FIG. 40;

FIG. 44 is a schematic block diagram of an example of direct memory access for a processing core resource and/or for a network connection;

FIG. 45 is a schematic block diagram of an example of data blocks and data messages for direct memory access of a processing core resource and/or of a network connection;

FIGS. 46-52 are schematic block diagrams of an example of processing a received data and distributed the processed table for storage in the database system;

FIGS. 53-54 are schematic block diagrams of an example of processing a received data and distributed the processed table for storage in the database system when a computing device in a storage cluster is unavailable;

FIG. 55 is a schematic block diagram of an example of memory device (MD) buffer queues being allocated to memory devices of processing core resources of a node of a computing device in accordance with the present invention;

FIG. 56 is a schematic block diagram of an example of a read operation to read data from memory space of a non-volatile memory device into an allocated buffer of main memory;

FIG. 57 is a schematic block diagram of another example of a read operation to read data from memory space of a non-volatile memory device into an allocated buffer of main memory based on logical block addresses (LBA);

FIG. 58 is a logic diagram of another example of a method for a read operation to read data from memory space of a non-volatile memory device into an allocated buffer of main memory based on logical block addresses (LBA);

FIG. 59 is a schematic block diagram of an example of allocated memory of main memory being allocated to read data from processing core resources;

FIG. 60 is a schematic block diagram of an example of allocated memory of main memory for manifest data and/or index data of a segment associated with a processing core resource;

FIG. 61 is a schematic block diagram of an example of a partition allocator allocating partitions of the allocated memory of main memory to requesting operations;

FIG. 62 is a logic diagram of an example of a method of allocating partitions of the allocated memory of main memory to requesting operations;

FIG. 63 is a schematic block diagram of another example of a partition allocator allocating partitions of the allocated memory of main memory to requesting operations;

FIG. 64 is a schematic block diagram of an example of compressing data;

FIG. 65 is a schematic block diagram of an example of compressing data;

FIG. 66 is a schematic block diagram of an example of compressing data using null elimination; and

FIG. 67 is a schematic block diagram of another example of compressing data using null elimination.

### DETAILED DESCRIPTION OF INVENTION

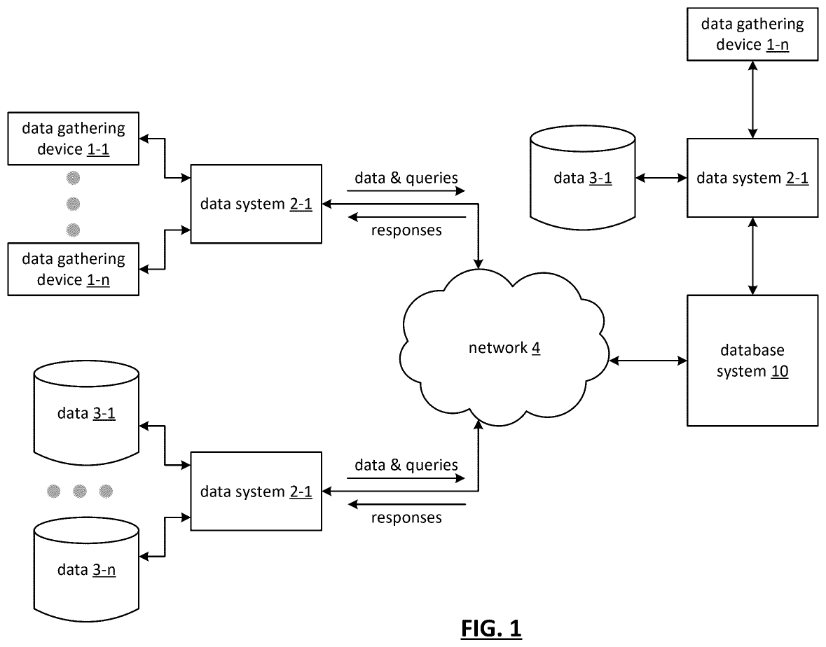

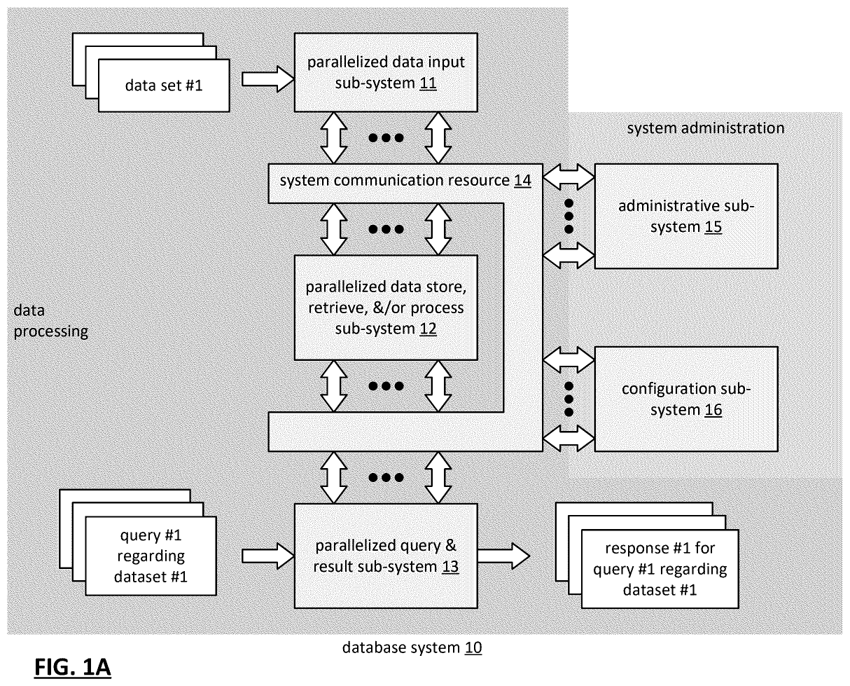

FIG. 1 is a schematic block diagram of an embodiment of a large-scale data processing network that includes a database system. The network further includes a plurality of data systems that provide data and one or more queries to the database system 10. The data systems are coupled to or include a plurality of data gathering device (e.g., sensors, monitors, handheld computing devices, etc.) and/or a plurality of storage devices (e.g., hard drives, cloud storage, etc.).

FIG. 1A is a schematic block diagram of an embodiment of a database system 10 that includes a parallelized data input sub-system 11, a parallelized data store, retrieve, and/or process sub-system 12, a parallelized query and response sub-system 13, an administrative sub-system 14, a configuration sub-system 15, and a system communication resource 16. The system communication resources 16 include one or more of wide area network (WAN) connections, local area network (LAN) connections, wireless connections, wireless connections, etc. to couple the sub-systems 11-15 together. Each of the sub-systems 11-15 include a plurality of computing devices; an example of which is discussed with reference to one or more of FIGS. 3A-3C.

In an example of operation, the parallelized data input sub-system 11 receives tables of data from a data source. For example, a data source is one or more computers. As another example, a data source is a plurality of machines. As yet another example, a data source is a plurality of data mining algorithms operating on one or more computers. The data source organizes its data into a table that includes rows and columns. The columns represent fields of data for the rows. Each row corresponds to a record of data. For example, a table include payroll information for a company's employees. Each row is an employee's payroll record. The columns include data fields for employee name, address, department, annual salary, tax deduction information, direct deposit information, etc.

The parallelized data input sub-system 11 processes a table to determine how to store it. For example, the parallelized data input sub-system 11 divides the data into a plurality of data partitions. For each data partition, the parallelized data input sub-system 11 determines a number of data segments based on a desired encoding scheme. As a specific example, when a 4 of 5 encoding scheme is used (meaning any 4 of 5 encoded data elements can be used to recover the data), the parallelized data input sub-system 11 divides a data partition into 5 segments. The parallelized data input sub-system 11 then divides a data segment into data slabs. Using one or more of the columns as a key, or keys, the parallelized data input sub-system sorts the data slabs. The sorted data slabs are sent to the parallelized data store, retrieve, and/or process sub-system 12 for storage.

The parallelized query and response sub-system 13 (also referred to herein as parallelized query & result sub-system) receives queries regarding tables and processes the queries prior to sending them to the parallelized data store, retrieve, and/or process sub-system 12 for processing. For example, the parallelized query and response sub-system 13 receives a specific query regarding a specific table. The query is in a standard query format such as Open Database Connectivity (ODBC), Java Database Connectivity (JDBC), and/or SPARK. The query is assigned to a node within the sub-system 13 for subsequent processing. The assigned node identifies the relevant table, determines where and how it is stored, and determines available nodes within the parallelized data store, retrieve, and/or process sub-system 12 for processing the query.

In addition, the assigned node parses the query to create an abstract syntax tree. As a specific example, the assigned node converts an SQL (Standard Query Language) statement into a database instruction set. The assigned node then validates the abstract syntax tree. If not valid, the assigned node generates an SQL exception, determines an appropriate correction, and repeats. When the abstract syntax tree is validated, the assigned node then creates an annotated abstract syntax tree. The annotated abstract syntax tree includes the verified abstract syntax tree plus annotations regarding column names, data type(s), data aggregation or not, correlation or not, sub-query or not, and so on.

The assigned node then creates an initial query plan from the annotated abstract syntax tree. The assigned node optimizes the initial query plan using a cost analysis function (e.g., processing time, processing resources, etc.). Once the query plan is optimized, it is sent to the parallelized data store, retrieve, and/or process sub-system 12 for processing.

Within the parallelized data store, retrieve, and/or process sub-system 12, a computing device is designated as a primary device for the query plan and receives it. The primary device processes the query plan to identify nodes within the parallelized data store, retrieve, and/or process sub-system 12 for processing the query plan. The primary device then sends appropriate portions of the query plan to the identified nodes for execution. The primary device receives responses from the identified nodes and processes them in accordance with the query plan. The primary device provides the resulting response to the assigned node of the parallelized query and response sub-system 13. The assigned node determines whether further processing is needed on the resulting response (e.g., joining, filtering, etc.). If not, the assigned node outputs the resulting response as the response to the query. If, however, further processing is determined, the assigned node further processes the resulting response to produce the response to the query.

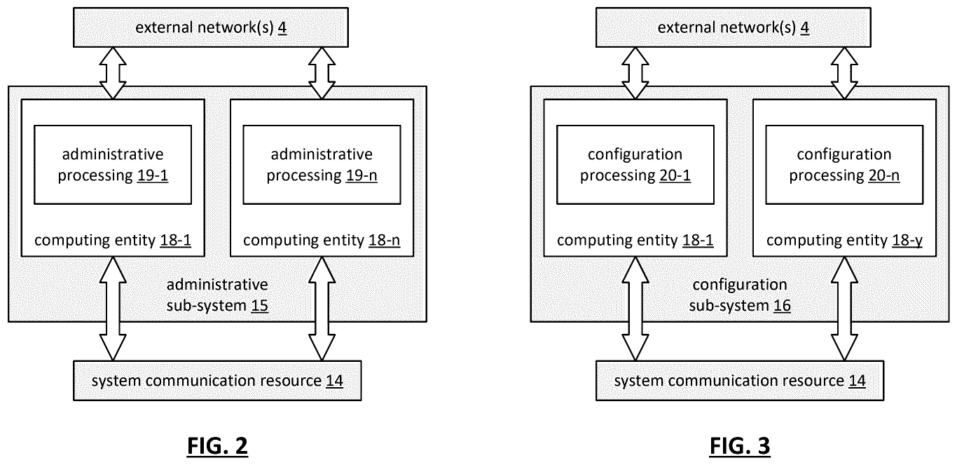

FIG. 2 is a schematic block diagram of an embodiment of an administrative sub-system that includes one or more computing devices. Each of the computing devices executes an administrative processing function (which includes a plurality of administrative operations) that coordinates system level operations of the database system. Each computing device is coupled to an external network, or networks, and to the system communication resources.

As will be described in greater detail with reference to one or more subsequent figures, a computing device includes a plurality of nodes and each node includes a plurality of processing core resources. Each processing core resource is capable of executing at least a portion of an administrative operation independently. This supports lock free and parallel execution of one or more administrative operations.

FIG. 3 is a schematic block diagram of an embodiment of a configuration sub-system that includes one or more computing devices. Each of the computing devices executes a configuration processing function (which includes a plurality of configuration operations) that coordinates system level configurations of the database system. Each computing device is coupled to an external network, or networks, and to the system communication resources.

As will be described in greater detail with reference to one or more subsequent figures, a computing device includes a plurality of nodes and each node includes a plurality of processing core resources. Each processing core resource is capable of executing at least a portion of a configuration operation independently. This supports lock free and parallel execution of one or more configuration operations.

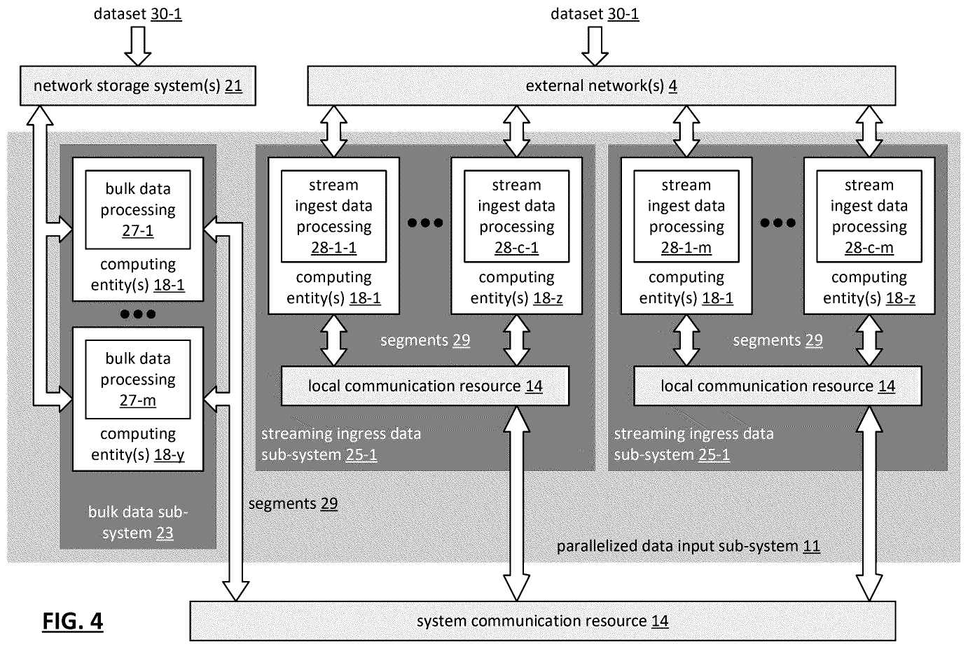

FIG. 4 is a schematic block diagram of an embodiment of a parallelized data input sub-system 11 that includes a bulk data sub-system 20 and a parallelized ingress sub-system 21. Each of the bulk data sub-system 20 and the parallelized ingress sub-system 21 includes a plurality of computing devices. The computing devices of the bulk data sub-system 20 execute a bulk data processing function to retrieve a table from a network storage system 23 (e.g., a server, a cloud storage service, etc.).

The parallelized ingress sub-system 21 includes a plurality of ingress data sub-systems that each include a plurality of computing devices. Each of the computing devices of the parallelized ingress sub-system 21 execute an ingress data processing function that enables the computing device to stream data of a table into the database system 10 from a wide area network 24. With a plurality of ingress data sub-systems, data from a plurality of tables can be streamed into the database system at one time.

Each of the bulk data processing function and the ingress data processing function generally function as described with reference to FIG. 1 for processing a table for storage. The bulk data processing function is geared towards retrieve data of a table in a bulk fashion (e.g., the table is stored and retrieved from storage). The ingress data processing function, however, is geared towards receiving streaming data from one or more data sources. For example, the ingress data processing function is geared towards receiving data from a plurality of machines in a factory in a periodic or continual manner as the machines create the data.

As will be described in greater detail with reference to one or more subsequent figures, a computing device includes a plurality of nodes and each node includes a plurality of processing core resources. Each processing core resource is capable of executing at least a portion of the bulk data processing function or the ingress data processing function. In an embodiment, a plurality of processing core resources of one or more nodes executes the bulk data processing function or the ingress data processing function to produce the storage format for the data of a table.

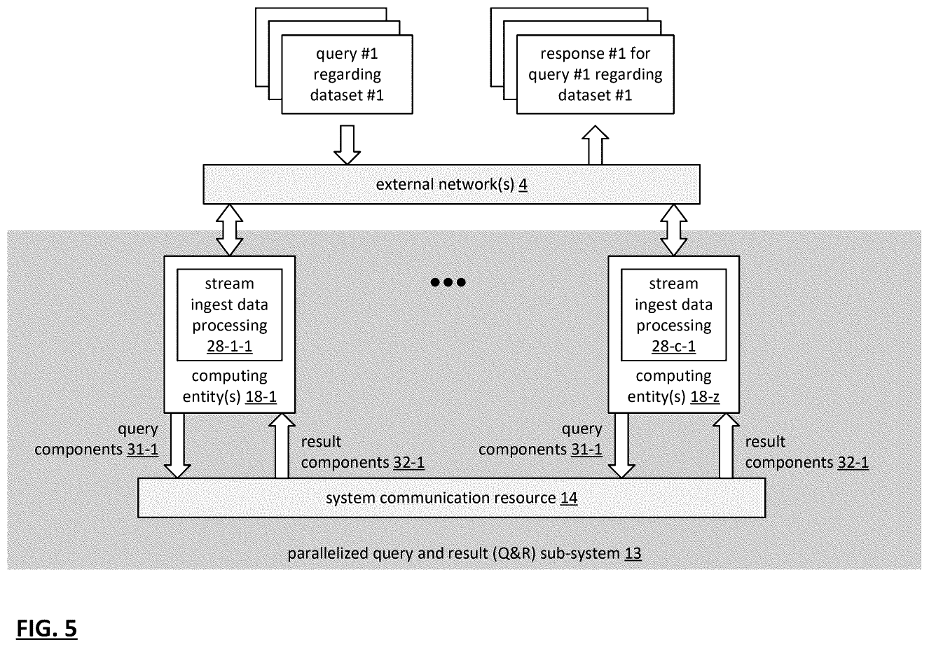

FIG. 5 is a schematic block diagram of an embodiment of a parallelized query and results sub-system 13 that includes a plurality of computing devices. Each of the computing devices executes a query (Q) & response (R) function. The computing devices are coupled to a wide area network 24 (e.g., cellular network, Internet, telephone network, etc.) to receive queries regarding tables and to provide responses to the queries.

The Q & R function enables the computing devices to process queries and create responses as discussed with reference to FIG. 1. As will be described in greater detail with reference to one or more subsequent figures, a computing device includes a plurality of nodes and each node includes a plurality of processing core resources. Each processing core resource is capable of executing at least a portion of the Q & R function. In an embodiment, a plurality of processing core resources of one or more nodes executes the Q & R function to produce a response to a query.

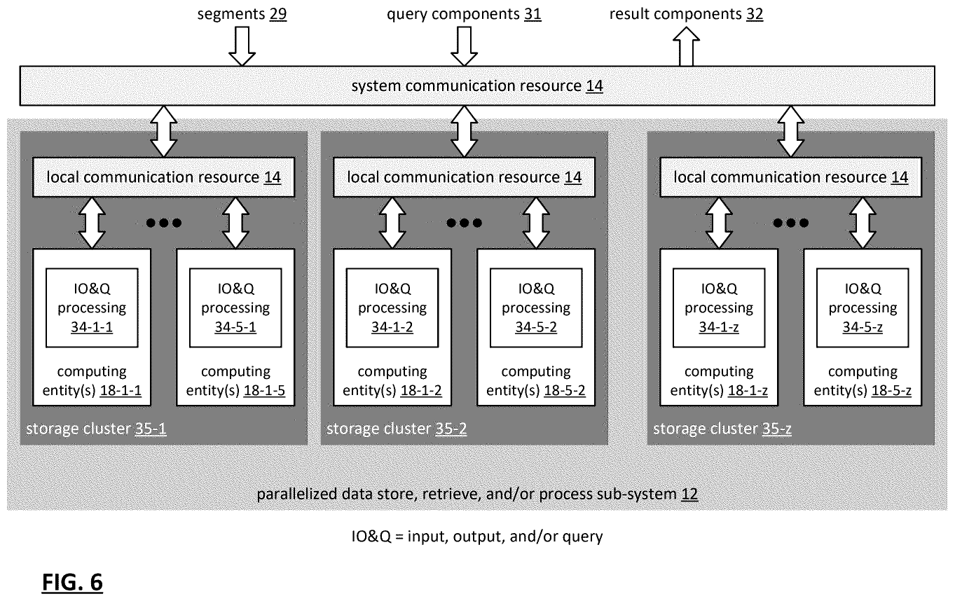

FIG. 6 is a schematic block diagram of an embodiment of a parallelized data store, retrieve, and/or process sub-system 12 that includes a plurality of storage clusters. Each storage cluster includes a plurality of computing devices and each computing device executes an input, output, and processing (IO &P) function to produce at least a portion of a resulting response. The number of computing devices in a cluster corresponds to the number of segments in which a data partitioned is divided. For example, if a data partition is divided into five segments, a storage cluster includes five computing devices. Each computing device then stores one of the segments.

As will be described in greater detail with reference to one or more subsequent figures, a computing device includes a plurality of nodes and each node includes a plurality of processing core resources. Each processing core resource is capable of executing at least a portion of the IO & P function. In an embodiment, a plurality of processing core resources of one or more nodes executes the IO & P function to produce at least a portion of the resulting response as discussed in FIG. 1.

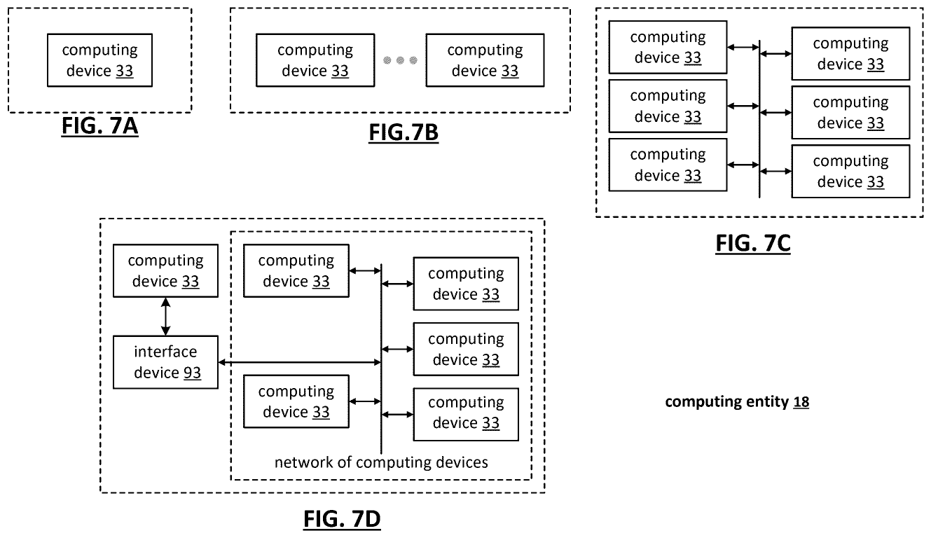

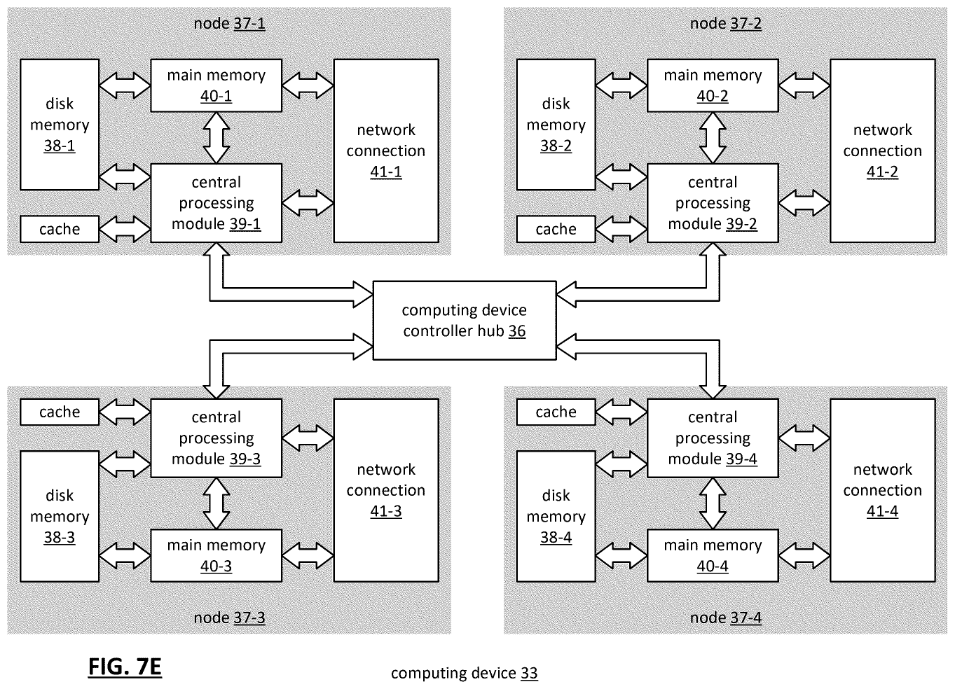

FIGS. 7A through 7D are schematic block diagrams of various embodiments of a computing entity 18. FIG. 7A is schematic block diagram of an embodiment of a computing entity 18 that includes a computing device 33 (e.g., one or more of the embodiments of FIGS. 7E-9G). A computing device may function as a user computing device, a server, a system computing device, a data storage device, a data security device, a networking device, a user access device, a cell phone, a tablet, a laptop, a printer, a game console, a satellite control box, a cable box, etc.

FIG. 7B is schematic block diagram of an embodiment of a computing entity 18 that includes two or more computing devices 33 (e.g., two or more from any combination of the embodiments of FIGS. 7E-9G). The computing devices 33 perform the functions of a computing entity in a peer processing manner (e.g., coordinate together to perform the functions), in a master-slave manner (e.g., one computing device coordinates and the other support it), and/or in another manner.

FIG. 7C is schematic block diagram of an embodiment of a computing entity 18 that includes a network of computing devices 33 (e.g., two or more from any combination of the embodiments of FIGS. 7E-9G). The computing devices are coupled together via one or more network connections (e.g., WAN, LAN, cellular data, WLAN, etc.) and perform the functions of the computing entity.

FIG. 7D is schematic block diagram of an embodiment of a computing entity 18 that includes a primary computing device (e.g., any one of the computing devices of FIGS. 7E-9G), an interface device 93 (e.g., a network connection), and a network of computing devices 33 (e.g., one or more from any combination of the embodiments of FIGS. 7E-9G). The primary computing device utilizes the other computing devices as co-processors to execute one or more the functions of the computing entity, as storage for data, for other data processing functions, and/or storage purposes.

FIG. 7E is a schematic block diagram of an embodiment of a computing device 33 that includes a plurality of nodes 37-1 through 37-4 coupled to a computing device controller hub 36. The computing device controller hub 36 includes one or more of a chipset, a quick path interconnect (QPI), and an ultra path interconnection (UPI). Each node 37-1 through 37-4 includes a central processing module 39-1 through 39-4, a main memory 40-1 through 40-4, a disk memory 38-1 through 38-4, and a network connection 41-1 through 41-4. In an alternate configuration, the nodes share a network connection, which is coupled to the computing device controller hub 36 or to one of the nodes.

In an embodiment, each node is capable of operating independently of the other nodes. This allows for large scale parallel operation of a query request, which significantly reduces processing time for such queries. In another embodiment, one or more node function as co-processors to share processing requirements of a particular function, or functions.

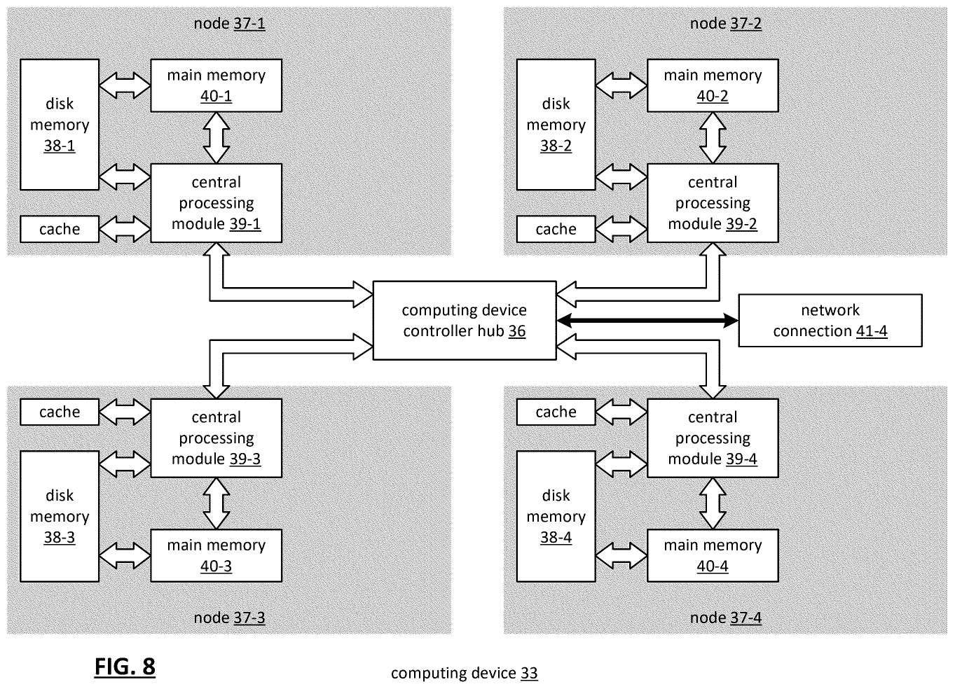

FIG. 8 is a schematic block diagram of another embodiment of a computing device 33 that is similar to the computing device of FIG. 7 with an exception that it includes a single network connection, which is coupled to the computing device controller hub. As such, each node coordinates with the computing device controller hub to transmit or receive data via the network connection.

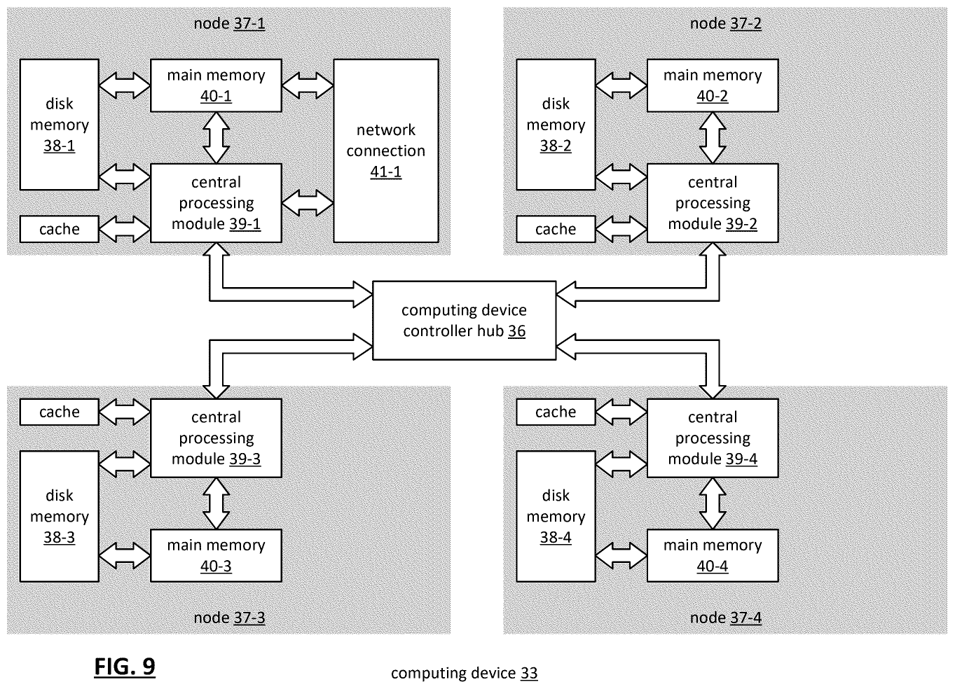

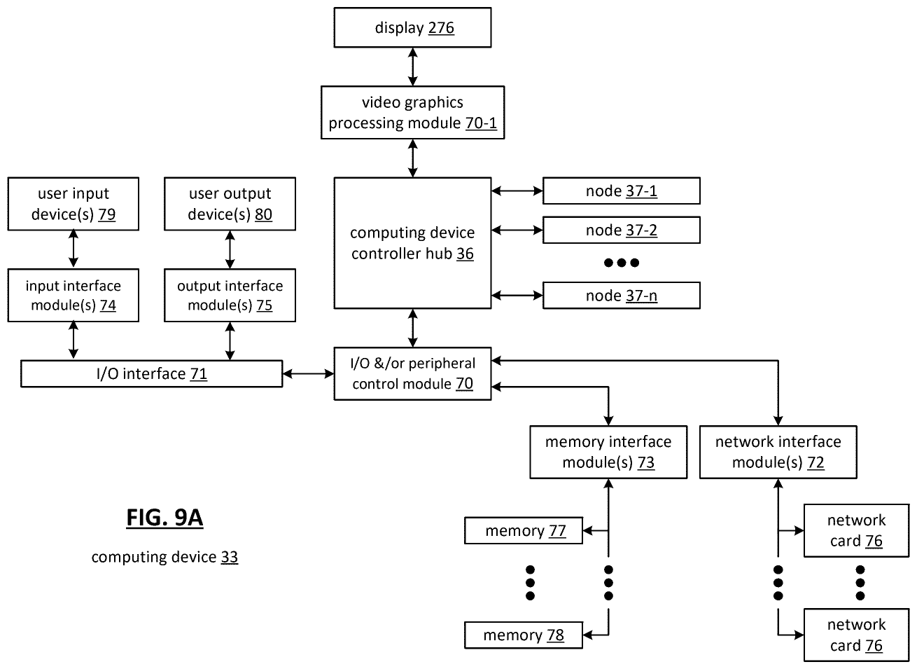

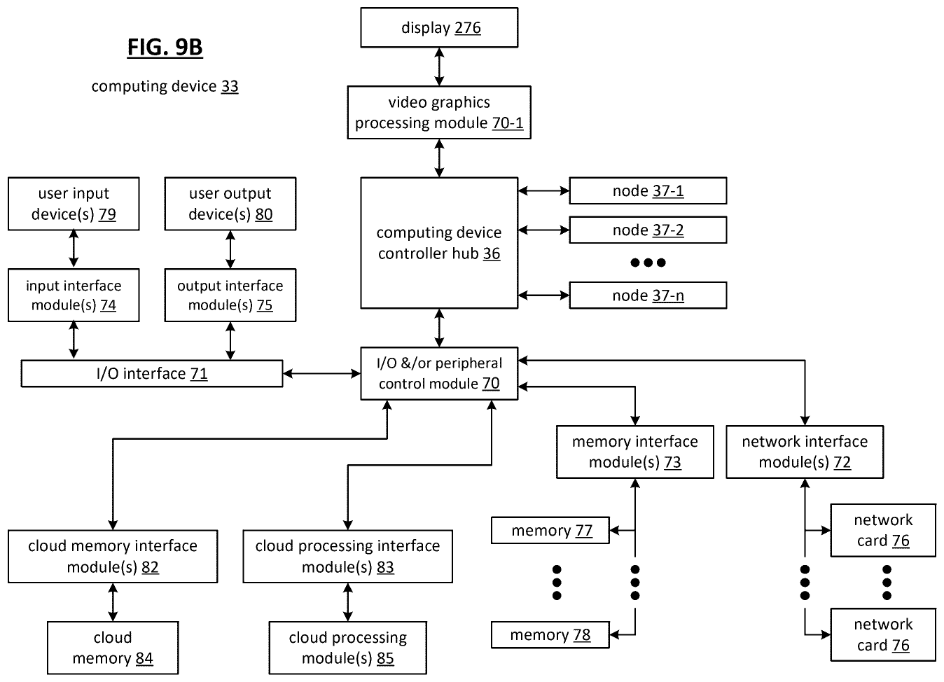

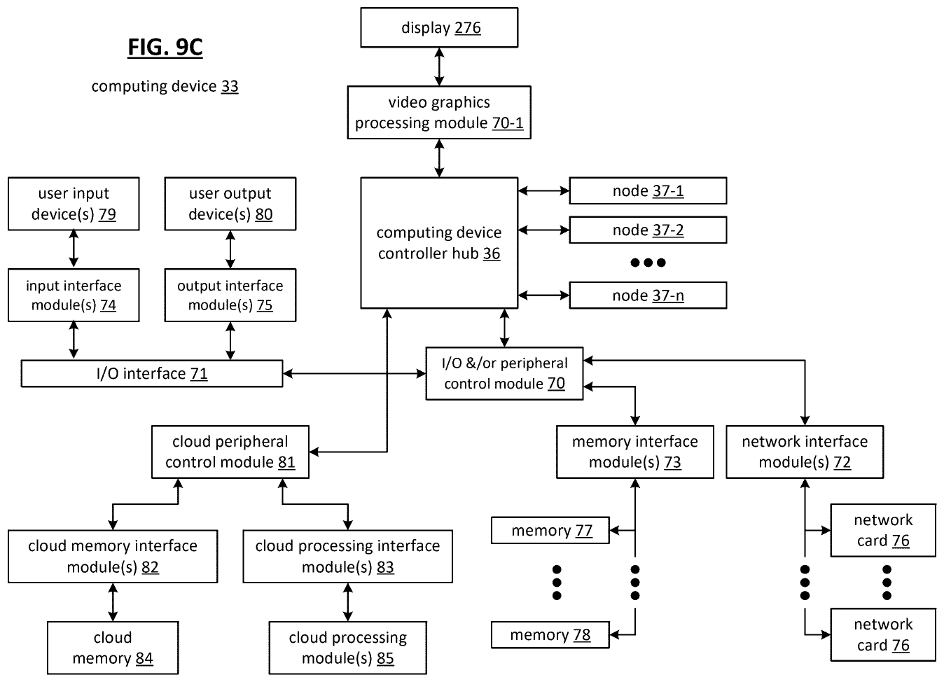

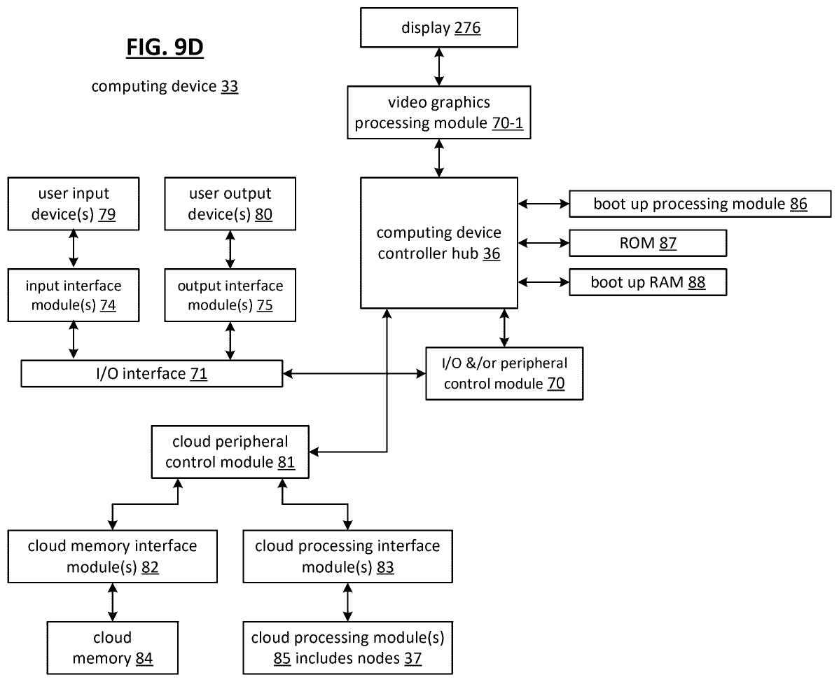

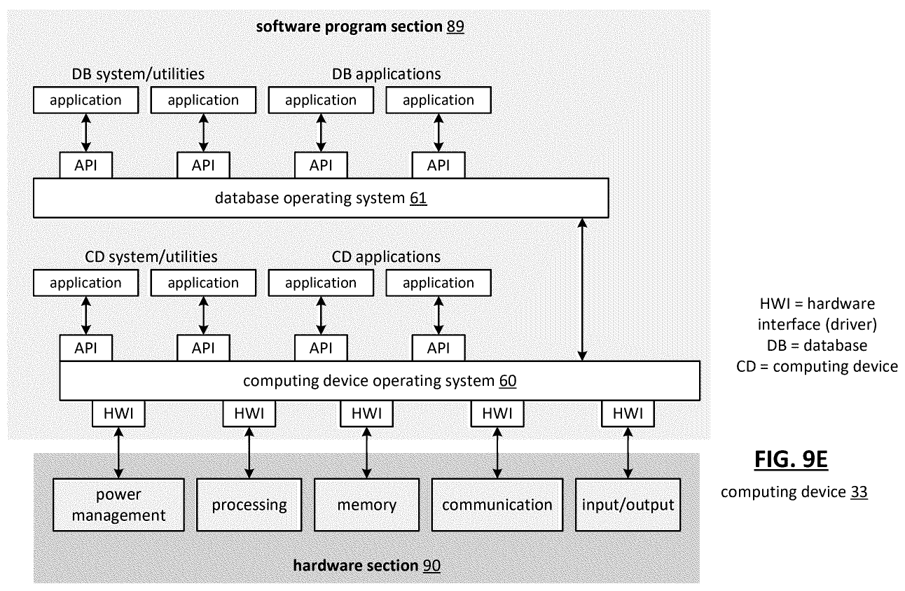

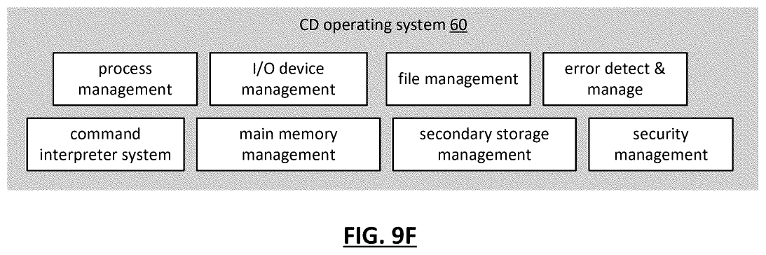

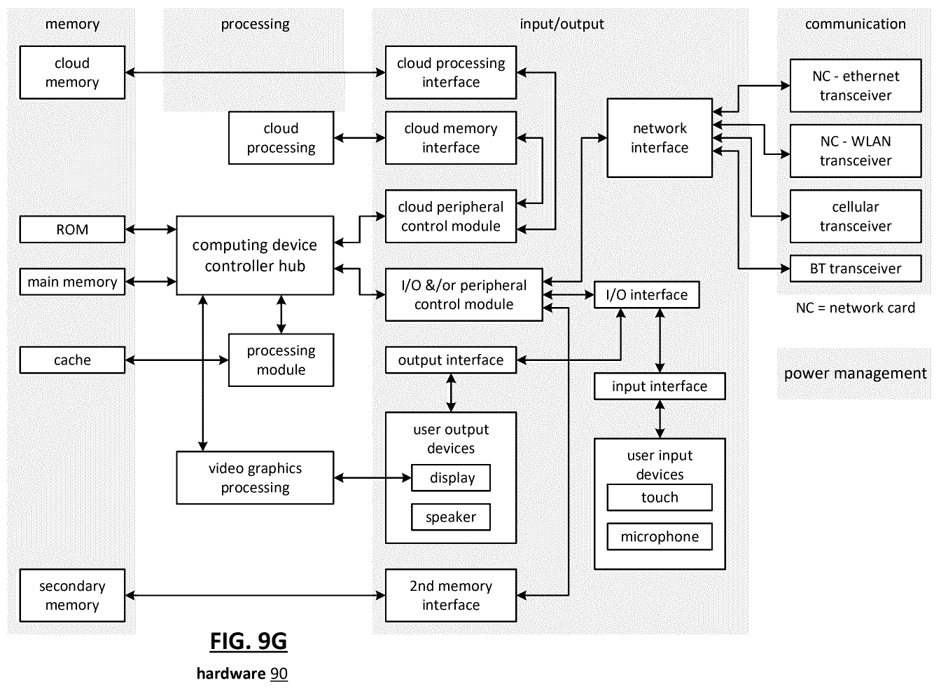

FIG. 9 is a schematic block diagram of another embodiment of a computing device 33 that is similar to the computing device of FIG. 7 with an exception that it includes a single network connection, which is coupled to a processing module of a node. As such, each node coordinates with the processing module via the computing device controller hub to transmit or receive data via the network connection.

FIGS. 9A-9G are schematic block diagrams of various embodiments of a computing device 33. FIG. 9A is a schematic block diagram of an embodiment of a computing device 33 that includes a plurality of computing resources. The computing resources, which form a computing core, include a computing device controller hub 36, a plurality of nodes 37-1 through 37-n, one or more video graphics processing modules 70-1, one or more displays 276 (optional), an Input-Output (I/O) peripheral control module 70, an I/O interface module 71 (which could be omitted if direct connect IO is implemented), one or more input interface modules 74, one or more output interface modules 75, one or more network interface modules 72, and one or more memory interface modules 73, one or more secondary memories 76-78, and one or more network cards 76.

A node of the plurality of nodes 37-1 through 37-n includes a plurality of processing core resources. Various embodiments of the plurality of nodes 37-1 through 37-n are discussed with reference to FIGS. 7E, 8, and 10-12. A processing core resource includes a main memory component (of a distributed main memory), a memory device (e.g., ROM, disk memory, etc.), a memory interface module, cache memory, and a processing module (e.g., a central processing module). Embodiments of processing core resources are discussed in more detail with reference to one or more of the subsequent figures.

A processing module is described in greater detail at the end of the detailed description section. In an alternate embodiment, the computing device controller hub 36 and the I/O and/or peripheral control module 70 are one module, such as a chipset, a quick path interconnect (QPI), and/or an ultra-path interconnect (UPI).

In this example, the nodes 37-1 through 37-n, computing device controller hub 36, and/or the video graphics processing module 70-1 form a processing core for a computing device. In other embodiments, the nodes include other components of the computing device. Computing resources 91 of FIGS. 9B-9G include one more of the components shown in this Figure and/or in or more of FIGS. 9B-9G.

The distributed main memory of the nodes 37-1 through 37-n includes one or more Random Access Memory (RAM) integrated circuits, or chips. In general, the main memory stores data and operational instructions most relevant for the nodes 37-1 through 37-n. For example, the computing device controller hub 36 coordinates the transfer of data and/or operational instructions between the main memory and the secondary memory device(s) 76-78. The data and/or operational instructions retrieve from secondary memory 76-78 are the data and/or operational instructions requested by the processing module or will most likely be needed by the processing module. When the processing module is done with the data and/or operational instructions in main memory, the computing device controller hub 36 coordinates sending updated data to the secondary memory 76-78 for storage.

The secondary memory 76-68 includes one or more hard drives, one or more solid state memory chips, and/or one or more other large capacity storage devices that, in comparison to cache memory and main memory devices, is/are relatively inexpensive with respect to cost per amount of data stored. The secondary memory 76-78 is coupled to the computing device controller hub 36 via the I/O and/or peripheral control module 70 and via one or more memory interface modules 73. In an embodiment, the I/O and/or peripheral control module 70 includes one or more Peripheral Component Interface (PCI) buses to which peripheral components connect to the computing device controller hub 36. A memory interface module 73 includes a software driver and a hardware connector for coupling a memory device to the I/O and/or peripheral control module 70. For example, a memory interface is in accordance with a Serial Advanced Technology Attachment (SATA) port.

The computing device controller hub 36 coordinates data communications between the nodes 37-1 through 37-n and network(s) via the I/O and/or peripheral control module 70, the network interface module(s) 72, and one or more network cards 76. A network card 76 includes a wireless communication unit or a wired communication unit. For example, a wireless communication unit includes a wireless local area network (WLAN) communication device, a cellular communication device, a Bluetooth device, and/or a ZigBee communication device. For example, a wired communication unit includes a Gigabit LAN connection, a Firewire connection, and/or a proprietary computer wired connection. A network interface module 76 includes a software driver and a hardware connector for coupling the network card to the I/O and/or peripheral control module 70. For example, the network interface module 72 is in accordance with one or more versions of IEEE 802.11, cellular telephone protocols, 10/100/1000 Gigabit LAN protocols, etc.

The computing device controller hub 36 coordinates data communications between the nodes 37-1 through 37-n and input device(s) 79 via the input interface module(s) 74, the I/O interface 71, and the I/O and/or peripheral control module 70. An input device 79 includes a keypad, a keyboard, control switches, a touchpad, a microphone, a camera, etc. An input interface module 74 includes a software driver and a hardware connector for coupling an input device to the I/O and/or peripheral control module 70. In an embodiment, an input interface module 74 is in accordance with one or more Universal Serial Bus (USB) protocols.

The computing device controller hub 36 coordinates data communications between the nodes 37-1 through 37-n and output device(s) 80 via the output interface module(s) 75 and the I/O and/or peripheral control module 70. An output device 80 includes a speaker, auxiliary memory, headphones, etc. An output interface module 75 includes a software driver and a hardware connector for coupling an output device to the I/O and/or peripheral control module 70. In an embodiment, an output interface module 75 is in accordance with one or more audio codec protocols.

The nodes 37-1 through 37-n communicate directly with a video graphics processing module 70-1 to display data on the display 276. The display 276 includes an LED (light emitting diode) display, an LCD (liquid crystal display), and/or other type of display technology. The display has a resolution, an aspect ratio, and other features that affect the quality of the display. The video graphics processing module 70-1 receives data from the nodes 37-1 through 37-n, processes the data to produce rendered data in accordance with the characteristics of the display, and provides the rendered data to the display 276.

FIG. 9B is a schematic block diagram of an embodiment of a computing device 33 that includes a plurality of computing resources similar to the computing resources of FIG. 9A with the addition of one or more cloud memory interface modules 82, one or more cloud processing interface modules 83, cloud memory 84, and one or more cloud processing modules 85. The cloud memory 84 includes one or more tiers of memory (e.g., ROM, volatile (RAM, main, etc.), non-volatile (hard drive, solid-state, etc.) and/or backup (hard drive, tape, etc.)) that is remoted from the computing device controller hub 36 and is accessed via a network (WAN and/or LAN). The cloud processing module 85 is similar to a processing module of nodes 37-1 through 37-n but is remoted from the computing device controller hub 36 and is accessed via a network.

FIG. 9C is a schematic block diagram of an embodiment of a computing device 33 that includes a plurality of computing resources similar to the computing resources of FIG. 9B with a change in how the cloud memory interface module(s) 82 and the cloud processing interface module(s) 83 are coupled to computing device controller hub 36. In this embodiment, the interface modules 82 and 83 are coupled to a cloud peripheral control module 81 that directly couples to the computing device controller hub 36.

FIG. 9D is a schematic block diagram of an embodiment of a computing device 33 that includes a plurality of computing resources, which includes include a computing device controller hub 36, a boot up processing module 86, boot up RAM 88, a read only memory (ROM) 87, one or more video graphics processing modules 70-1, one or more displays 276 (optional), an Input-Output (I/O) peripheral control module 70, one or more input interface modules 74, one or more output interface modules 75, one or more cloud memory interface modules 82, one or more cloud processing interface modules 83, cloud memory 84, and cloud processing module(s) 85.

In this embodiment, the cloud processing modules include the nodes 37-1 through 37-n of previous figures. The computing device 33 includes enough processing resources (e.g., processing module 86, ROM 87, and RAM 88) to boot up. Once booted up, the cloud memory 84 and the cloud processing module(s) 83 along with nodes 37-1 through 37-n function as the computing device's memory (e.g., main and hard drive) and processing module.

FIG. 9E is a schematic block diagram of another embodiment of a computing device 33 that includes a hardware section 90 and a software program section 89. The hardware section 90 includes the hardware functions of power management, processing, memory, communications, and input/output. FIG. 9G illustrates the hardware section 90 in greater detail.

The software program section 89 includes a database operating system 61, database system and/or utilities applications, and database applications. The software program section 89 further includes a computing device operating system 60, computing device system and/or utilities applications, and computing device applications. The software program section further includes APIs and HWIs. APIs (application programming interface) are the interfaces between the system and/or utilities applications and the operating system and the interfaces between the applications and the operating system. HWIs (hardware interface) are the interfaces between the hardware components and the operating system. For some hardware components, the HWI is a software driver. The functions of the operating system are discussed in greater detail with reference to FIG. 9F.

FIG. 9F is a diagram of an example of the functions of the computing device operating system of a computing device 33. In general, the operating system function to identify and route input data to the right places within the computer and to identify and route output data to the right places within the computer. Input data is with respect to the processing module and includes data received from the input devices, data retrieved from main memory, data retrieved from secondary memory, and/or data received via a network card. Output data is with respect to the processing module and includes data to be written into main memory, data to be written into secondary memory, data to be displayed via the display and/or an output device, and data to be communicated via a network care.

The operating system includes the OS functions of process management, command interpreter system, I/O device management, main memory management, file management, secondary storage management, error detection & correction management, and security management. The process management OS function manages processes of the software section operating on the hardware section, where a process is a program or portion thereof.

The process management OS function includes a plurality of specific functions to manage the interaction of software and hardware. The specific functions include:
load a process for execution;
enable at least partial execution of a process;
suspend execution of a process;
resume execution of a process;
terminate execution of a process;
load operational instructions and/or data into main memory for a process;
provide communication between two or more active processes;
avoid deadlock of a process and/or interdependent processes; and
control access to shared hardware components.

The I/O Device Management OS function coordinates translation of input data into programming language data and/or into machine language data used by the hardware components and translation of machine language data and/or programming language data into output data. Typically, input devices and/or output devices have an associated driver that provides at least a portion of the data translation. For example, a microphone captures analog audible signals and converts them into digital audio signals per an audio encoding format. An audio input driver converts, if needed, the digital audio signals into a format that is readily usable by a hardware component.

The File Management OS function coordinates the storage and retrieval of data as files in a file directory system, which is stored in memory of the computing device. In general, the file management OS function includes the specific functions of:
File creation, editing, deletion, and/or archiving;
Directory creation, editing, deletion, and/or archiving;
Memory mapping files and/or directors to memory locations of secondary memory; and
Backing up of files and/or directories.

The Network Management OS function manages access to a network by the computing device. Network management includes
Network fault analysis;
Network maintenance for quality of service;
Network access control among multiple clients; and
Network security upkeep.

The Main Memory Management OS function manages access to the main memory of a computing device. This includes keeping track of memory space usage and which processes are using it; allocating available memory space to requesting processes; and deallocating memory space from terminated processes.

The Secondary Storage Management OS function manages access to the secondary memory of a computing device. This includes free memory space management, storage allocation, disk scheduling, and memory defragmentation.

The Security Management OS function protects the computing device from internal and external issues that could adversely affect the operations of the computing device. With respect to internal issues, the OS function ensures that processes negligibly interfere with each other; ensures that processes are accessing the appropriate hardware components, the appropriate files, etc.; and ensures that processes execute within appropriate memory spaces (e.g., user memory space for user applications, system memory space for system applications, etc.).

The security management OS function also protects the computing device from external issues, such as, but not limited to, hack attempts, phishing attacks, denial of service attacks, bait and switch attacks, cookie theft, a virus, a trojan horse, a worm, click jacking attacks, keylogger attacks, eavesdropping, waterhole attacks, SQL injection attacks, and DNS spoofing attacks.

FIG. 9G is a schematic block diagram of the hardware components of the hardware section 90 of a computing device. The memory portion of the hardware section includes the ROM, the main memory, the cache memory, the cloud memory, and the secondary memory. The processing portion of the hardware section includes the computing device controller hub, the processing modules (e.g., of the nodes), the video graphics processing module, and the cloud processing module.

The input/output portion of the hardware section includes the cloud peripheral control module, the I/O and/or peripheral control module, the network interface module, the I/O interface module, the output device interface, the input device interface, the cloud memory interface module, the cloud processing interface module, and the secondary memory interface module. The IO portion further includes input devices such as a touch screen, a microphone, and switches. The IO portion also includes output devices such as speakers and a display.

The communication portion includes an ethernet transceiver network card (NC), a WLAN network card, a cellular transceiver, a Bluetooth transceiver, and/or any other device for wired and/or wireless network communication.

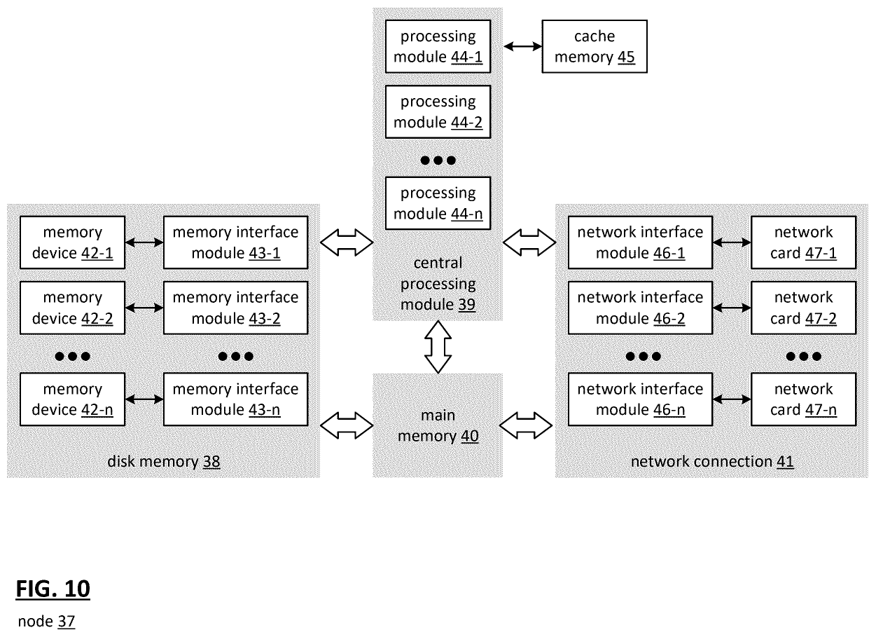

FIG. 10 is a schematic block diagram of an embodiment of a node 37 of computing device 33. The node 37 includes the central processing module 39, the main memory 40, the disk memory 38, and the network connection 41. The main memory 40 includes read only memory (RAM) and/or other form of volatile memory for storage of data and/or operational instructions of applications and/or of the operating system. The central processing module 39 includes a plurality of processing modules 44-1 through 44-n one or more cache memory 45. A processing module is as defined at the end of the detail description.

The disk memory 38 includes a plurality of memory interface modules 43-1 through 43-n and a plurality of memory devices 42-1 through 42-n. The memory devices 42-1 through 42-n include, but are not limited to, solid state memory, disk drive memory, cloud storage memory, and other non-volatile memory. For each type of memory device, a different memory interface module 43-1 through 43-n is used. For example, solid state memory uses a standard, or serial, ATA (SATA), variation, or extension thereof, as its memory interface. As another example, disk drive memory devices use a small computer system interface (SCSI), variation, or extension thereof, as its memory interface.

In an embodiment, the disk memory 38 includes a plurality of solid state memory devices and corresponding memory interface modules. In another embodiment, the disk memory 38 includes a plurality of solid state memory devices, a plurality of disk memories, and corresponding memory interface modules.

The network connection 41 includes a plurality of network interface modules 46-1 through 46-n and a plurality of network cards 47-1 through 47-n. A network card 47-1 through 47-n includes a wireless LAN (WLAN) device (e.g., an IEEE 802.11n or another protocol), a LAN device (e.g., Ethernet), a cellular device (e.g., CDMA), etc. The corresponding network interface module 46-1 through 46-n includes the software driver for the corresponding network card and a physical connection that couples the network card to the central processing module or other component(s) of the node.

The connections between the central processing module 39, the main memory 40, the disk memory 38, and the network connection 41 may be implemented in a variety of ways. For example, the connections are made through a node controller (e.g., a local version of the computing device controller hub). As another example, the connections are made through the computing device controller hub.

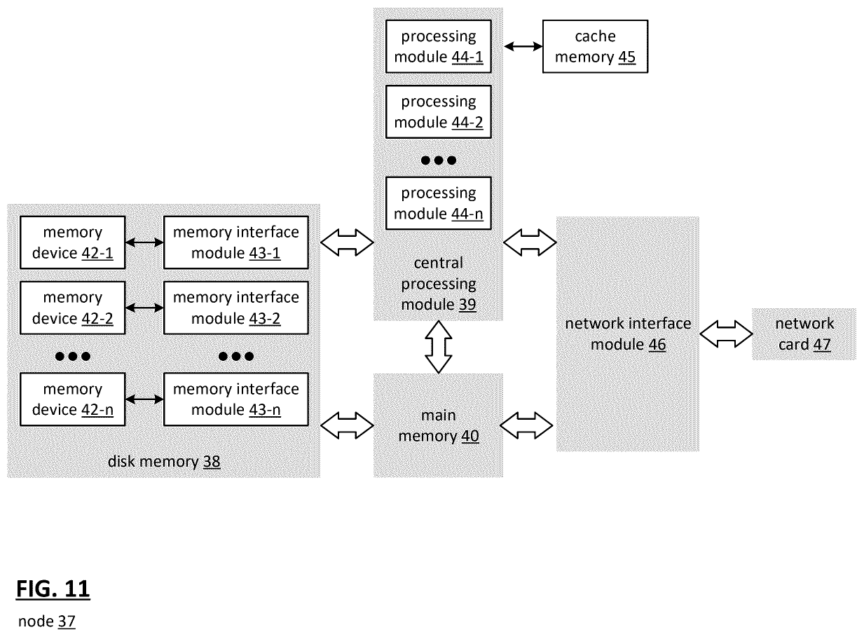

FIG. 11 is a schematic block diagram of an embodiment of a node of a computing device that is similar to the node of FIG. 10, with a difference in the network connection. In this embodiment, the node includes a single network interface module-network card configuration.

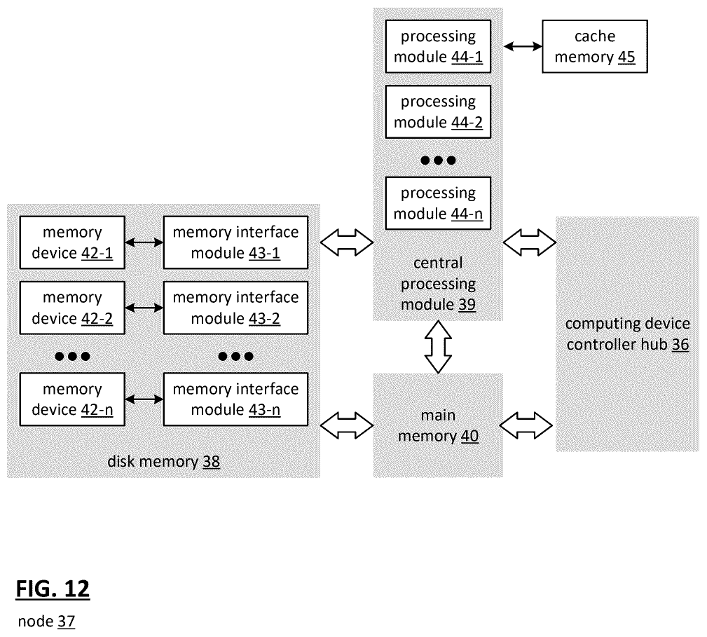

FIG. 12 is a schematic block diagram of an embodiment of a node of a computing device that is similar to the node of FIG. 10, with a difference in the network connection. In this embodiment, the node connects to a network connection via the computing device controller hub.

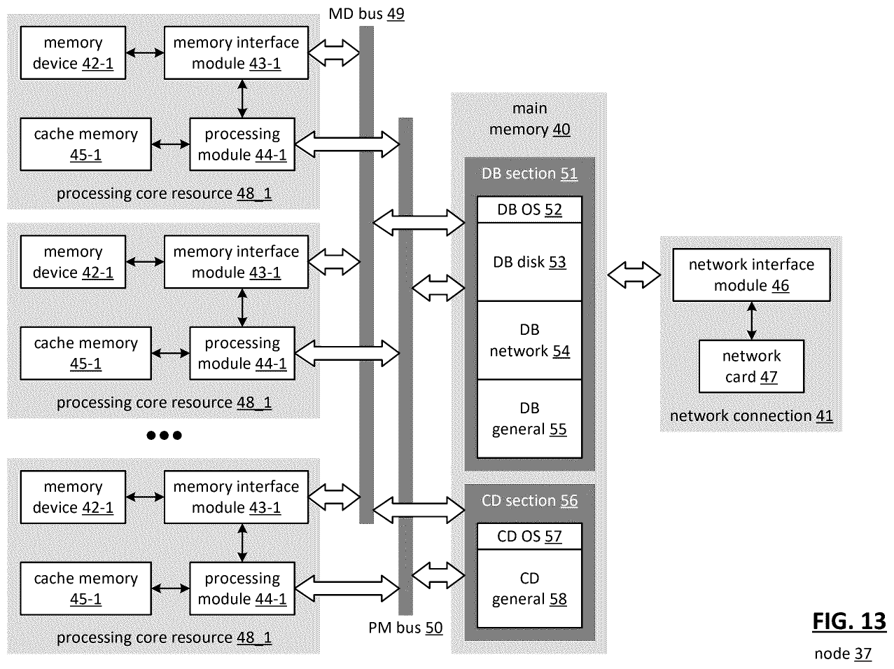

FIG. 13 is a schematic block diagram of another embodiment of a node 37 of computing device 33. The components of the node are arranged into processing core resources 48_1. Each processing core resource includes a processing module 44-1, a memory interface module(s) 43-1, memory device(s) 42-1, and cache memory 45-1 In this configuration, each processing core resource can operate independently of the other processing core resources. This further supports increased parallel operation of database functions to further reduce execution time.

The main memory is divided into a computing device (CD) section and a database (DB) section. The database section includes a database operating system (OS) area, a disk area, a network area, and a general area. The computing device section includes a computing device operating system (OS) area and a general area. Note that each section could include more or less allocated areas for various tasks being executed by the database system.

In general, the database OS allocates main memory for database operations. Once allocated, the computing device OS cannot access that portion of the main memory. This supports lock free and independent parallel execution of one or more operations.

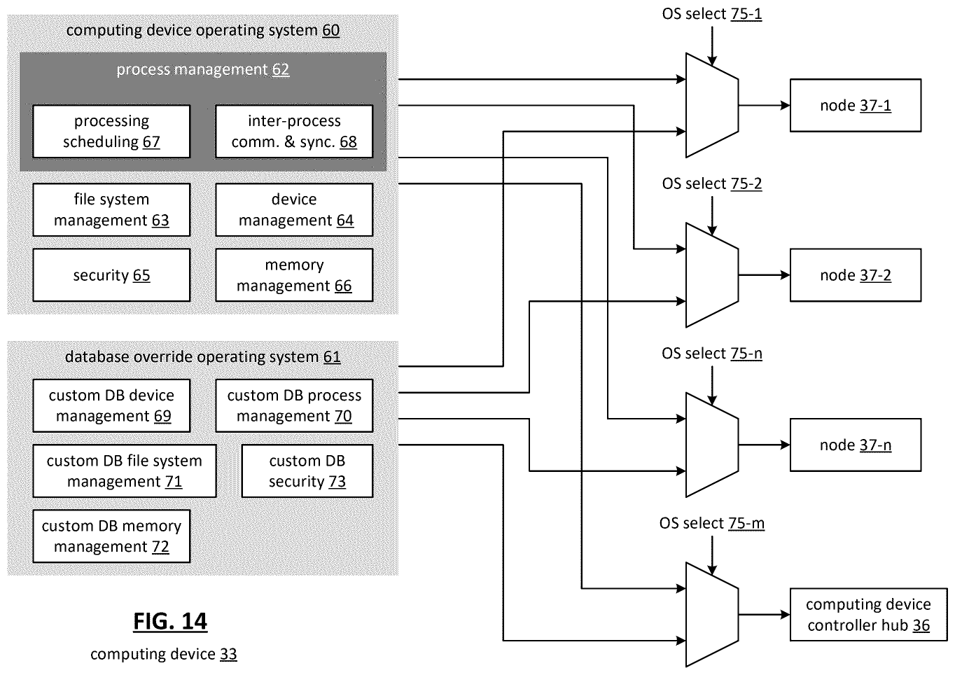

FIG. 14 is a schematic block diagram of an embodiment of operating systems of a computing device. The computing device includes a computing device operating system (CD OS) 60 and a database overriding operating system (DB OS) 61. The computing device OS 60 includes process management 62, file system management 63, device management 64, memory management 66, and security 65. The processing management 62 generally includes process scheduling 67 and inter-process communication and synchronization 68. In general, the computing device OS 60 is a conventional operating system used by a variety of types of computing devices. For example, the computing device operating system is a personal computer operating system, a server operating system, a tablet operating system, a cell phone operating system, etc.

The database operating system (DB OS) 61 includes custom DB device management 69, custom DB process management 70 (e.g., process scheduling and/or inter-process communication & synchronization), custom DB file system management 71, custom DB memory management 72, and/or custom security 73. In general, the database OS 61 provides hardware components of a node more direct access to memory, more direct access to a network connection, improved independency, improved data storage, improved data retrieval, and/or improved data processing than the computing device OS.

In an example of operation, the database OS 61 controls which operating system, or portions thereof, operate with each node and/or computing device controller hub of a computing device. For example, device management of a node is supported by the computing device operating system, while process management, memory management, and file system management are supported by the database operating system. To override the computing device OS, the database OS provides instructions to the computing device OS regarding which management tasks will be controlled by the database OS. The database OS also provides notification to the computing device OS as to which sections of the main memory it is reserving exclusively for one or more database functions, operations, and/or tasks. One or more examples of the database operating system are provided in subsequent figures.

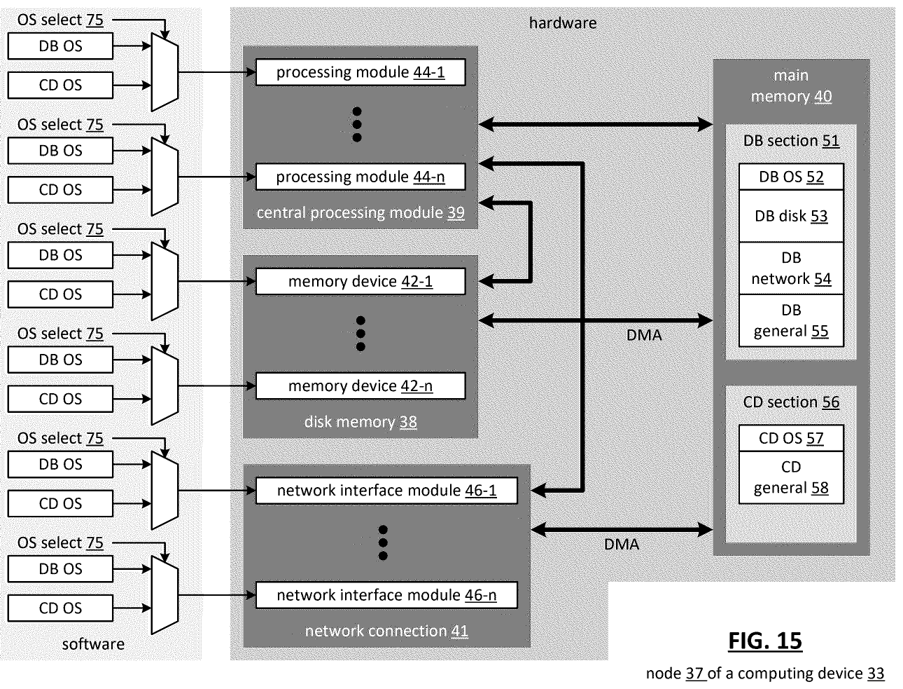

FIG. 15 is a schematic block diagram of an embodiment of operating systems for a node 37 of a computing device 33. A node 37 of a computing device 33 includes hardware and software architectures. The software architecture includes a computing device operating system (CD OS), a database operating system (DB OS), and a plurality of software applications (not shown). The hardware architecture includes disk memory 38, a centralized processing module unit (CPM) 39, main memory (which is shared by the nodes of the computing device) 40, and a network connection (which could be dedicated to the node or shared by the nodes of the computing device) 41.

The disk memory 38 includes a plurality of disks (e.g., memory devices 42-1 through 42-n). A memory device is a non-volatile memory of a variety of forms. For example, a memory device is a solid-state memory such as random access memory (RAM) and/or flash memory (NAND or NOR flash). The centralized processing module unit (CPM) 39 includes a plurality of processing modules 44-1 through 44-n. A processing module is defined at the end of the detailed description section. If the node includes its own network connection 41, the network connection 41 includes one or more network interfaces 46-1 through 46-n and corresponding network cards (which are not shown).

Within the hardware section of a node, the centralized processing module unit (CPM) 39 has direct connections with the disk memory 38, with the main memory 40, and with the network connection 41. Also, within the hardware section, each of the disk memory 38 and network connection 41 has direct memory access (DMA) with the main memory 40.

The software architecture allows individual selection of which operating system to use for the centralized processing module unit (CPM), the disk memory, and/or the network connection. Further, within each of these hardware sections, the desired operating system is selectable at the component level. For example, a first processing module uses the computing device operating system (CD OS) and a second processing module uses the database operating system (DB OS).

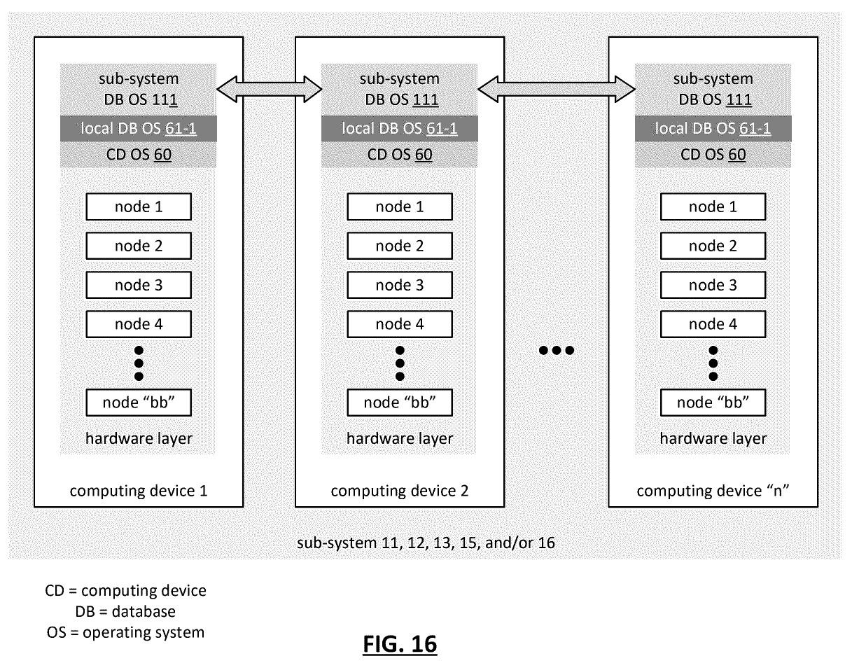

FIG. 16 is a schematic block diagram of an embodiment of operating systems of a sub-system of the database system. The sub-system (e.g., the parallelized data input sub-system, the parallelized store, retrieve, and/or process sub-system, the parallelized query & results sub-system, the administrative sub-system, and/or the configuration sub-system) includes a plurality of computing devices. Each computing device includes a hardware (HW) layer that includes a plurality of nodes and a software layer. The software layer includes the computing device operating system (CD OS), a local database operating system (DB OS), and a sub-system database operating system (DB OS).

The interaction action between the hardware layer, the computing device operating system (CD OS), and the local database operating system (DB OS) was generally described with reference to FIG. 15. The sub-system database operating system (DB OS) resides within one or more of the computing devices to provide sub-system level operating system functionality of one or more of file system management, device management, process management (e.g., process scheduling and/or inter-process communication and synchronization), memory management, and/or security.

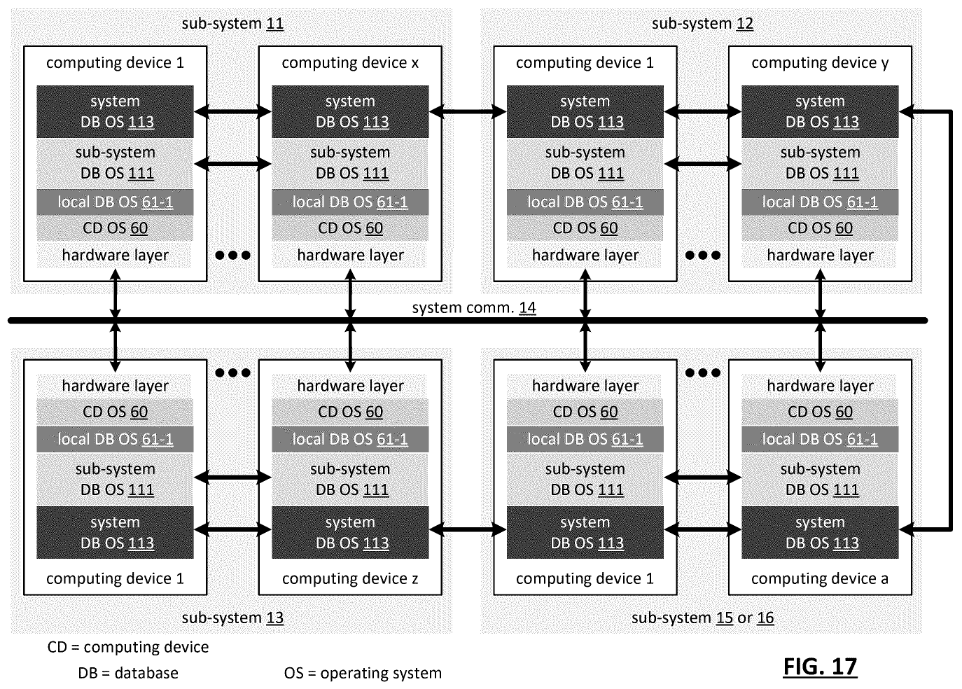

FIG. 17 is a schematic block diagram of an embodiment of operating systems of the database system that includes a plurality of sub-systems (e.g., the parallelized data input sub-system, the parallelized store, retrieve, and/or process sub-system, the parallelized query & results sub-system, the administrative sub-system, and/or the configuration sub-system). Each sub-system includes a plurality of computing devices (CD) and each computing device includes the hardware layer and the software layer of FIG. 16 with the addition of a system level database operating system.

The system database operating system (DB OS) resides within one or more of the computing devices of one or more of the sub-systems to provide system level operating system functionality of one or more of file system management, device management, process management (e.g., process scheduling and/or inter-process communication and synchronization), memory management, and/or security.

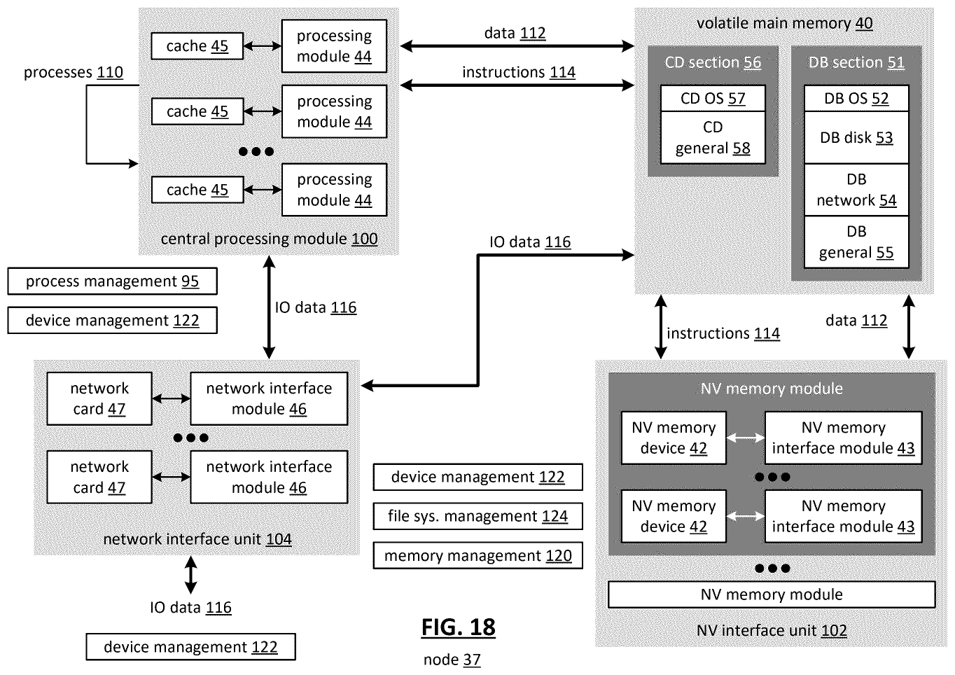

FIG. 18 is a schematic block diagram of an embodiment of a node 37 of a computing device. The node 37 of FIG. 18 is similar to the nodes of previous figures except that FIG. 18 depicts flow of data and operational instructions within the hardware and software architecture of the node 37. FIG. 18 includes a central processing module 100, volatile main memory 40, a network interface unit 104, and a non-volatile (NV) interface unit 102. The volatile main memory 40 includes read only memory (RAM) and/or other form of volatile memory for storage of data and/or operational instructions of applications and/or of the operating system. The central processing module 100 includes a plurality of processing modules 44 one or more cache memory 45.

The non-volatile (NV) interface unit 102 includes a plurality of NV memory modules. An NV memory module includes a plurality of NV memory devices 42 coupled to a corresponding plurality of NV memory interface modules 43. The NV memory devices 42 include, but are not limited to, solid state memory, disk drive memory, cloud storage memory, and other non-volatile memory. For each type of memory device, a different NV memory interface module 43. For example, solid state memory uses a standard, or serial, ATA (SATA), variation, or extension thereof, as its memory interface. As another example, disk drive memory devices use a small computer system interface (SCSI), variation, or extension thereof, as its memory interface.

The network interface unit 104 includes a plurality of network interface modules 46 and a plurality of network cards 47-1 through 47-n. A network card 47 includes a wireless LAN (WLAN) device (e.g., an IEEE 802.11n or another protocol), a LAN device (e.g., Ethernet), a cellular device (e.g., CDMA), etc. The corresponding network interface module 46 includes the software driver for the corresponding network card and a physical connection that couples the network card to the central processing module or other component(s) of the node.

The connections between the central processing module 100, the volatile main memory 40, the NV interface unit 102, and the network interface unit 104 may be implemented in a variety of ways. For example, the connections are made through a node controller (e.g., a local version of the computing device controller hub). As another example, the connections are made through the computing device controller hub.

The software architecture includes a computing device operating system (CD OS), a database operating system (DB OS), and a plurality of software applications (not shown). In an example of operation, the database OS controls which operating system, or portions thereof, operate with each node and/or computing device controller hub of a computing device. For example, device management 122 of a node is supported by the computing device operating system, while process management 95, memory management 120, and file system management 124 are supported by the database operating system.

As shown, the central processing module 100 performs processes 110, and sends and receives data 112 and instructions from the volatile main memory 40. The volatile main memory 40 exchanges instructions 114 and data 122 with NV interface unit 102. The central processing module 100 sends and receives IO data 116 from the network interface unit 104 in accordance with process management 95 and device management 122 operational instructions. The volatile main memory 40 is also operable to send and receive IO data 116 via the network interface unit 104. Data sent/received via memory is controlled by device management 122, file system management 124, and memory management 120 operational instructions. The network interface unit 104 is operable to send and receive IO data 116 from other nodes and/or processing core resources of the computing device in accordance with device management 122 operational instructions.

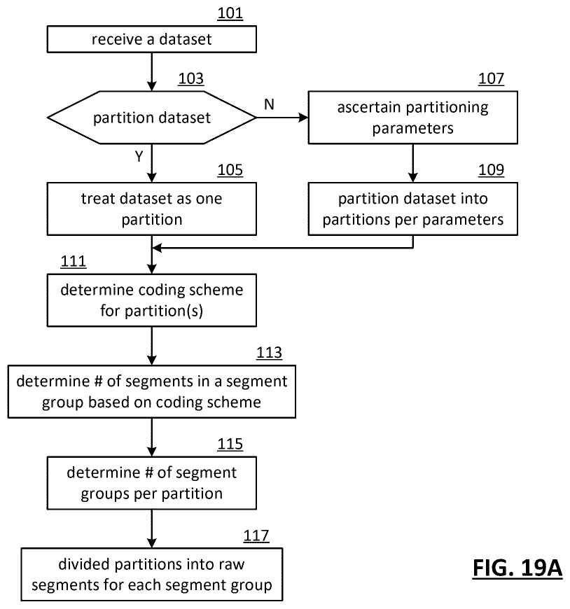

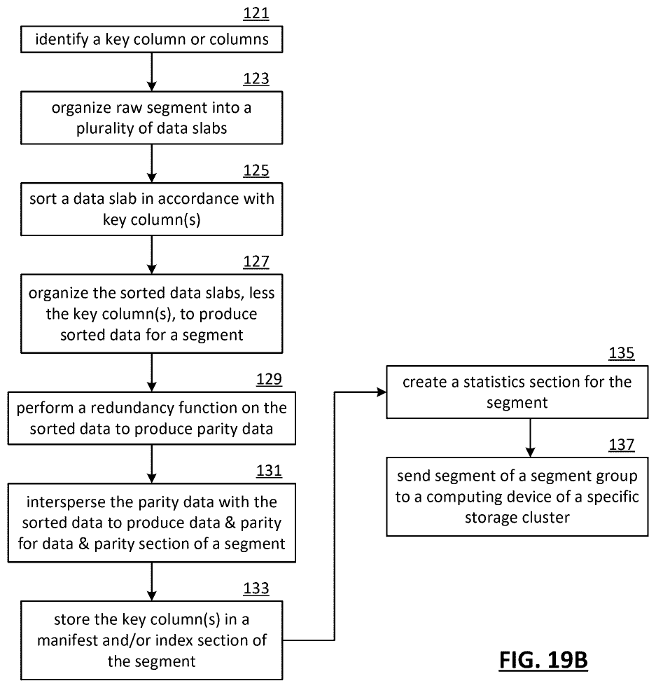

FIG. 19A is a logic diagram of an example of processing a table or data set for storage in the database system that begins at step 101 where a processing core resource, a node, a computing device, or devices, (hereinafter for this figure referred to as a computing node) of the parallelized data input sub-system receives a data set (e.g., a table). The method continues at step 103 where the computing node determines whether to partition the data set.

If yes, the method continues at step 107 where the computing node ascertains partitioning parameters (e.g., one or more of segment size, number of computing devices in a cluster, number of nodes, number of processing core resources, data block size, memory formatting, network formatting, query probabilities (how the data will need to be sorted, retrieved, and/or processed for queries), etc.). The method continues at step 109 where the computing node partitions the data set into a plurality of data partitions in accordance with the partitioning parameters.

If not partitioning the data set (e.g., a table), then the method continues at step 105 where the computing node treats the data set as one data partition. The method continues from step 105 and from step 109 at step 111 where the computing node determines a number of segments in a segment group for each data partition. For example, the number of segments is based on a coding scheme for encoding the data set before storage. As a specific example, when the coding scheme is parity encoding of four data pieces, then five pieces are created (e.g., four for the data pieces and one for the parity piece) and the number of segments in a group is five.

The method continues at step 115 where the computing node determines a number of segments groups to be created for each data partition based on one or more of a variety of factors. The factors include, but are not limited to, data block size, number of processing core resources available, number of nodes available, number of computing devices available, number of storage clusters, etc. The method continues at step 117 where the computing node divides a data partition into raw segments for each segment group.

FIG. 19B is a logic diagram of an example of processing a raw data segment of a table or data set for storage in the database system that begins at step 121 where a processing core resource, a node, a computing device, or devices, (hereinafter for this figure referred to as a computing node) of the parallelized data input sub-system receives a data set (e.g., a table). The method continues at step 123 where the computing node organizes the raw (e.g., unsorted, uncompressed, and/or unprocessed) data segment into a plurality of data slabs. For example, a data slab corresponds to a column of a table.

The method continues at step 125 where the computing node sorts a data slab in accordance with one or more key columns (i.e., one or more selected columns of the table used to sort the data slab). The method continues at step 127 where the computing node organizes the sorted data slabs, less the key column(s), to produce a plurality of sorted data slabs (i.e., a sorted data segment).

The method continues at step 129 where the computing node performs a redundancy function (e.g., parity, RAID 5, RAID 6, RAID 10, erasure encoding, etc.) on the sorted data segment to produce parity data. The method continues at step 131 where the computing node intersperses the parity data with the sorted data to produce data & parity of a data & parity section of a segment. The method continues at step 133 where the computing node stores the key column(s) in a manifest and/or an index section of the segment. The manifest section stores metadata of the data and/or parity of the data & parity section of the segment.

The method continues at step 135 where the computing node creates a statistics sections for the segment for storing statistical information regarding the segment. For example, the statistics section stores number of rows in a table, number of rows in a data slab, average length of a variable length column, average row length, etc. The method continues at step 137 where the computing node sends the segment of a segment group to a computing device of a specific storage cluster.

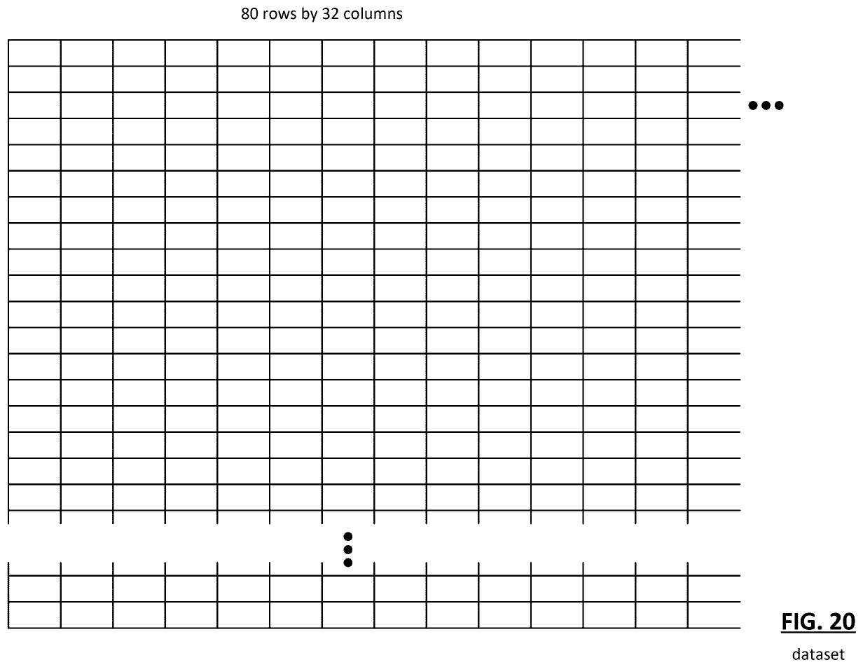

FIGS. 20-30 are schematic block diagrams of an example of processing a table or data set for storage in the database system. FIG. 20 illustrates an example of a data set or table that includes 32 columns and 80 rows, or records, that is received by the parallelized data input-subsystem. This is a very small table but is sufficient for illustrating one or more concepts regarding one or more aspects of a database system.

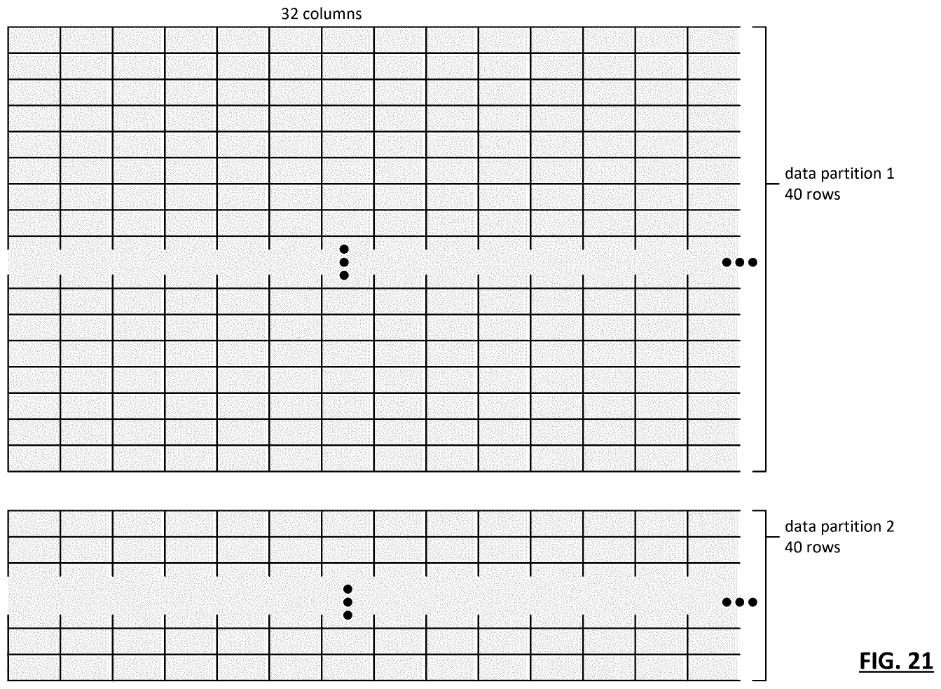

FIG. 21 illustrates an example of the parallelized data input-subsystem dividing the data set into two partitions. Each of the data partitions includes 40 rows, or records, of the data set. In other examples, the parallelized data input-subsystem divides the data set into more than two partitions with each partition including a different number of rows.

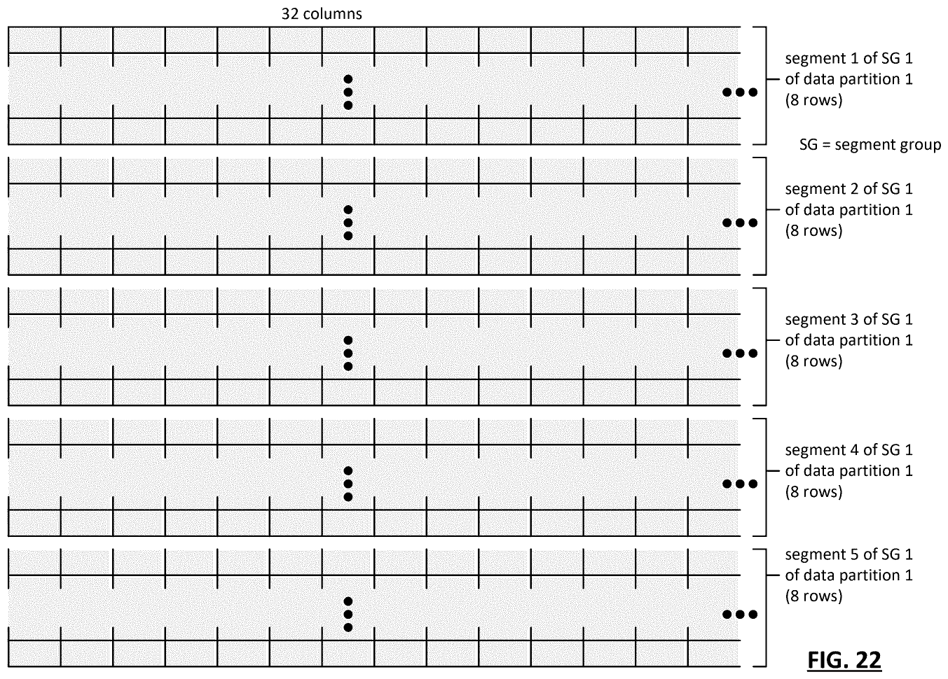

FIG. 22 illustrates an example of the parallelized data input-subsystem dividing a data partition into a plurality of segments to form a segment group. The number of segments in a segment group is a function of the data redundancy encoding. In this example, the data redundancy encoding is single parity encoding from four data pieces; thus, five segments are created.

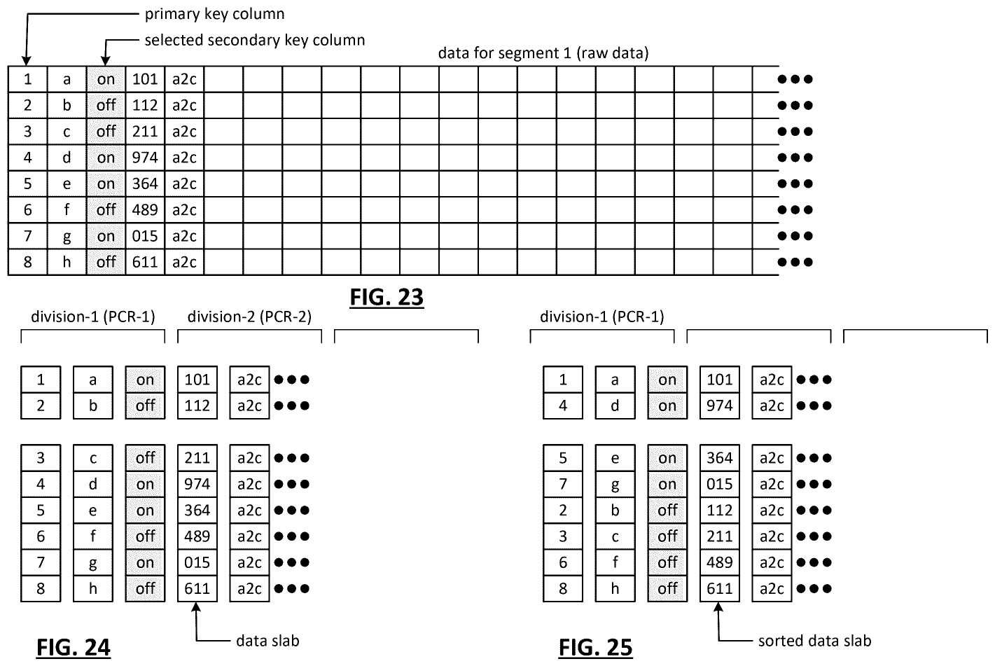

FIG. 23 illustrates an example of data for segment 1 of the segments of FIG. 22; referred to as a raw segment. Segment 1 includes 8 rows and 32 columns. The third column is selected as the key column.

FIG. 24 illustrates an example of the parallelized data input-subsystem dividing segment 1 of FIG. 23 into a plurality of data slabs (e.g., divisions). A data slab is a column of segment 1. In this figure, the data of the data slabs has not been sorted. The plurality of data slabs are divided into divisions based on the number of processing core resources (PCR) in a node. A first division is sent to a first PCR and so on.

FIG. 25 illustrates an example of the parallelized data input-subsystem sorting the data slabs based on the key column. In this example, the data slabs are sorted based on the third column which includes data of “on” or “off”. The result is sorted data slabs.

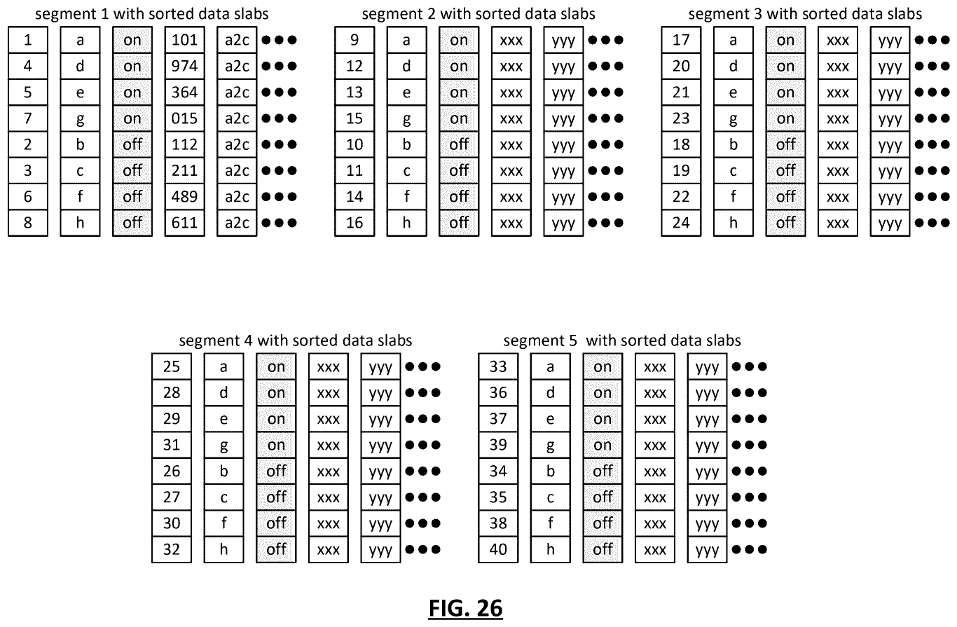

FIG. 26 illustrates an example of each segment being sorted to produce sorted data slabs. The similarity of data from segment to segment is for the convenience of illustration. Note that each segment has its own data, which may or may not be similar to the data in the other sections. Each segment is divided into the same number of data slabs and are sorted based on the same key column.

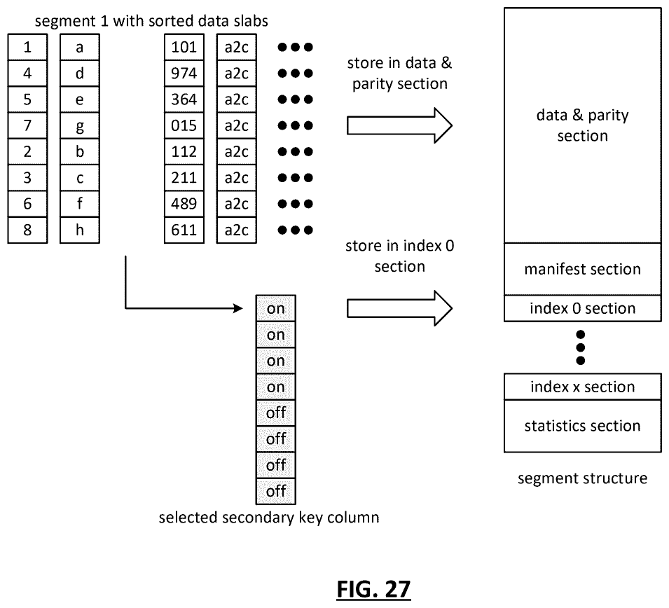

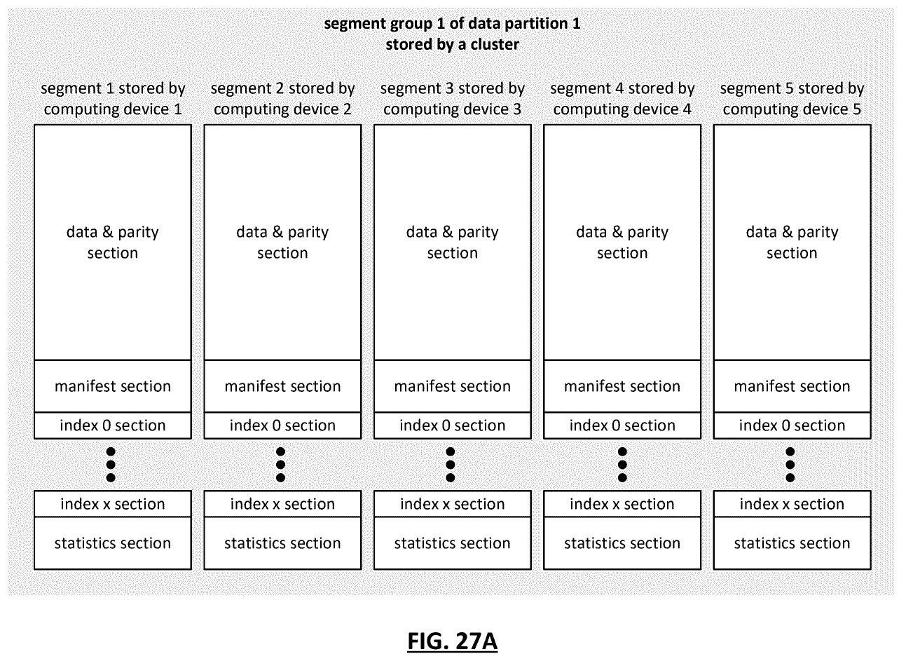

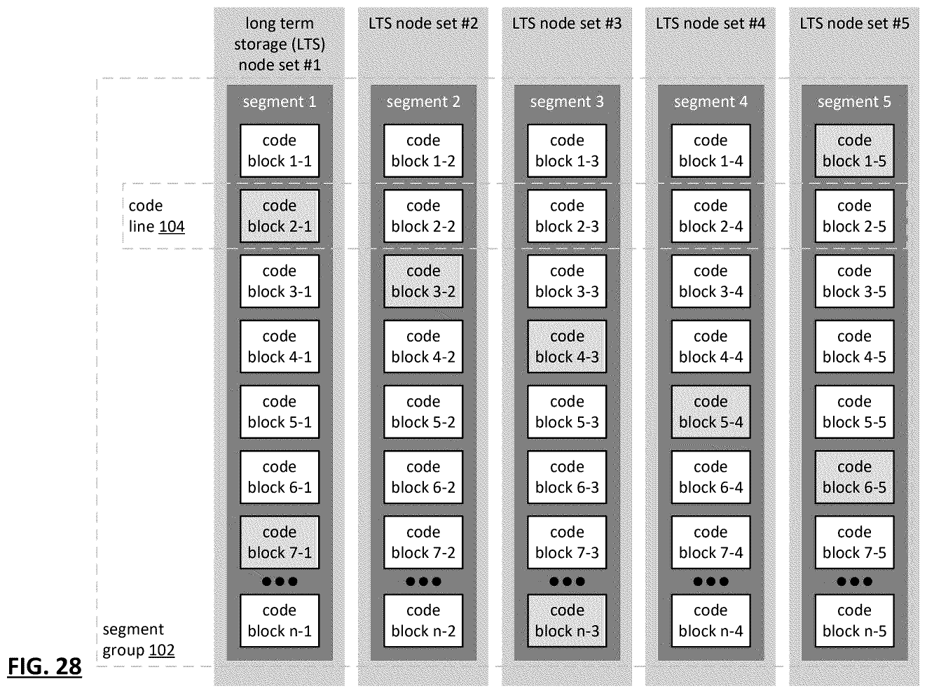

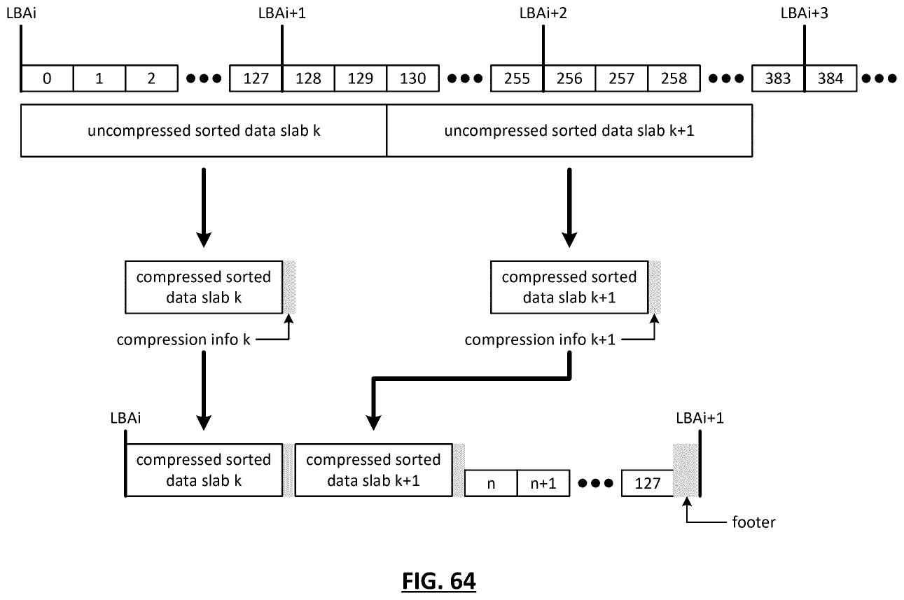

FIG. 27 illustrates an example of creating a segment of a group of segments. The sorted data slabs of FIG. 25 are placed in the data & parity section of a segment. The sorted data slabs are stored in the data & parity section in a compressed format or as raw data (i.e., non-compressed format). Compression of the sorted data slabs is discussed below with reference to one or more of FIGS. 64-67.

Before the sorted data slabs are stored in the data & parity section, or concurrently with storing in the data & parity section, sorted data slabs from the segments of a segment group are redundancy encoded. The redundancy encoding may be done in a variety of ways. For example, the redundancy encoding is in accordance with RAID 5, RAID 6, or RAID 10. As another example, the redundancy encoding is a form of forward error encoding (e.g., Reed Solomon, Trellis, etc.). An example of redundancy encoding is discussed in greater detail with reference to one or more of FIGS. 28 and 58-64.

The manifest section stores metadata regarding the sorted data slabs. The metadata includes one or more of, but is not limited to, descriptive metadata, structural metadata, and/or administrative metadata. Descriptive metadata includes one or more of, but is not limited to, information regarding data such as name, an abstract, keywords, author, etc. Structural metadata includes one or more of, but is not limited to, structural features of the data such as page size, page ordering, formatting, compression information, redundancy encoding information, logical addressing information, physical addressing information, physical to logical addressing information, etc. Administrative metadata includes one or more of, but is not limited to, information that aids in managing data such as file type, access privileges, rights management, preservation of the data, etc.

The key column is stored in an index section. For example, a first key column is stored in index #0. If a second key column exists, it is stored in index #1. As such, for each key column, it is stored in its own index section. Alternatively, one or more key columns are stored in a single index section.

The statistics section stores statistical information regarding the segment and/or the segment group. The statistical information includes one or more of, but is not limited, to number of rows (e.g., data values) in one or more of the sorted data slabs, average length of one or more of the sorted data slabs, average row size (e.g., average size of a data value), etc. The statistical information includes information regarding raw data slabs, raw parity data, and/or compressed data slabs and parity data.

FIG. 27A illustrates a segment group having five segments. Each segment includes a data & parity section, a manifest section, one or more index sections, and a statistic section. Each segment is targeted for a different computing device of a storage cluster. The number of segments in the segment group corresponds to the number of computing devices in a storage cluster. In this example, there are five computing devices in a storage cluster. Other examples include more or less than five computing devices in a storage cluster.

FIG. 28 illustrates an example of redundancy encoding using single parity encoding. The data of a segment is divided into data blocks (e.g., 4 K bytes). The data blocks of the segments are logically aligned such that the first data blocks of the segments are aligned. For example, coding block 1_1 (the first number represents the code block number in the segment and the second number represents the segment number, thus 1_1 is the first code block of the first segment) is aligned with the first code block of the second segment (code block 1_2), the first code block of the third segment (code block 1_3), and the first code block of the fourth segment (code block 1_4). This forms a data portion of a coding line.

The four data coding blocks are exclusively ORed together to form a parity coding block, which is represented by the gray shaded block 1_5. The parity coding block is placed in segment 5 as the first coding block. As such, the first coding line includes four data coding blocks and one parity coding block. Note that the parity coding block is typically only used when a data code block is lost or has been corrupted. Thus, during normal operations, the four data coding blocks are used.

To balance the reading and writing of data across the segments of a segment group, the positioning of the four data coding blocks and the one parity coding block are distributed. For example, the position of the parity coding block from coding line to coding line is changed. In the present example, the parity coding block, from coding line to coding line, follows the modulo pattern of 5, 1, 2, 3, and 4. Other distribution patterns may be used. In some instances, the distribution does not need to be equal. Note that the redundancy encoding may be done by one or more computing devices of the parallelized data input sub-system and/or by one or more computing devices of the parallelized data store, retrieve, &/or process sub-system.

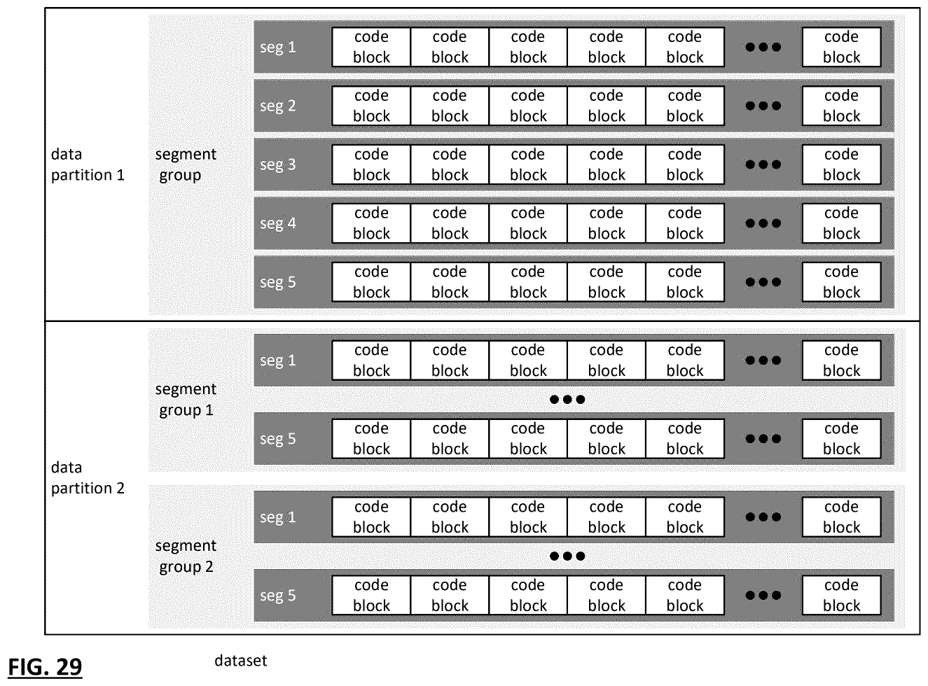

FIG. 29 illustrates an overlay of the dividing of a data set (e.g., a table) into partitions. Each partition is then divided into one or more segment groups. Each segment group includes a number of segments. Each segment is further divided into coding block, which include data coding blocks and parity coding blocks.

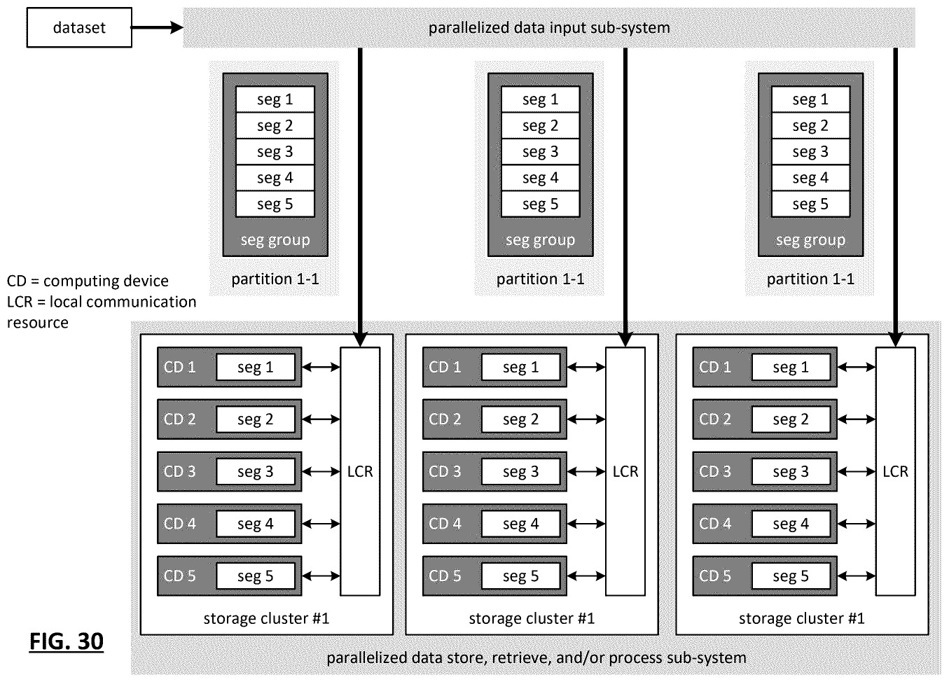

FIGS. 30-32 are schematic block diagrams of an example of storing a processed table or data set in the database system. FIG. 30 illustrates the parallelized data input sub-system sending segment groups of data partitions of a data set (e.g., table) to storage clusters of the parallelized data store, retrieve, &/or process sub-system. In this example, each storage cluster includes five computing devices, as such, a segment group includes five segments.

Each storage cluster has a primary computing device for receiving incoming segment groups. The primary computing device is randomly selected for each ingesting of data or is selected in a predetermined manner (e.g., a round robin fashion). The primary computing device of each storage cluster receives the segment group and then provides the segments to the computing devices in its cluster; including itself. Alternatively, the parallelized data input-section sends each segment of a segment group to a particular computing device within the storage clusters.

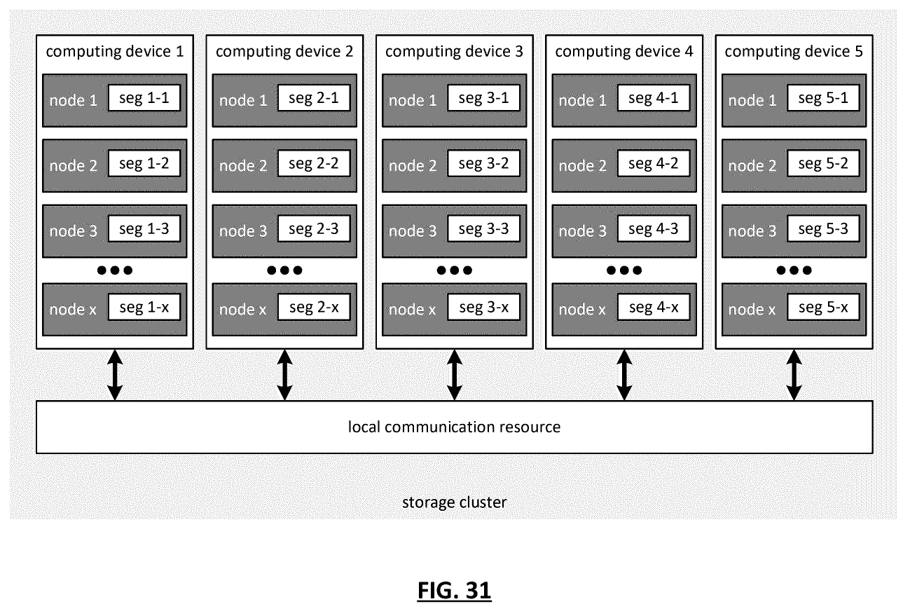

FIG. 31 illustrates a storage cluster distributing storage of a segment group among its computing devices and the nodes within the computing device. Within each computing device, a node is selected as a primary node for dividing a segment into segment divisions and distributing the segment divisions to the nodes; including itself. For example, node 1 of computing device (CD) 1 receives segment 1. Having x number of nodes in the computing device 1, node 1 divides the segment into x segment divisions (e.g., seg 1_1 through seg 1_x, where the first number represents the segment number of the segment group and the second number represents the division number of the segment). Having divided the segment into divisions (which may include an equal amount of data per division, an equal number of coding blocks per division, an unequal amount of data per division, and/or an unequal number of coding blocks per division), node 1 sends the segment divisions to the respective nodes of the computing device.

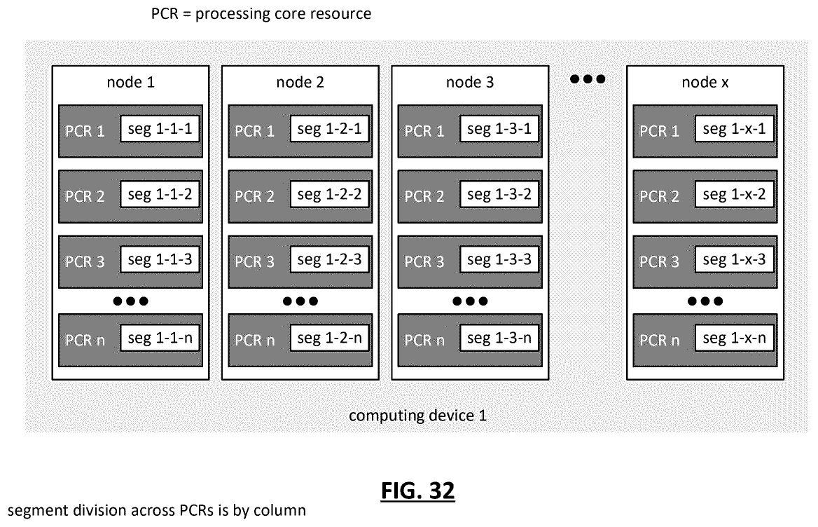

FIG. 32 illustrates a node of a computing device distributing storage of a segment division among its processing core resources (PCR). Within each node, a processing core resource (PCR) is selected as a primary PCR for dividing a segment division into segment sub-divisions and distributing the segment sub-divisions to the other PCRs of the node: including itself. For example, PCR 1 of node 1 of computing device 1 receives segment division 1_1. Having n number of PCRs in node 1, PCR 1 divides the segment division 1 into n segment sub-divisions (e.g., seg 1_1_1 through seg 1_1_n, where the first number represents the segment number of the segment group, the second number represents the division number of the segment, and the third number represents the sub-division number). Having divided the segment division into sub-divisions (which may include an equal amount of data per sub-division, an equal number of coding blocks per sub-division, an unequal amount of data per sub-division, and/or an unequal number of coding blocks per sub-division), PCR 1 sends the segment sub-divisions to the respective PCRs of node 1 of computing device 1.

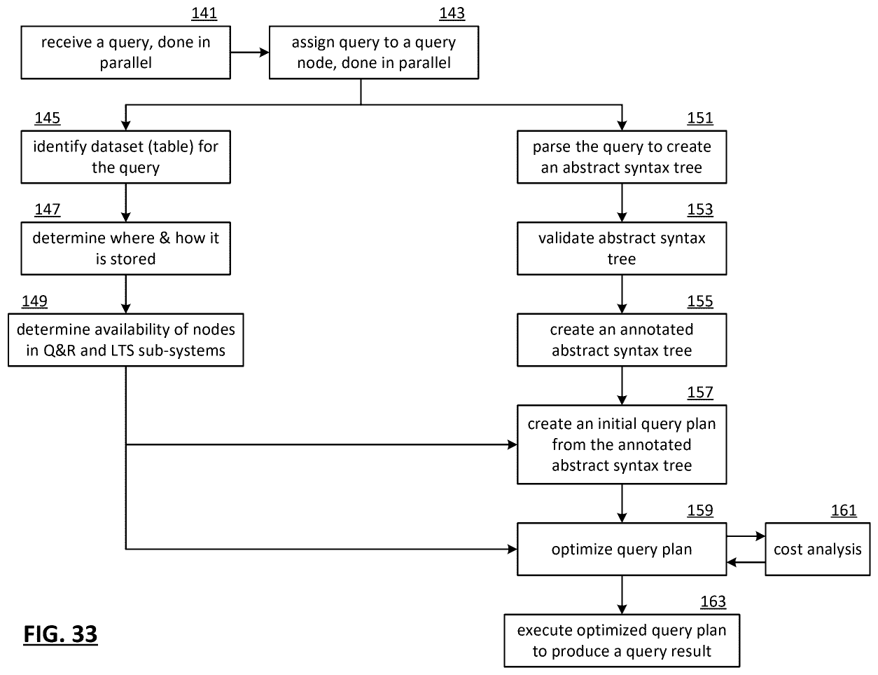

FIG. 33 is a logic diagram of an example of creating a query plan for execution within the database system that begins at steps 141 and 143 where one or more processing core resources of a node, one or more nodes of a computing device, and/or one or more computing devices of the parallelized query & response sub-system (hereinafter referred to as a computing node for the discussion of this figure) is assigned to receive a query. The received query is formatted in one of a variety of conventional query formats. For example, the query is formatted in accordance with Open Database Connectivity (ODBC), Java Database Connectivity (JDCB), or Spark.

The parallelized query & response sub-system is capable of receiving and processing a plurality of queries in parallel. For ease of discussion, the present method is discussed with reference to one query.

The method branches to steps 145 and 151. At step 145, the computing device identifies a table (or tables) for the received query. The method continues at step 147 where the computing device determines where and how the table(s) is/are stored. For example, the computing device determines how the table was partitioned; how each partition was divided into one or more segment groups; how many segments in a segment group; how many storage clusters are storing segment groups; how many computing devices are in a storage cluster; how many nodes per computing device; and/or how many processing core resources per node.

The method continues at step 149 where the computing device determines available nodes (and/or processing core resources) within the parallelized Q&R sub-system for processing operations of the query. In addition, the computing device determines nodes (and/or processing core resources) available for processing operations of the query. Typically, the nodes and/or processing core resources storing a relevant portion of the table will be need for processing one or more operations of the query.

At step 151, the computing device parses the received query to create an abstract syntax tree. For example, the computing device converts SQL statements of the query into nodes of a syntactic structure of source code and creates a tree structure of the nodes. A node corresponds to a construct occurring in the source code.

The method continues at step 153 where the computing device validates the abstract syntax tree. For example, the computing device verifies one or more of the SQL statements are valid, the conversion to operations of the DB instruction set are valid, the table(s) exists, the selected operations of the DB instruction set and/or the SQL statements yield viable data (e.g., will produce a result, will not cause a deadlock, etc.), etc. If not, the computing device sends an SQL exception to the source of the query.

For validated abstract syntax tree, the method continues at step 155 where the computing device generates an annotated abstract syntax tree. For example, the computing device adds column names, data types, aggregation information, correlation information, subquery information, etc. to the verified abstract system tree.

The method continues at step 157 where the computing device creates an initial query plan from the annotated abstract syntax tree. For example, the computing device selects operations from an operating instruction set of the database system to implement the abstract syntax tree. The operating instruction set of the database system (i.e., DB instruction set) includes the following operations:
Aggregation—aggregates two or more rows based on one or more values of a row and then combine (e.g., sum, average, appended, sort, etc.) into a row;
Agg VectorOperationInstance—use when number of rows is known and is less than or equal to a specific value (e.g., 256), use a vector operation instead of a hash function to aggregate rows, which allows aggregation without the need for caching;
Broadcast—computing device or node sending data to other computing devices or nodes performing similar tasks, functions, and/or operations (typically for lateral data flow in the system);
Eos—“end of stream” is a placeholder to indicate no data, may also be used to indicate a function cannot be performed;
Except—set subtraction;
Extend—add a column to received data;
Gather—combine data together;
GdeLookup—“Global Dictionary Compression” lookup function for data compression;
HashJoin—join data using a hash function;
IncrementBigInt—increment one or more data values in accordance with a test protocol
IncremetingInt—increment one or more data values

Index—uses indexed metadata to reduce amount of data to read and/or to push operations downstream to delay reading;
IndexAgg—aggregation of indexing;
IndexDistinct—indexing of distinct row, rows, column, and/or columns;
SegmentAgg (operator instance)—segmenting of an aggregation operation to produce sub-aggregation operations;
SegmentDistinct (operator instance)—segmenting of a distinct operation to produce sub-distinct operations;
IndexCountStar— [symbol]
Intersect—is a mathematical function to find data from two or more sets of data that intersect;
Jobs Virtual— [symbol]
Limit—limit the number of rows to be read, to be operated on, etc.;
Make Vector—convert columns into a matrix for linear algebra functions;
UnMake Vector—convert a resulting matrix back into columns;
MatrixExtend—add columns or another matrix to an existing matrix;
Offset—is an offset for data retrieval;
OrderedAgg—ordering of aggregation to allow for lower level aggregation, which allows higher level to be more efficient
OrderedDistinct—ordering of distinct values at lower levels, which allows higher levels to be more efficient;
OrderedGather—ordering of gathering at lower levels, which allows higher levels to be more efficient;
ProductJoin—nested loop join function (e.g., join data from one or more rows and/or from one or more columns);
ProjectOut—remove a column for data of interest (e.g., want to do this as far downstream as possible);
Rename—change name of a column, (can be used to avoid column name collisions);
Reorder—reorder data of one or more rows and/or one or more columns based on an ordering preference;
Root—conduit for data flow;
Select—select columns from one or more tables;
Shuffle—sub-divide data into a plurality of data sub-divisions (typically for lateral data flow in the system);
Switch—change where to send data when a condition is met;
TableScan—retrieve all of the data of a table;
TableSlabScan (operator instance)—retrieve particular data slabs of a table;
Tee—creates a brand in operational flow when operating on redundant data;
Union—establish a set of operations;
Window—is a specific type of aggregation that captures a moving window of aggregated data (e.g., a running sum, a running average, etc.); and

MultiplexerOperatorInstance for Set/ProductJoin/HashJoin/Sort/Aggregation—allows for lock free multiplexing for various types of operations.

The method continues at step 159 where the computing device optimizes the query plan using a cost analysis of step 161. The initial query plan is created to be executed by a computing device within the parallelized query & response sub-system. Optimizing the plan spreads the execution of the query across multiple layers (e.g., three or more) and includes the other sub-systems of the database system. The computing device utilizes one or more optimization transforms to optimize the initial query plan. The optimization transforms include:
AddDistinctBeforeMinMax: Adds a union distinct before an aggregation operator that only performs min/max
RemoveDistinctBeforeMinMax: The opposite of addDistinctBeforeMinMax
AddDistinctBetoreSemiAnti: Adds a union distinct as the right child of a join that is a semi or anti join
RemoveDistinctBeforeSemiAnti: The opposite of addDistinctBeforeSemiAnti
AggDistinctPushDown: Pushes down an aggregation that is only performing distinct operators (count/sum distinct) below its child
AggDistinctPushUp: The opposite of AggDistinctPushDown
AggregatePushDown: The same as AggDistinctPushDown but for aggregations performing non-distinct operations
AggregatePushUp: The opposite of AggregatePushDown
ConvertProductToHashJoin: Converts a product join with lhasCol=rhsCol filters into an equivalent hash join
CreateTee: Given a certain node in the tree, searches the rest of the tree for equivalent subtrees, if one or more is found, the equivalent subtrees are deleted and a tee operator is created as the parent of the given node, which then forwards the results to the parents of those equivalent subtrees
Delete Tee: The opposite of create Tee
RedistributeAggDistinct: Moves a distinct aggregation to a lower level (below a gather), and adds a shuffle if needed
DedistributeAggDistinct: The opposite of redistributeAggDistinct
RedistibuteAggregation: The same as redistributeAggDistinct but for non-distinct aggregations
DedistributeAggregation: The opposite of redistributeAggregation
DeletePointlessSort: Deletes a pointless sort from the tree
DeletePointlessSwitch: Deletes a pointless switch from the tree (only happens if all of the extends the switch created were pushed out of the switch-union block)
DuplicateAggBelow Shuffles: Given an aggregation (including aggdistinct) with a shuffle as its child, create a copy of the aggregation below the shuffle and update the original to have the correct operations
RemoveAggBelow Shuffles: The opposite of duplicateAggBelow Shuffles
DuplicateLimit: Given a limit above a gather type operator, create a copy of it below the gather type operator
ExceptPushDown: Pushes an except operator down below all of its child, can only happen if they are all equivalent
ExceptPushUp: The opposite of exceptPushDown
ExceptUnionContract: Given an except with more than 2 children, take children [1, N-1] and make them the children of a union all, which becomes child 1 of the except
ExceptUnionExpand: The opposite of exceptUnionContract
ExtendPushDown
ExtendPush Up
IntersectPushDown: The same as exceptPushDown but for an intersect operator
IntersectPushUp: The opposite of intersectPushDown
JoinPushDown: Pushes a join down below its child(ren). Similar to except/intersectPushDown except with a few other cases. If one child is a join it instead swaps the joins, it also has to check that pushing below its children doesn't break the join (for example by creating name collisions or removing columns that needed to exist)
JoinPushUp: The opposite of joinPushDown, but with some more potential for optimizations. Specifically, if the parent is a select on equiJoin columns, the select can be pushed down to all children, or is the parent is a project and the join is a gdeJoin, then this deletes the join and its right subtree entirely
LimitPushDown
LimitPushUp
Make VectorDown
Make VectorPushUp
MatrixExtendPushDown
MatrixExtendPushI) own
MergeEquiJoins: Given two adjacent inner hash joins with no other filters, combine them into a single hash join with more children
SplitEquiJoins: The opposite of mergeEquiJoins
MergeExcept: Given two adjacent except operators, take the input to the lower one and make all of its children become children of the higher one
MergeIntersect: The same as mergeExcept but for intersect
Merge Tee: Given two adjacent tee operators, take delete the higher one and make its parent additional parents on the lower one
MergeUnion: The same as mergeExcept but for union
Merge Windows: Combine two adjacent window operators into a single one
OffsetPushDown
OffsetPushUp
ProjectOutPushDown
ProjectOutPushUp
PushAggBelowJoin: Duplicates an aggregation below a hash join, and updates the higher one accordingly
PushAggAboveJoin: The opposite of pushAggBelowJoin
PushAggBelowGdcJoin: Given an aggregation above a gdcJoin, this moves it below the gdcJoin if possible. Currently requires that the aggregation does not reference the gdc column at all, or only groups by it. More cases are possible
PushJoinBelowSet: Given a join where one if its children is a set operator, and moves the join below the set such that there are not multiple joins as the children of the set operator
PushSetBelowJoin: The opposite of pushJoinBelowSet
PushLimitintolndex: Pushes a limit operator into an index operator, this way the index knows to only output up to LIMIT rows
PushLimitIntoSort: Pushes a limit into a sort operator, which causes us to run a faster limitSort algorithm in the virtual machine (e.g., node or processing core resource)
PushLimitOutOfSort: The opposite of pushLimitInto Sort
PushProjectIntoIndex: Pushes a project into an operator, which causes a not read of a column. Used when start reading all columns in plan generation
PushSelectBelowGdcJoin: Given a select above a gdcJoin, where the select is filtering the compressed column, this converts the filter to a filter on the stored integer mapping of that column and moves the select below the join. For example, where coll=“hello” might be converted to where coll Key=42
PushSelectintoHashJoin: Given a select above a hash join, where the select filters on lhsCol=rhsCol, this creates additional equi join columns on the hash join
PushSelectOutOffiashJoin: The opposite of pushSelectintoHashJoin
PushSelectintoProduct: The same as pushSelectintoHashJoin but for product joins
PushSelectOut01Product: The opposite of pushSelectIntoProduct
RenamePushDown
RenamePushUp
ReorderPushDown
ReorderPushUp
SelectOutJoinNulls: Given a join that is joining on coll, if coll is nullable this creates a select below the join that has the filter where coll!=NULL
UnselectOutJoinNulls: The opposite of selectOutJoinNulls
SelectPushDown
SelectPushUp
SortPushDown
SortPushUp
SwapJoinChildren: Swaps the order of a joins children
SwitchPushDown: Given a switch operator, push it down over its child. In some cases, this causes copies of the child to become the switch's parents', and in others this causes that child to jump the entire switch union block and become the parent of the union associated with the switch
SwitchPushUp: The opposite of switchPushDown, but nothing jumps because the parents of the switch are inside the switch union block already. Also requires that all parents are equivalent
TeePushDown: Pushes a tee down below its child, causing that child to be copied for each parent of the tee
TeePushUp: The opposite of teePushDown, requires that all parents are equivalent
UnionDistinctCopyDown: Given a union distinct with gathers as its children, creates another 1 child union distinct as the children of those gathers
UnionDistinctCopyUp: The opposite of unionDistinctCopyDown
UnionPushDown: The same as exceptPushDown except for union, also handles the different rules that apply to union all and union distinct
UnionPushlJp: The opposite of unionPushDown, also handles the case where this is the opposite of switchPushDown because the union has an associated switch, so some operators will jump the entire switch union block
UnmakeVectorPushDown
UnmakeVectorPushUp
WindowPushDown
WindowPushUp
post-optimization options
Combining adjacent selects into super Selects
Combining adjacent limits
Combining adjacent offsets
Converting distinct aggregations into a non-distinct aggregation with a union distinct as its child
Duplicating union distincts around shuffles, this only happens if there is a union distinct on 1 side of a shuffle, but not both
Replacing index type operators with an eos operator if we can determine that the filters (if any) on the index are always false (possible by comparing possible values of data types)
Evaluating alternate indexes besides the primary index
Building orderedAggregations and orderedDistincts
Getting rid of pointless renames
Pushing sorts down to level 3 if possible
Creating indexCountStar operators if possible
Fixing out of order indexAggs, this makes the grouping key order match the primary index order when possible
Tee'ing leaf operators, this combines as many equivalent leaf operators as possible to reduce IO
Deleting pointless reorders

Note that the Down and push Up transforms are used frequently and mean to take the given operator and swap its position in the tree with its child (or parent) for most operators. Further note that not all of these transforms are legal in all possible cases, and they only get applied if they are legal.

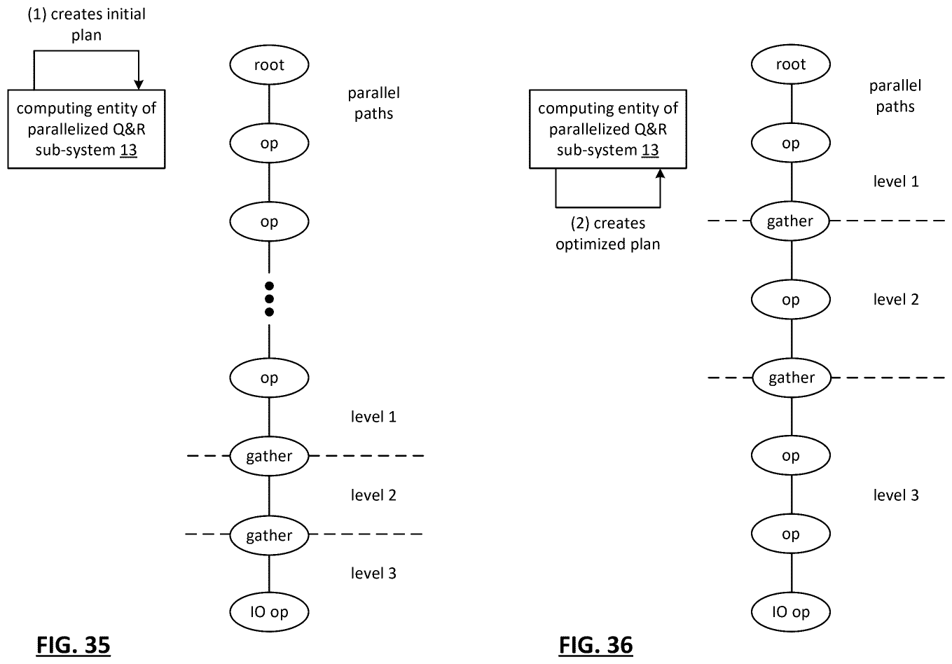

The method continues at step 163 where the query plan is executed to produce a query result. FIGS. 35-36 provide an example of optimizing a query plan.

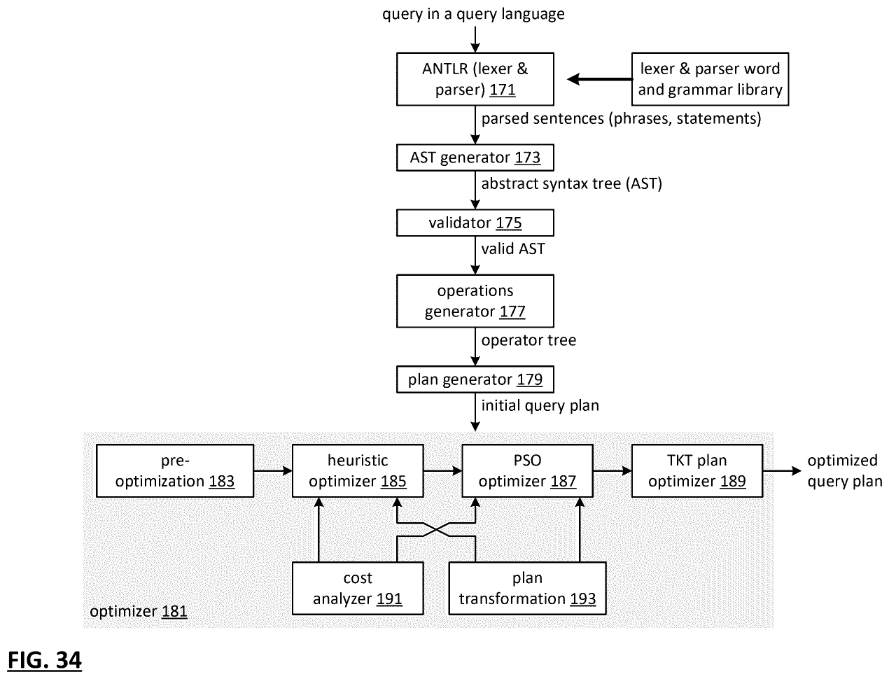

FIG. 34 is a logic diagram of another example of creating a query plan for execution within the database system that begins at step 171 where one or more processing core resources of a node, one or more nodes of a computing device, and/or one or more computing devices of the parallelized query & response sub-system (hereinafter referred to as a computing node for the discussion of this figure) performs a lexer function and a parsing function using ANTRL on a received query, which was received in a query language. The computing node executes steps 173-181 to produce a query plan.

FIGS. 35-43 are schematic block diagrams of an example of creating and distributing a query plan in the database system. FIG. 35 illustrates one or more processing core resources of a node, one or more nodes of a computing device, and/or one or more computing devices of the parallelized query & response sub-system (hereinafter referred to as a computing device for the discussion of FIGS. 35-43). The computing device creates an initial plan from a received query using one or more operators from a plurality of operators.

FIG. 35 illustrates an example of a computing device of the parallelized Q&R sub-system creating an initial plan from a received query. The initial query plan is created for execution by a computing device of the parallelized query & response sub-system. As created, the initial query plan is guaranteed to produce a result from the select table(s).

The initial plan includes a root operator, a plurality of operators (op), and one or more input/output operations (IO op). The query includes one or more parallel paths of execution. Accordingly, when the computing device is creating the initial plan, it is dividing the execution of the query plan into threads that can be executed relatively independently and without lock up. For the most part, the initial plan is executed at level 1 and the other levels have very few, if any, operations.

FIG. 36 illustrates the computing device optimizing the initial plan to produce an optimized plan. In general, an optimized plan still guarantees a result, just like the initial plan, but is optimized for efficiency of execution (e.g., efficient use of processing resources of the database system and speed in producing an answer). In this example, the computing device creates a plurality of a parallel paths and distributes execution of operations among three levels. Note that there may be more than three levels of execution.

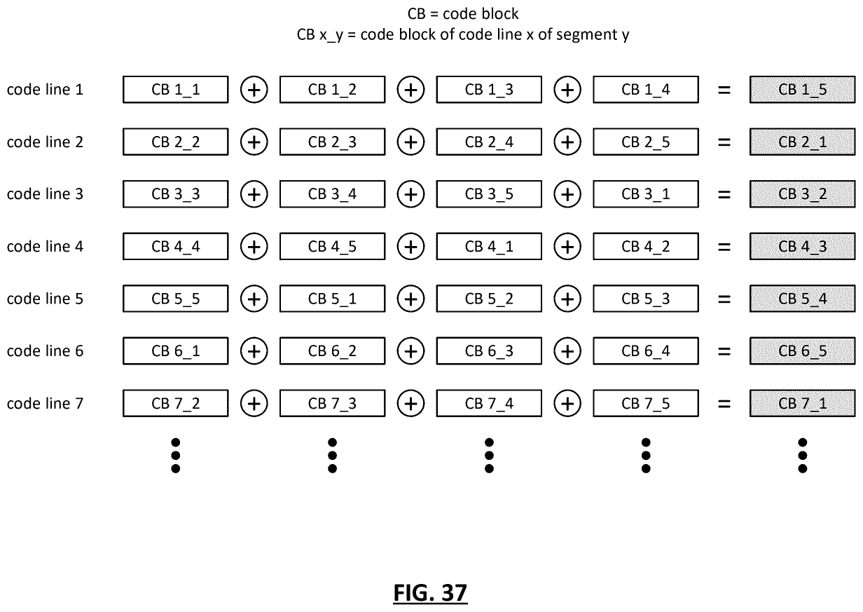

FIG. 37 is a schematic block diagram of an example of encoding a code line of data. Data is divided into groups of segments and segments are further divided into coding blocks (CBs). A parity calculation is done on the coding block level allowing for the smallest unit of data recovery (e.g., a coding block or data block, 4 Kbytes). In this example, data is divided into 5 segments where each segment is divided into a plurality of coding blocks. Four coding blocks from four of the data segments are arranged into a code line to calculate a fifth coding block (i.e., a parity coding block) based on a 4 of 5 coding scheme.

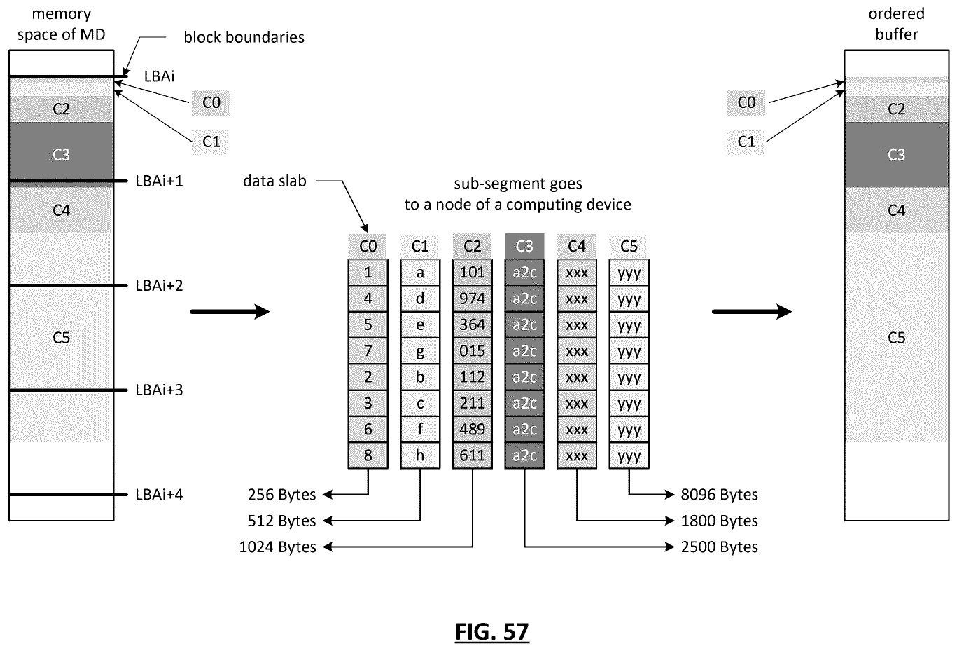

Because coding blocks of segments are stored in separate storage nodes, four coding blocks from different segments are used to create a parity coding block to be stored with coding blocks of the segment not used in the parity calculation. For example, in code line 1 a XOR operation is applied to CB 1_1 (coding block of code line 1 of segment 1), CB 1_2 (coding block of code line 1 of segment 2), CB 1_3, and CB 1_4 (coding block of code line 1 of segment 4) to create CB 1_5 (parity coding block of code line 1 of segment 5). As such, any combination of four code blocks out of five code blocks of a code line can be used to reconstruct a code block from that line. An example of coding blocks mapped to logical block addresses of a memory device of a node is described with reference to FIG. 57.

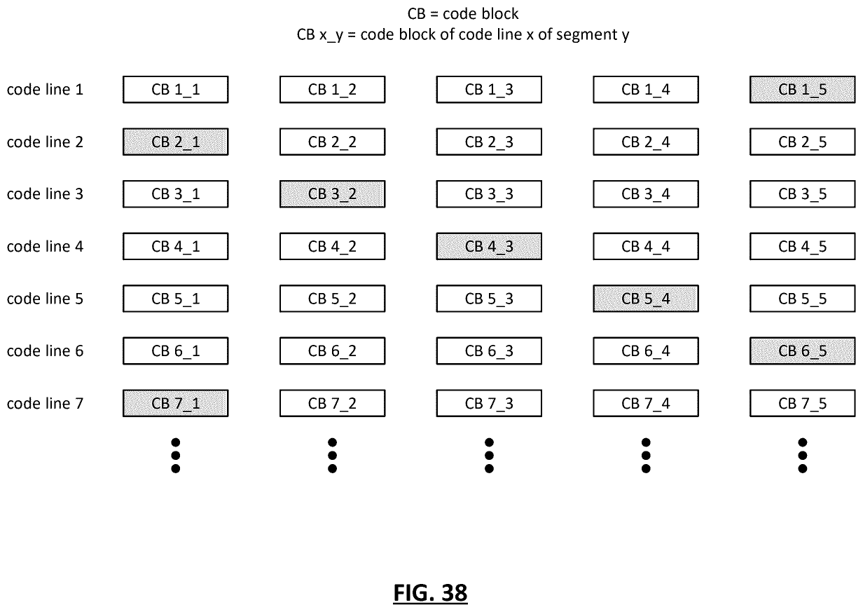

FIG. 38 is a schematic block diagram of an example of encoded code lines with distributed positioning of parity blocks. The parity coding blocks generated in the example of FIG. 37 (shown as shaded blocks) are distributed in accordance with a corresponding segment for storage. For example, parity coding blocks CB 2_1 and CB 7_1 are arranged with coding blocks of a first segment for storage in a first storage node, parity coding block CB 3_2 is arranged with coding blocks of a second segment for storage in a second storage node, parity coding block CB 4_3 is arranged with coding blocks of a third segment for storage in a third storage node, parity coding block 5_4 is arranged with coding blocks of a fourth segment for storage in a fourth storage node, and parity coding blocks CB 1_5 and CB 6_5 are arranged with coding blocks of a fifth segment for storage in a fifth storage node.

Using a dedicated parity storage node creates parity storage node bottlenecks for write operations. Therefore, distributing the parity coding blocks allows for more balanced data access and substantially fixes the write bottleneck issue.

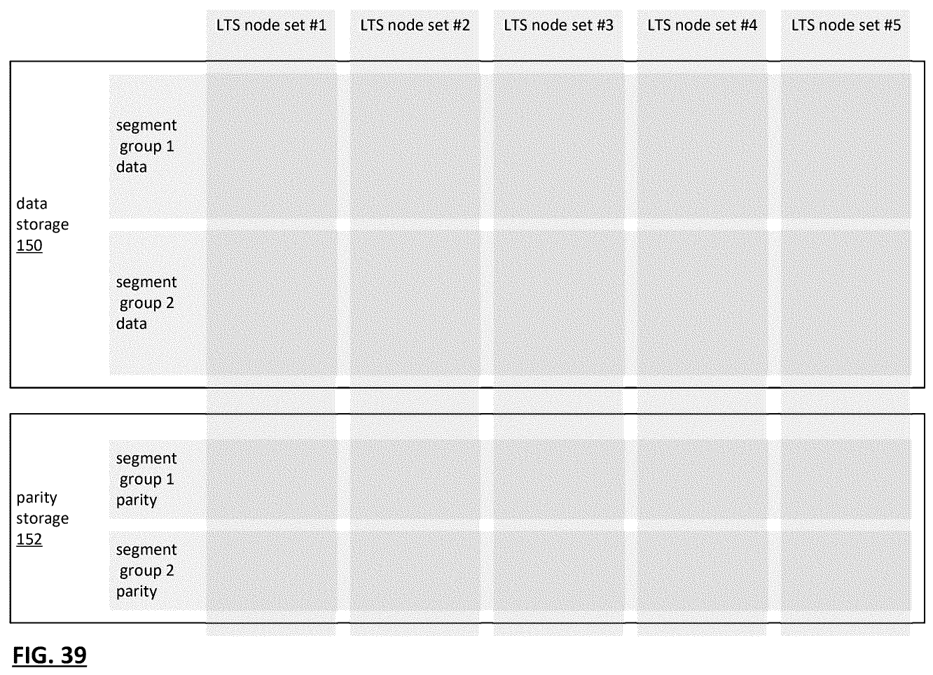

FIG. 39 is a schematic block diagram of an example of memory of a cluster of nodes and/or of computing devices having a data storage section and a parity storage section. Here, five long term storage (LTS) node sets (LTS node sets #1-5) are shown storing data that has been divided into five segments (e.g., each segment requires its own storage node) and further divided into pluralities of coding blocks and parity coding blocks. The data storage section may be divided into one or more sections for one or more segment groups. For example, the data storage section shown includes segment group 1 data section (e.g., data from a first segment group of five segments) and segment group 2 data section (e.g., data from a second segment group of five segments).

The parity storage section may also be divided into one or more sections for one or more segment groups. For example, the parity storage section shown includes segment group 1 parity section (e.g., parity from a first segment group of five segments) and segment group 2 parity (e.g., parity from a second segment group of five segments). Organizing the parity data in a separate storage section from the data within a storage node allows for greater data access efficiency. For example, parity data is only accessed when data requires reconstructing (e.g., data is lost, after a reboot, etc.). Other data access operations are achieved by simply accessing the data required from the data storage section.

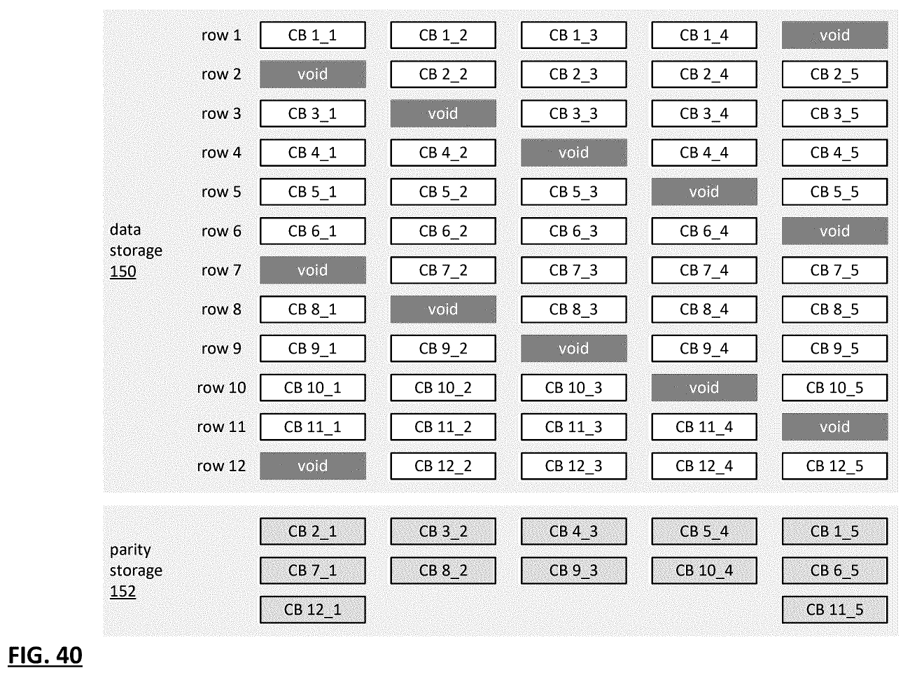

FIG. 40 is a schematic block diagram of an example of storing data blocks in a data storage section and parity blocks in a parity storage section, with empty spaces in the data storage section. Five storage node sets are shown storing data that has been divided into five segments (e.g., each segment requires its own storage node) and further divided into pluralities of coding blocks (CBs) and parity coding blocks. Moving parity coding blocks from the data storage section to the parity storage section (as discussed in FIG. 39) results in voids in the data section.

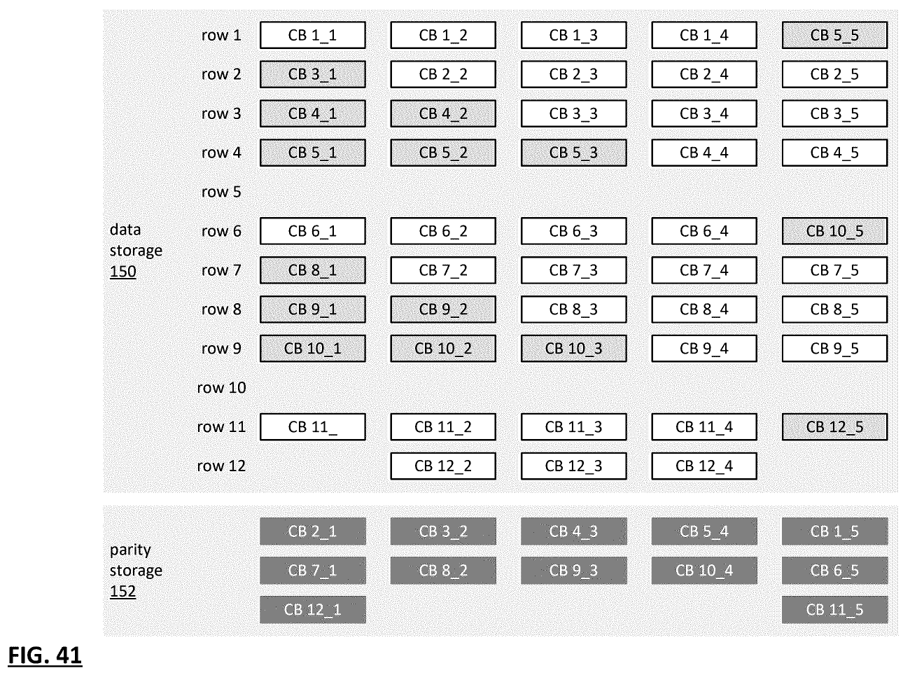

For example, parity coding blocks 2_1, 7_1, and 12_1 are moved from the first storage node to the parity storage section resulting in three voids in the data storage section as shown. Various ways to fill these voids in the data section are discussed in FIGS. 41-43.

FIG. 41 is a schematic block diagram of an example of filling the empty spaces in the data storage section of FIG. 40. In this example, voids in the data storage section are filled by pushing up coding blocks (CBs) in groups of five to use a minimal amount of moves to fill voids. For example, parity coding blocks 2_1, 7_1, and 12_1 are moved from the first storage node to the parity storage section resulting in three voids in the data storage section. CB 3_1-CB 5_1 are pushed up to form a group of five coding blocks (CB 1_1, CB 3_1, CB 4_1, and CB 5_1) and fill one void in the data section of the first storage node. CB 8_1-CB 10_1 are pushed up to fill another void.

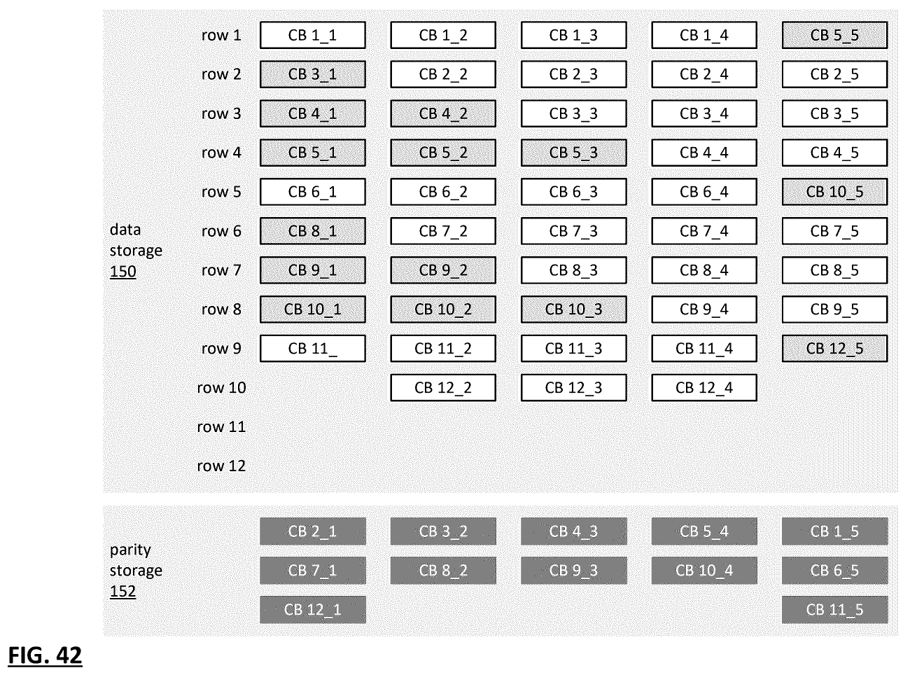

FIG. 42 is a schematic block diagram of another example of filling the empty spaces in the data storage section of FIG. 40. In this example, voids in the data storage section are filled by sliding coding blocks (CBs) up such that no voids are left in the data section. For example, to fill the voids in the data section of the first storage node, CB 3_1 through 6_1 are each slid up one space and CB 8_1 through CB 11_1 are each slid up two spaces.

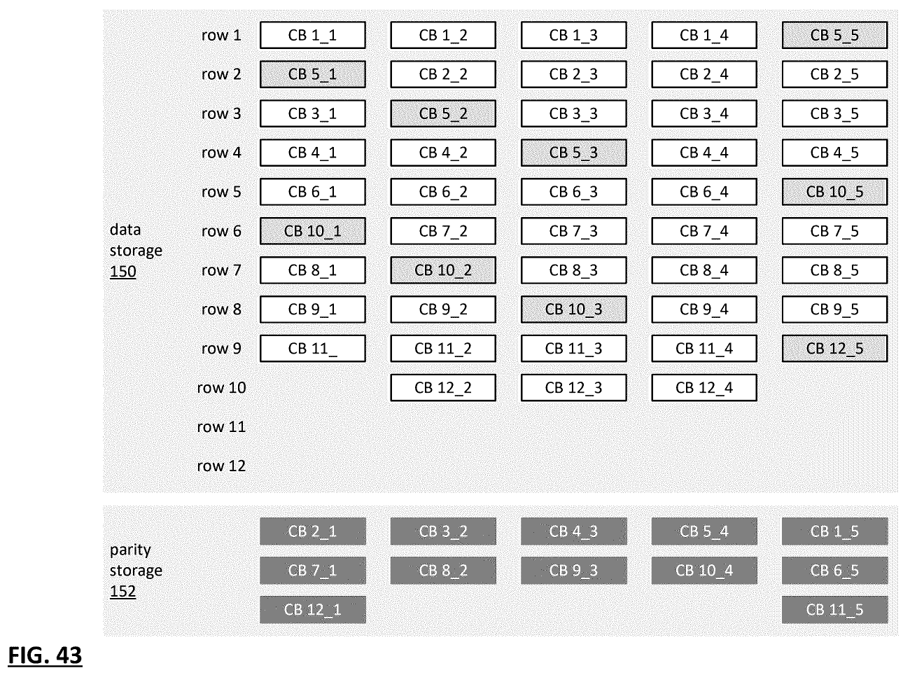

FIG. 43 is a schematic block diagram of another example of filling the empty spaces in the data storage section of FIG. 40. In this example, voids in the first four lines are filled with coding blocks from the fifth line. For example, the fifth line of coding blocks includes CB 5_1, CB 5_2, CB 5_3, and CB 5_5. CB 5_1 is used to fill the void between CB 1_1 and CB 3_1, CB 5_2 is used to fill the void between CB 2_2 and CB 4_2. CB 5_3 is used to fill the void above CB 2_5. A similar method occurs using data from the tenth line to fill voids between lines 6-9.

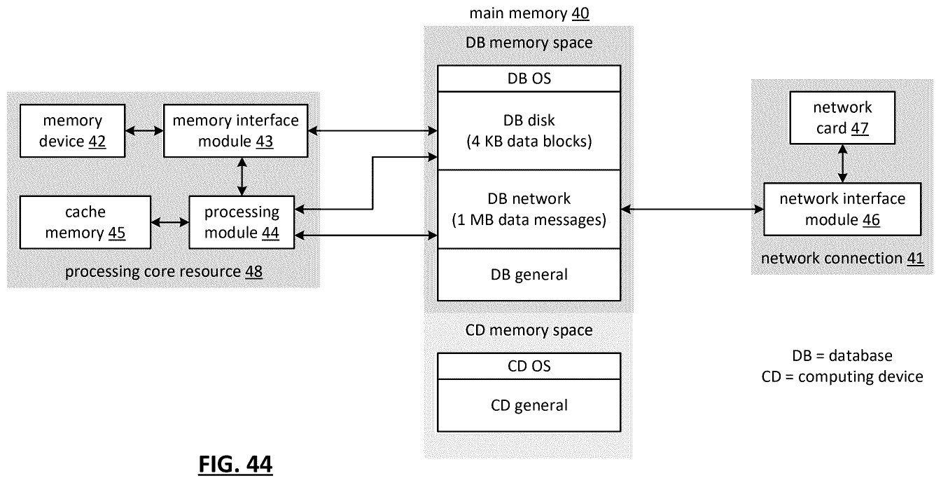

FIG. 44 is a schematic block diagram of an example of direct memory access for a processing core resource and/or for a network connection. Within a computing device, the main memory is logically partitioned into a database section (e.g., database memory space) and a computing device section (e.g., CD memory space). In an embodiment, the main memory is logically shared among the processing cores of the nodes of a computing device under the control of the database operating system. In another embodiment, the main memory is further logically divided by the database operating system such that a processing core resource of a node of the computing device is allocated its own main memory.

The database memory space is logically and dynamically divided into a database operating system (DB OS) section, a disk section, a network section, and a general section. The database operating system determines the size of the disk section, the network section, and the general section based on memory requirements for various operations being performed by the processing core resources, the nodes, and/or the computing device. As such, as the processing changes within a computing device, the size of the disk section, the network section, and the general section will most likely vary based on memory requirements for the changing processing.

Within the computing device, data stored on the memory devices is done in accordance with a data block format (e.g., 4 K byte block size). As such, data written to and read from the memory devices via the disk section of the main memory is done so in 4 K byte portions (e.g., one or more 4 K byte blocks). Conversely, network messages use a different format and are typically of a different size (e.g., 1 M byte messages).

To facilitate lock free and efficient data transfers, the disk section of the main memory is formatted in accordance with the data formatting of the memory devices (e.g., 4 K byte data blocks) and the network section of the main memory is formatted in accordance with network messaging formats (e.g., 1 M byte messages). Thus, when the processing module is processing disk access requests, it uses the disk section of the main memory in a format corresponding to the memory device. Similarly, when the processing module is processing network communication requests, it uses the network section of the main memory in a format corresponding to network messaging format(s).

In this manner, accessing memory devices is a separate and independent function of processing network communication requests. As such, the memory interface can directly access the disk section of the main memory with little to no intervention of the processing module. Similarly, the network interface can directly access the network section of the main memory with little to no intervention of the processing module. This substantially reduces interrupts of the processing module to process network communication request and memory device access requests. This also allows for lock free operation of memory device access requests and network communication requests with increased parallel operation of such requests.

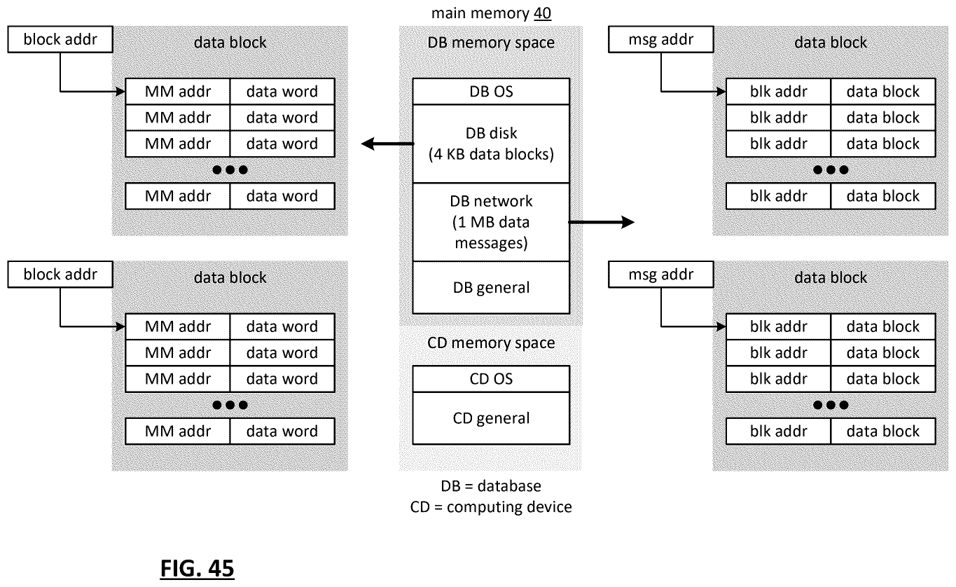

FIG. 45 is a schematic block diagram of an example of data blocks and data messages for direct memory access of a processing core resource and/or of a network connection. Data blocks include a block address that is a logical block address for system operations and corresponds to a physical address for data accesses. Each data block includes a plurality of data words, which range in size from 1 Byte to 32 Bytes or more. Each data word has an associated main memory (MM) address that, from a logical address perspective, are sequential offsets from the block address. For example, if each data word is the 32 Bytes and the data block is 4 K Bytes (actually 4,096 Bytes), there are 128 data words in a data block. The block address corresponds to the address of the first data word in the block. The other addresses in the block are the next sequential data word addresses corresponding to the next data words.

Accordingly, when a data block is written into the disk memory section of the database (DB) memory space, it is done so a data block with each data word having a sequential address. This facilitates direct memory access of the main memory by the memory devices via the respective memory interfaces.

Data messages includes a message address and a plurality of data blocks. Each data block has an associated block address. The block addresses are logical addressees and are sequential within a data message. The message address corresponds to the first data block address and the other data block addresses are a logical offset from the first. For example, a data message is 1 M Byte in size and includes 256 4 Kbyte data blocks. This message data structure within the network section of the main memory facilitates the network connection to have direct memory access.

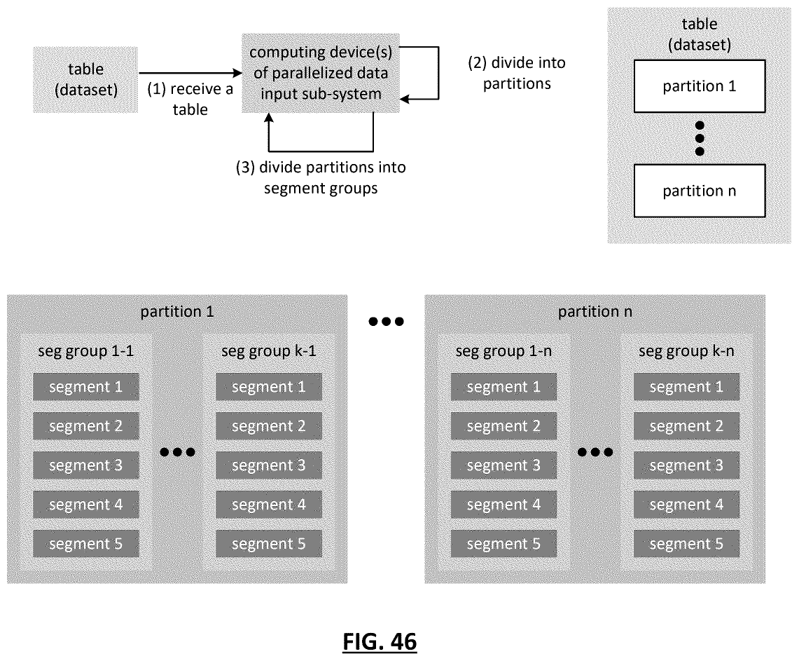

FIGS. 46-52 are schematic block diagrams of an example of processing a received data and distributed the processed table for storage in the database system. FIG. 46 illustrates one or more computing devices of the parallelized data input sub-system receiving a table. The computing device(s) divides the table into partitions. The computing device(s) divides each partition into one or more segment groups, with each segment group including a plurality of segments. An example of this was discussed with reference to one or more of FIGS. 20-22.

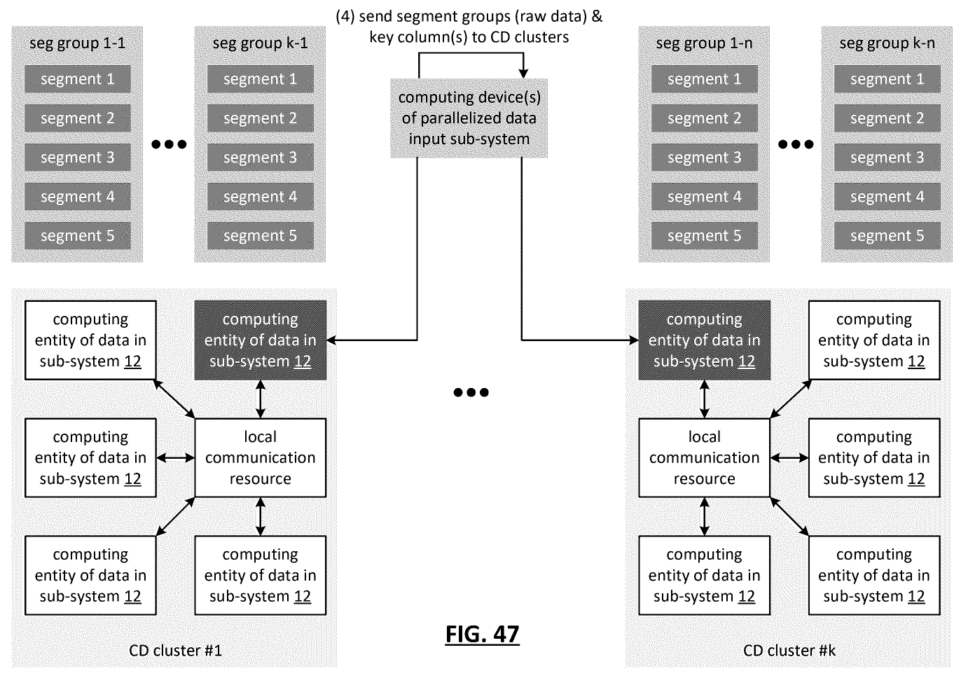

FIG. 47 illustrates the computing device(s) of the parallelized data input sub-system system selecting a level 2 (L2) computing entity from each computing device cluster to which a segment group is being sent. For example, the gray shaded box of computing device (CD) cluster 1 is the L2 computing entity for this cluster and the gray shaded box of CD cluster z is the L2 computing entity for cluster z.

The selection of the L2 computing entities can be done in a variety of ways. For example, the L2 computing entity is selected based on a pseudo random selection process. As another example, the L2 computing entity is selected in a round-robin manner. Having selected the L2 computing entities for each CD cluster, the computing device of the parallelized data input sub-system sends a corresponding segment group to each L2 computing device.

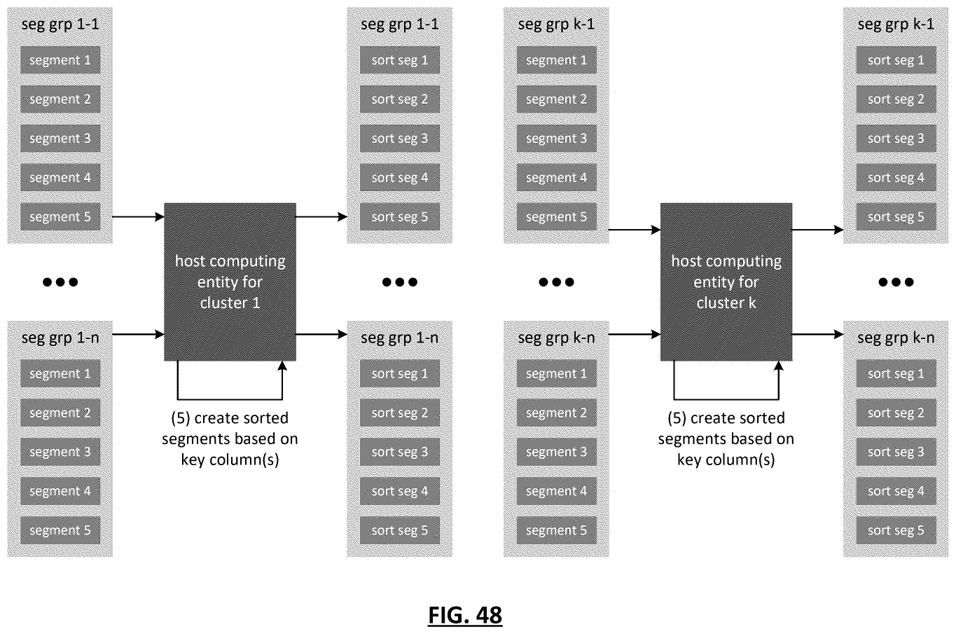

FIG. 48 illustrates each of the L2 computing entities sorting each segment of its segment group to produce a segment group of sorted segments. The sorting is based on one or more key columns. An example of sorting a segment was discussed with reference to one or more of FIGS. 23-26.

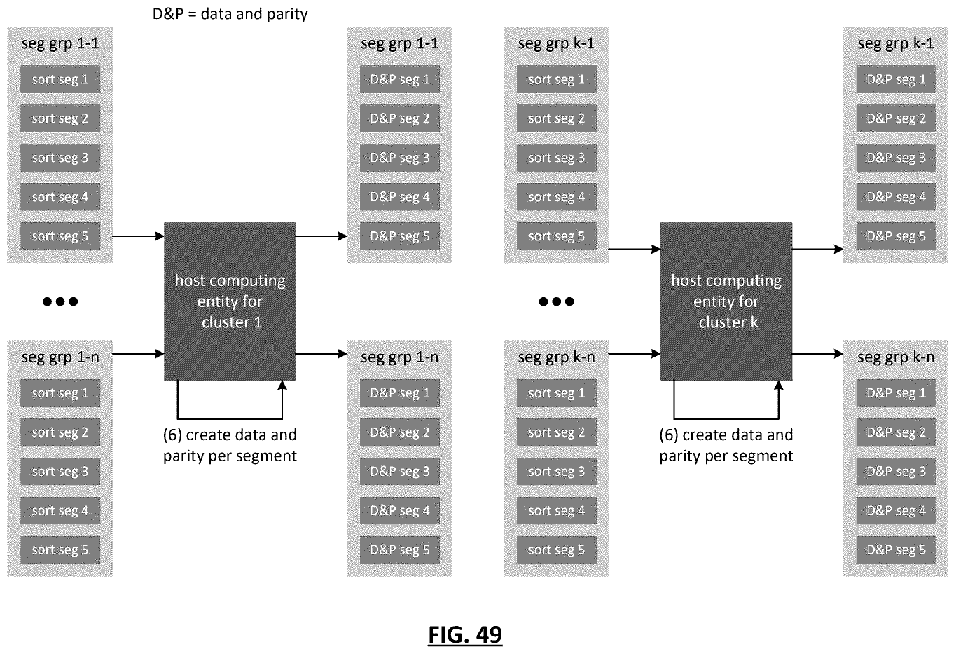

FIG. 49 illustrates the L2 computing entities creating data and parity segments from the sorted segments. In particular, the L2 computing entities executed a redundancy function to produce parity data from the raw data of the sorted segments. An example of creating the parity data was discussed with reference to one or more of FIGS. 37-43.

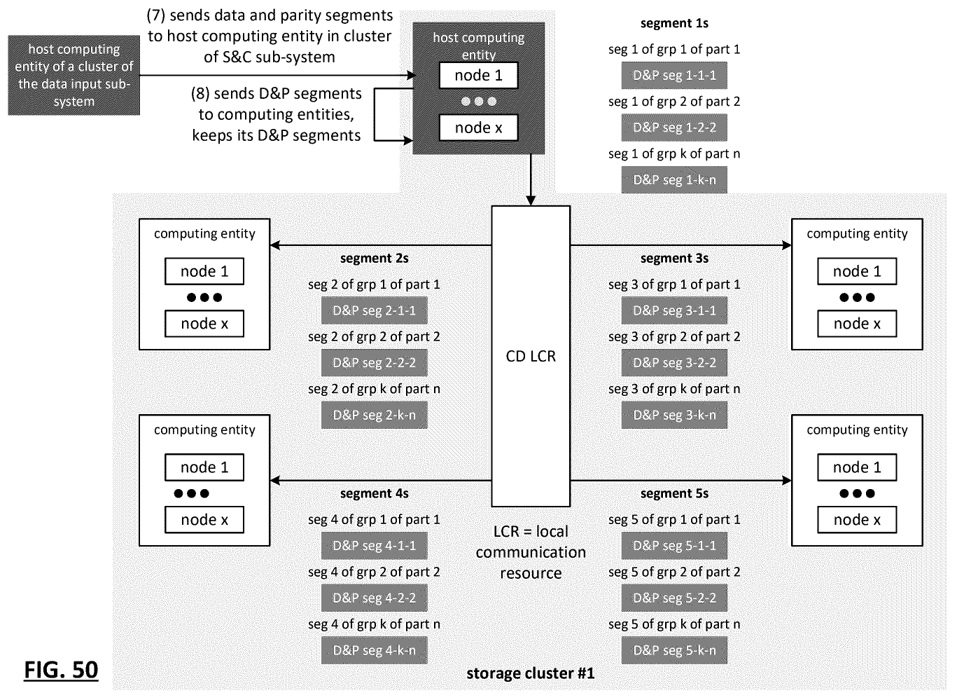

FIG. 50 illustrates a L2 computing entity within a storage cluster distributing the data & parity segments to the other computing devices within the storage cluster, including itself. Note that the data & parity segments also include a manifest section for metadata, one or more index sections for the key column(s), and may further include a statistics section.

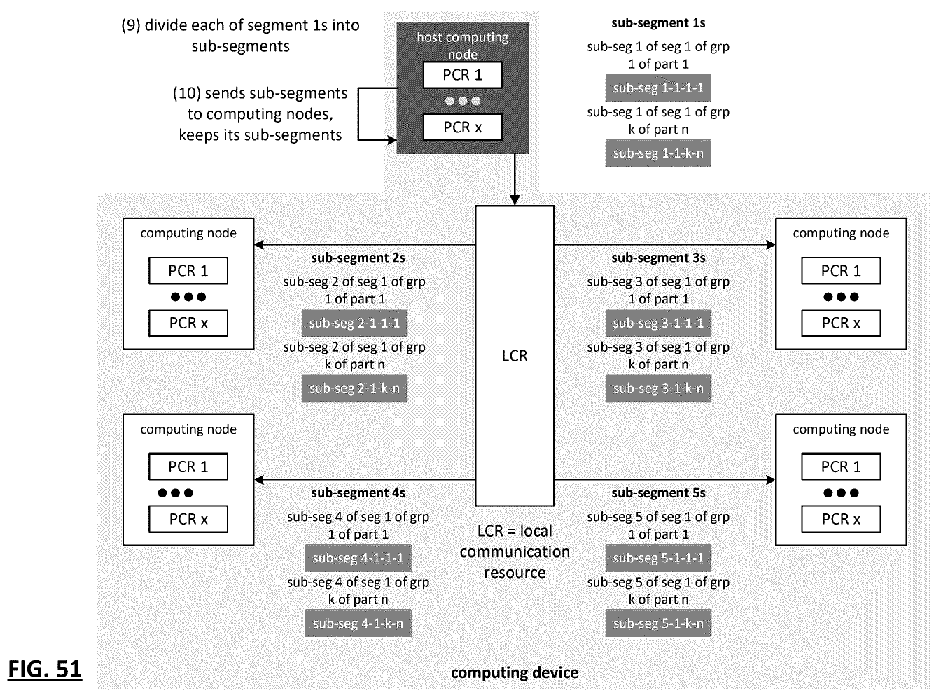

FIG. 51 illustrates a computing device within a cluster (at a third level L3) selecting a host node to initially process the received data & parity section. The host node (gray shaded box) divides the received segment into a plurality of segment divisions; one segment division per node within the computing device. The host node sends the segment divisions to the respective nodes of the L3 computing device.

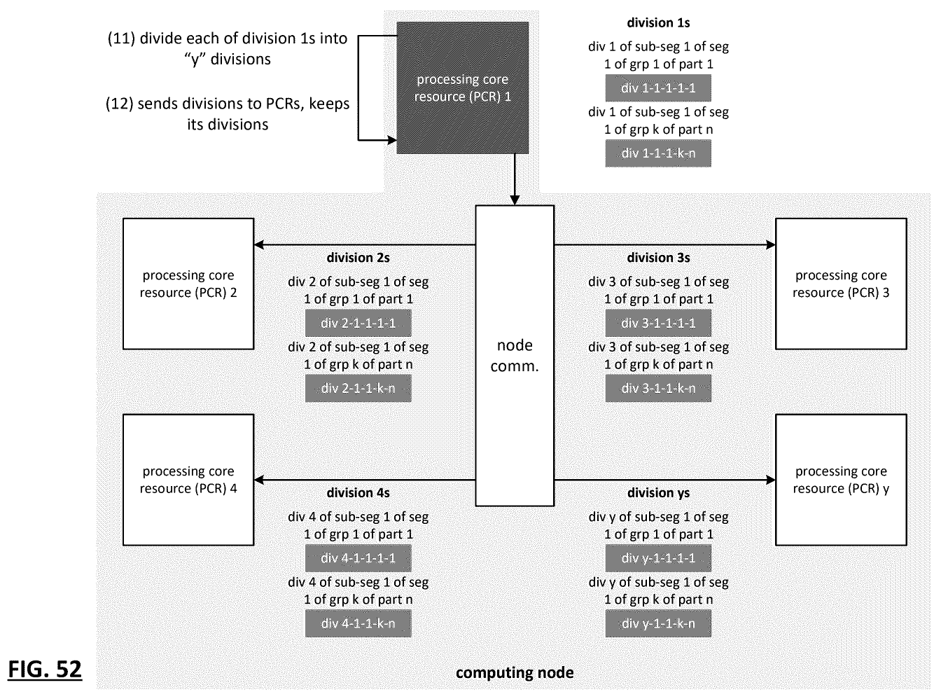

FIG. 52 illustrates a node of an L3 computing device selecting a host processing core resource (PCR) to process the received segment division. The host PCR further divides the segment division into a plurality of segment sub-divisions: one for each PCR in the node. The host PCR then sends the segment sub-divisions to the PCRs, including itself.

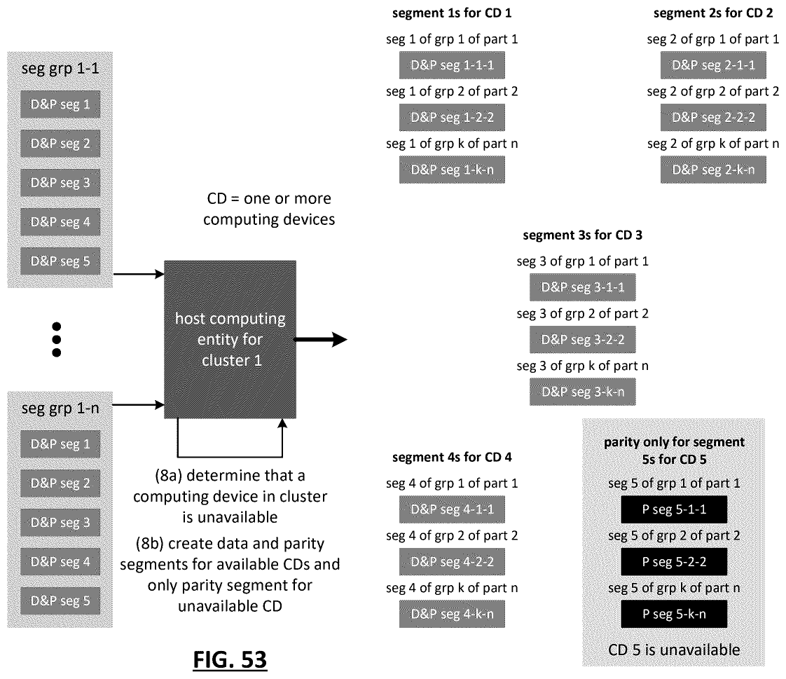

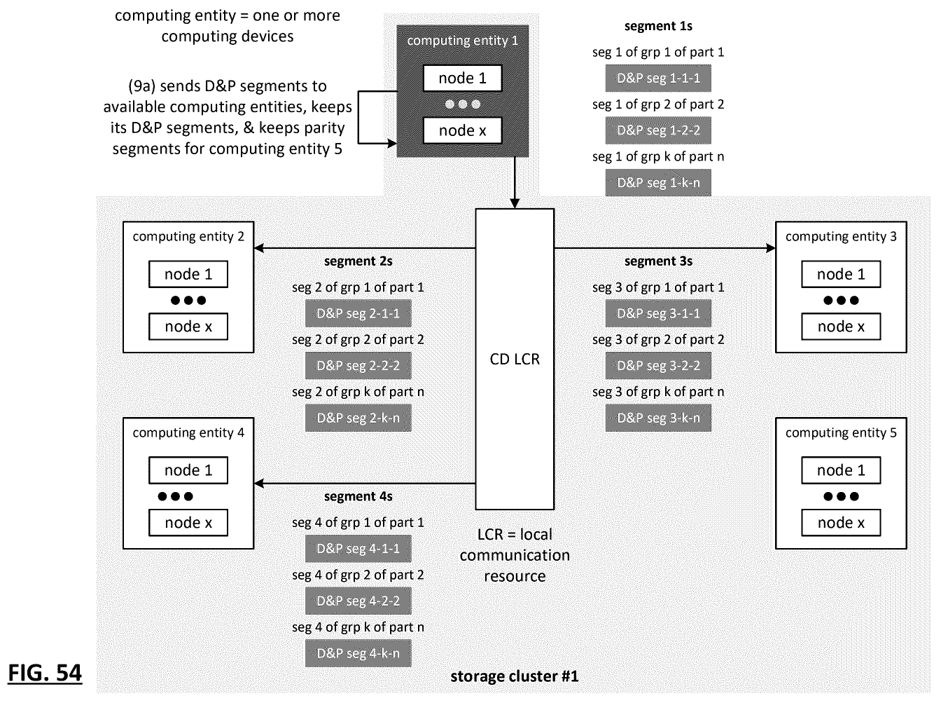

FIGS. 53-54 are schematic block diagrams of an example of processing a received data and distributed the processed table for storage in the database system when a computing device in a storage cluster is unavailable. As shown in FIG. 53, when this occurs, the host computing device (e.g., L2 computing device of a storage cluster or L1 computing device) reorganizes a segment group or creates a different type of a segment group. In either case, the resulting segment group (assuming 5 segments in the group) has four segments that include data and a fifth segment that only includes parity data.

FIG. 54 illustrates the host computing device sending the four data segments to the four active computing devices in the cluster and holds the parity segment for the unavailable computing device. When the unavailable computing device becomes available, the host computing device sends it the parity segment.

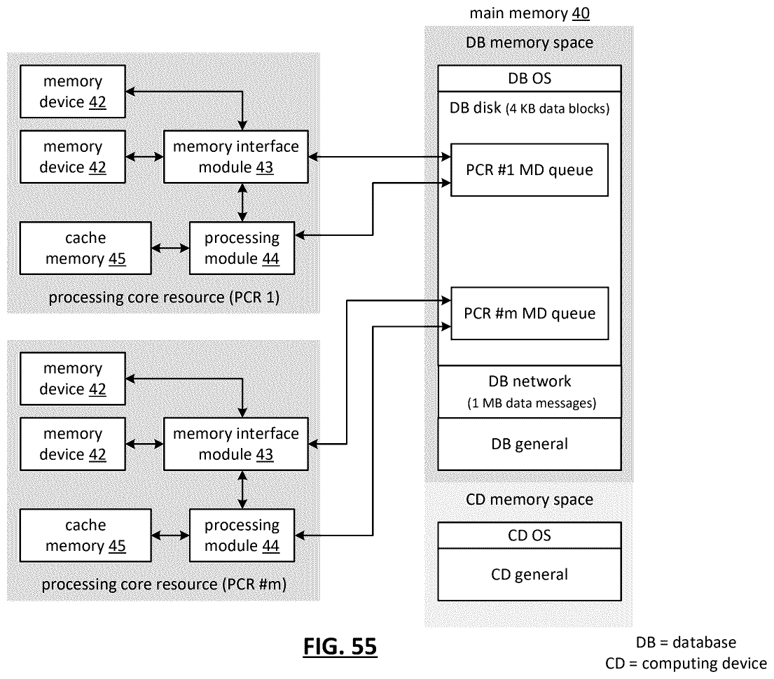

FIG. 55 is a schematic block diagram of an example of memory device (MD) buffer queues being allocated to memory devices of processing core resources of a node of a computing device. Under the control of the database operating system, the main memory of a computing device is divided into a database (DB) memory space and a computing device (CD) memory space. The DB memory space is generally and dynamically divided into a disk section, a network section, and/or a general section. Each of the sections may be further dynamically divided into buffers, queues, or other forms of temporary data storage containers. For the purposes of this figure, dynamically divided means that, in accordance with the DB operating system, a portion of the DB memory space is allocated to a node, a processing core resource (PCR), operation, and/or thread on an as needed basis.

In this example, queues are allocated to the memory devices of the processing core resources (PCR) of a node. As a specific example, the memory device (which includes one or more solid state non-volatile memory devices) of PRC #1 is allocated a queue called PCR #1 MD queue. The processing module of PCR #1 can write data into and read data from PCR #1 MD queue. The processing modules of the other processing core resources can read data from PCR #1 MD queue. In an embodiment, a processing module of another processing core (e.g., PCR #m) can write data to PCR #1 MD queue.

As a specific example, the memory device (which includes one or more solid state non-volatile memory devices) of PRC #m is allocated a queue called PCR #m MD queue. The processing module of PCR #m can write data into and read data from PCR #m MD queue. The processing modules of the other processing core resources can read data from PCR #m MD queue. In an embodiment, a processing module of another processing core (e.g., PCR #1) can write data to PCR #m MD queue.

Data is written into and read from the PCR memory device (MD) queues in a format and/or data word size that corresponds to the format and/or data word size of the memory devices. For example, data is stored as pages (i.e., a contiguous block of physical memory) in the memory devices. Accordingly, data is stored in the MD queues in the same sized pages (e.g., 4 Kbytes). By using the same size, the memory interface modules of the processing core resources can directly access the PCR MD queues. In this manner, the queues are pinned memory and improves read and write efficiencies between the memory devices of the processing core resources and main memory by eliminating reads and writes having to be processed by the processing module of the processing core resources. Such processing typically included a format change (e.g., a data size change from one data size to another).

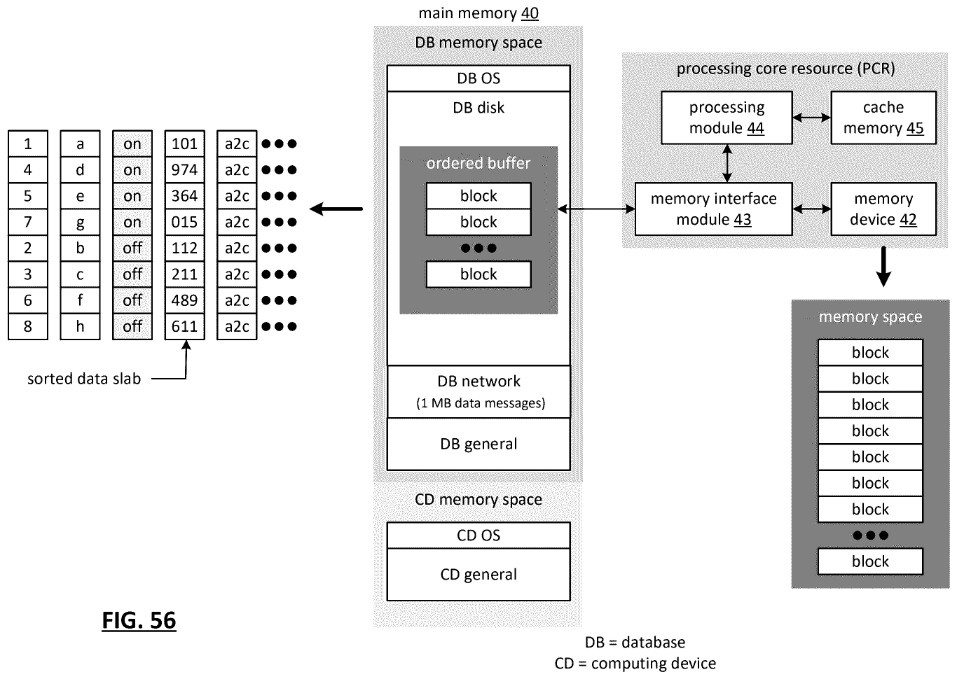

FIG. 56 is a schematic block diagram of an example of a read operation to read data from memory space of a non-volatile memory device into an allocated buffer of main memory. The processing core resource includes a processing module, cache memory, a memory interface module, and memory device(s) as previously discussed. Data is stored in the memory device in data blocks. Each data block is of a fixed size (e.g., 4 K Bytes). When data is read from the non-volatile memory device and written into an allocated buffer of the main memory, it is desirable to have it done with as minimal reads as possible and to have the data in the allocated buffer of the main memory in an ordered manner.

In an example, data is stored as ordered data slabs of a segment of a segment group of a partition of a table. In general, an ordered data slab is a sorted column of the segment of the segment group of the partition of the table. The entries in a sorted data slab are of a fixed size and/or of a varying size. For example, the data value entry is in the range of 1 byte to 32 bytes or more.

FIG. 57 is a schematic block diagram of another example of a read operation to read data from memory space of a non-volatile memory device into an allocated buffer of main memory based on logical block addresses (LBA). In this example, the non-volatile memory device is segregated based on logical block addresses (LBAi, LBAi+1, LBAi+2, LBAi+3, LBAi+4, and so on). The sorted data slabs are referenced as columns C0 through C5. Each column has a differing total amount of data. For example, column 0 has 256 bytes of data, column 1 has 512 bytes of data, column 2 has 1024 bytes (e.g., 1 KB) of data, column 3 has 2500 bytes of data, column 4 has 1800 bytes of data, and column 5 has 8094 (8 KB) bytes of data.

The amount of memory space for each column is represented in the memory space of the memory device (MD) as hashed lines. As shown, columns 0-2 are completely within logical data block LBAi. Column 3 is in two logical blocks, LBAi and LBAi+1. Column 4 is completely within logical block LBAi+1. Column 5 is in three logical blocks LBAi+1, LBAi+2, and LBAi+3.

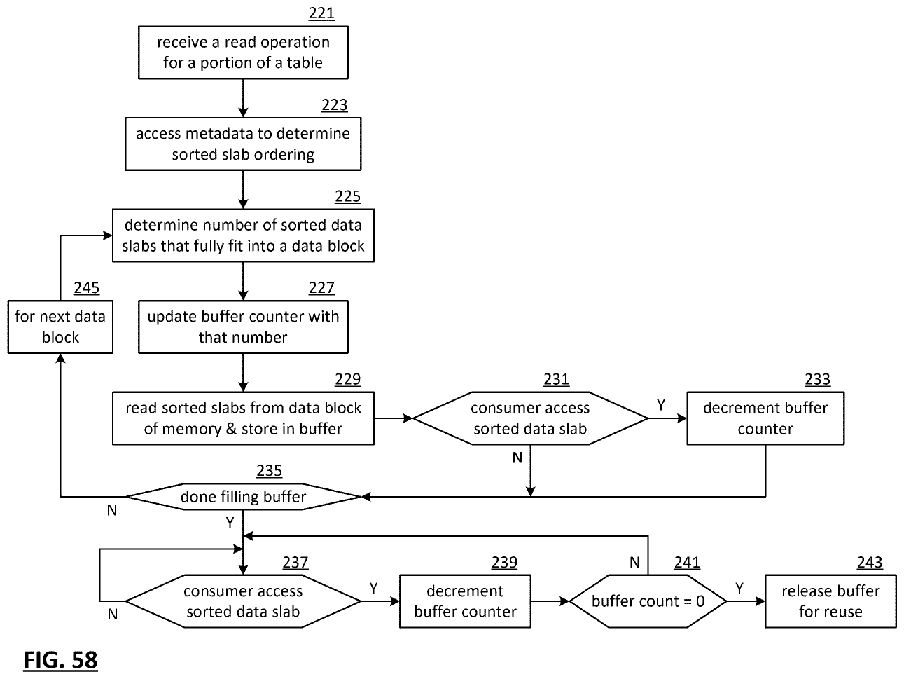

A straightforward read approach would be to read each column independently. For this example, that would be six reads. Within the six reads, logical block LBAi would be accessed four times: once for each of columns 0-3: logical block LBAi+1 would be accessed three times: once for each of columns 3-5; and logical blocks LBAi+2 and LBAi+3 would be accessed once for column 5. To improve the efficiency of reading columns 0-5, each logical block LBAi, LBAi+1, LBAi+2, and LBAi+3 would be read from once in a given order to preserve the ordering of the columns. FIG. 58 illustrates a method for efficient reading of columns from logical block of memory devices.

FIG. 58 is a logic diagram of another example of a method for a read operation to read data from memory space of a non-volatile memory device into an allocated buffer of main memory based on logical block addresses (LBA). The method begins at step 221 where a processing core resource receives a read operation for a portion of a table (e.g., a plurality of sorted data slabs corresponding to a segment of a segment group of a partition of a table). The method continues at step 223 where the processing core resource accesses metadata regarding the portion of the table to determine an ordering of the sorted data slabs.

The method continues at step 225 where the processing core resource determines a number of sorted data slabs that fully fit in a logical data block. For example, and with reference to FIG. 58, columns 0-2 fully fit in logical block LBAi. The method continues at step 227 where the processing core resources updates a buffer count with that number. For example, the buffer count is updated to add 3 to its previous count value for columns 0-2 of LBAi.

The method continues at step 229 where the processing core resource reads the sorted data slabs that are fully within a logical block of a memory device and stored them in the allocated buffer of main memory. The method continues at step 231 where the processing core resource determines whether a consumer of a sorted data slab, or slabs, has read it/them from the allocated buffer. If so, the method continues at step 233 where the processing core resource decrements the buffer counted by the number of sorted data slabs read from the allocated buffer by the consumer (e.g., another operation executed by the processing core resource or by another processing core resource).

If a consumer does not access a sorted data slab or the buffer count has been decremented, the method continues at step 235 where the processing core resource determines whether all of the requested data slabs have been read from the memory device. If not, the method continues at step 245 for the next logical data block and the method repeats at step 225. With reference to FIG. 58, the next logical block is LBAi+1, which includes the rest of column 3, all of column 4, and a first portion of column 5. Per step 227, the processing core resource updates the buffer count with the number of complete columns (e.g., sorted data slabs) being read. In the example of FIG. 58, the buffer count is incremented by 2.

These steps are repeated to read column 5 into the buffer and the buffer count is incremented by 1. For this example, to read six columns, only 3 reads of the memory device were performed. The first to retrieve columns 0-2, the second to retrieve columns 3 and 4, and the third to retrieve column 5. The buffer count is used to keep the allocated memory space of the main memory for this read operation sequence.

When all of the columns have been read from the memory device for the read operation sequence, the method continues at step 237 where the processing core resource determines whether a consumer has accessed (e.g., read) a sorted data slab from the buffer. If so, the method continues at step 239 where the processing core resource decrements the buffer count for each sorted data slab accessed from the buffer.

The method continues at step 241 where the processing core resource determines whether the buffer count equals 0. If not, the method repeats at step 237. If the buffer count equals 0, then the method continues at step 243 where the processing core resource releases the allocated memory of the main memory (e.g., deletes the buffer) for reuse.

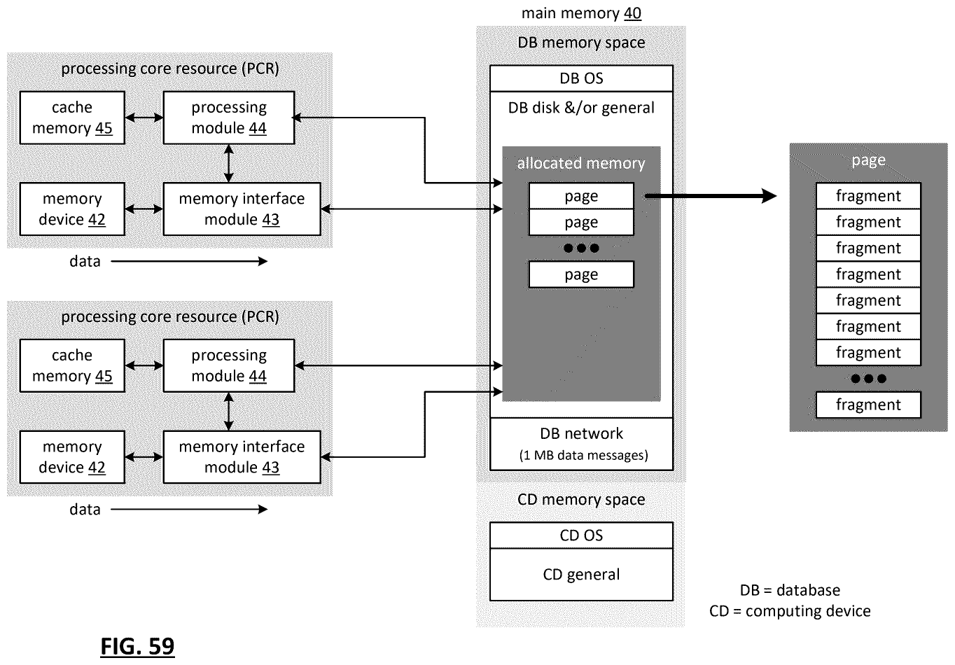

FIG. 59 is a schematic block diagram of an example of allocated memory of main memory being allocated to read data from processing core resources. The processing core resource includes a processing module, cache memory, a memory interface module, and memory device(s) as previously discussed. Data is stored in the memory device in pages of data blocks. For example, a page is of a selectable size (e.g., 4 KB to 2 GB). In an embodiment, a page size is selected to be 1 or 2 G bytes. When data is read from the non-volatile memory device and written into an allocated buffer of the main memory, it is desirable to have it done with efficiency in use of memory space and stored in a manner for ease of access for subsequent operations.

In this example, a portion of the DB (database) memory space is allocated for storing data read from the memory devices of the processing core resources. The allocated memory is of sufficient size to store a plurality of pages of data. To facilitate efficient storage and ease of use, each page is divided into fragments (e.g., 4 fragments per page or another number of fragments per page). In addition, it is desirable to avoid deadlocks with the data being stored in the allocated memory. To accomplish deadlock avoidance, efficiency of storage, and/or ease of use, single producer single consumer (SPSC) buffers are used between each virtual machine (VM, which is a processing core resource, a portion thereof, and/or multiple processing core resources).

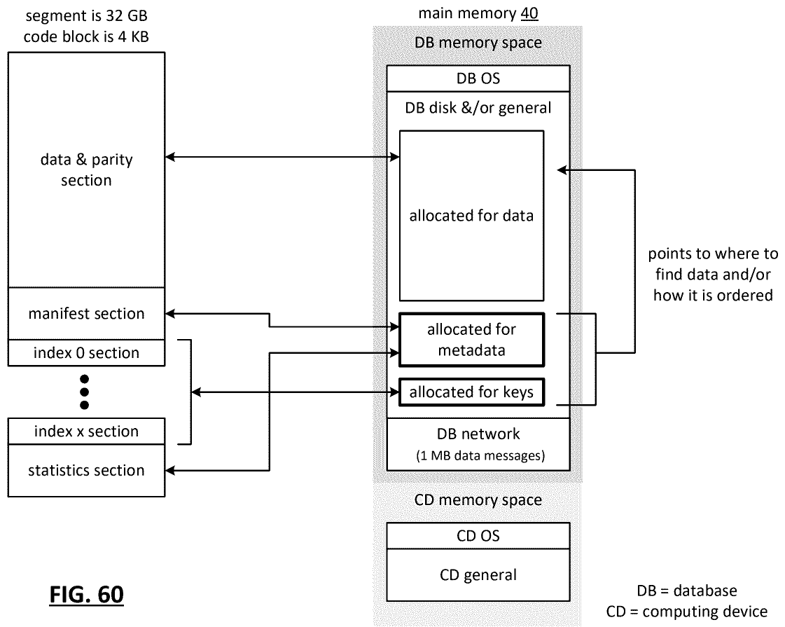

FIG. 60 is a schematic block diagram of an example of using allocated memory of main memory for manifest data and/or index data of a data segment associated with a processing core resource. Data segments, such as the data segment depicted on FIG. 60 are the fundamental building block for data storage, where the segment (in this example 32 GB) is divided into coding blocks of, for example 4 KB, as illustrated in FIGS. 26 and 27 and related text. Each data segment includes a data & parity section, a manifest (or metadata) section, and multiple index sections 0 through x, along with a statistics section where appropriate. Main memory, which can be random access memory (RAM) or any other suitable cache memory structure, is associated with each node, or can alternatively be associated with a plurality of nodes and is shown as an allocated memory resource. Specifically, the main memory may be allocated to provide defined space for the example elements of a database system, including memory space allocated for data, memory space allocated for metadata, and memory space allocated for keys, such as, for example the keys of the selected key column illustrated in FIG. 23.

When the main memory is not large enough to store all the metadata and key data for the associated data and parity of a data segment the metadata allocation and key data allocation in main memory can be used to point to the location of the data (along with the data ordering methodology) in a given data segment. The allocated memory illustrated for manifest data and/or index data of a data segment can be incorporated at a processing core resource, as shown, and/or at a computing device level and/or node level.

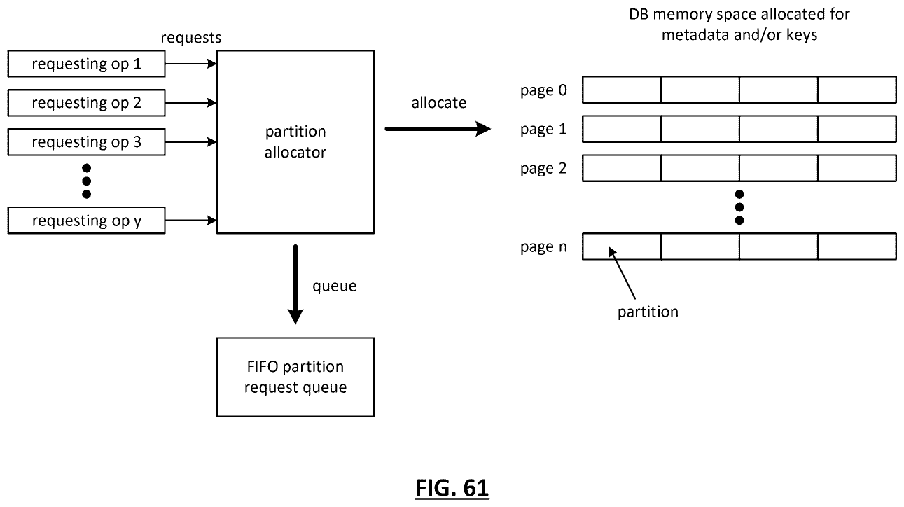

FIG. 61 provides a schematic block diagram of an example of a partition allocator allocating partitions of the allocated memory of main memory to requesting operations. Operations running on processing cores and or nodes (shown as requesting op 1 through requesting op y) execute requests over the network to one or computing devices associated with the database system. The computing devices include one more modules adapted as a partition allocator for the database memory, in order to process the requests in an ordered fashion. The partition allocator is further adapted to create a queue for the requests. The example shown illustrates a FIFO partition request queue; other alternatives include any queue that can be used to order the execution of requests from requesting entities.

Once the queue is created database memory space is allocated for the metadata and/or keys as discussed with regard to FIG. 60 above. In the example shown the database memory is divided into a plurality of pages (shown as pages (through page n). In an example there are a variable number of partitions defined for each page. For example, a page could be defined as a 1 gigabyte (GB) memory space with a partition size of 256-megabyte (MB) to render four (4) partitions per page. In an example page size can be selectable within any practical limit, and the number of partitions in each page can be selectable in a like manner.

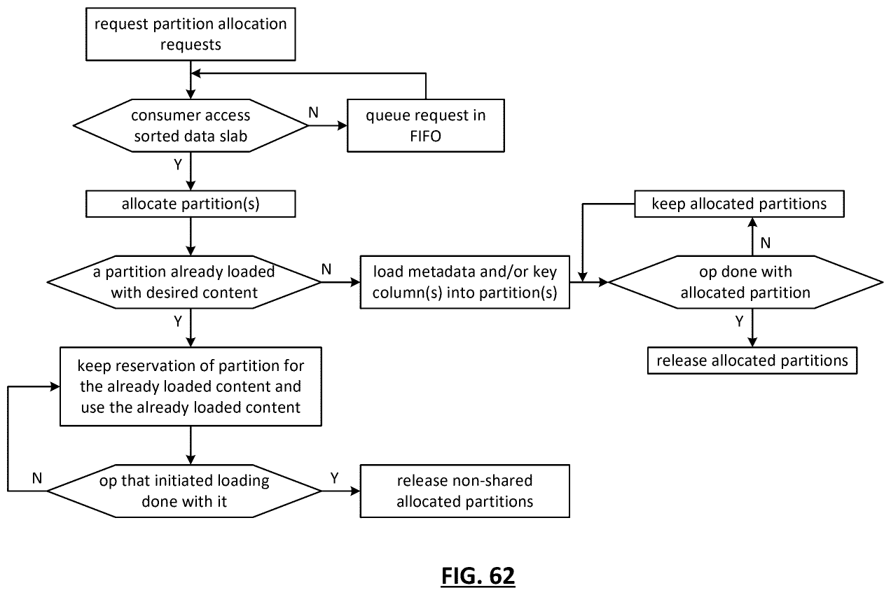

FIG. 62 is a logic diagram of an example of a method of allocating partitions of the allocated memory of main memory to requesting operations. In an example, the partition allocator of FIG. 61 receives partition allocation requests based on operations running on processing cores and or nodes. The requests can be in response to a query initiated by the computing device receiving the request, or they may be initiated based on the operations themselves. Each operation responsible for a request will know how many partitions will be required based on the size of the metadata and/or keys it is retrieving from the database. Considering a single request received at the computing device, once the request is received at a next step the computing device determines whether enough partitions are available. The computing device can determine whether the partitions are available based on prior knowledge and/or based on whether any requests are currently held in a partition queue, such as a FIFO queue. For example, if a FIFO queue has been created and already includes a previous request the computing device will determine that sufficient partitions are not available to service the request. In this case the request is queued in the FIFO queue in a step where the request is cycled through to the previous step.

If enough partitions are available the computing device allocates partitions at the next step determines whether a partition has already been loaded with the desired content, where the content is the metadata for an associated data segment and/or a portion of the key column(s) for the associated data segment. If a partition has not already been loaded with the desired content the metadata and/or key column(s) are loaded into the identified partitions at a next step. At a next step the computing device determines whether the operation is executed with the allocated partitions, and when it is at a next step the computing device releases the allocated partitions for use by another operation. When the operation is not executed with the allocated partitions at a next step the computing device ensures that the allocated partitions are maintained until the operation is executed or times out. Each operation requesting a partition is required to guarantee that the associated request can be either executed or that progress can be made toward execution so that the partition will not be deadlocked.

Additionally, a duty cycle can be established whereby on a regular interval each operation with one or more partitions that have been allocated are released and the operation associated with the request will initiate new partition requests for the same content. In such a case already allocated data can remain in main memory. The duty cycle can be based on a “deadlock avoidance” contract that all operations follow in order to ensure that nonperforming operations release allocated partitions on a regular interval in order to avoid locking up memory partitions and thereby decreasing performance of database operations.

When a partition has already been loaded with the desired content the method continues at a next step, where the computing device retains the partition(s) for already loaded content and the content is used for execution by the associated requestor(s). At a next step the computing device determines whether the operation that initiated the partition allocation has been executed and when the operation has been executed the computing device releases the allocated partitions in main memory at a next step, as long as the partitions are not shared with another request and/or operation. When the computing device determines that the operation has not completed execution associated with the underlying request, the computing device retains the allocated partition until the execution is complete.

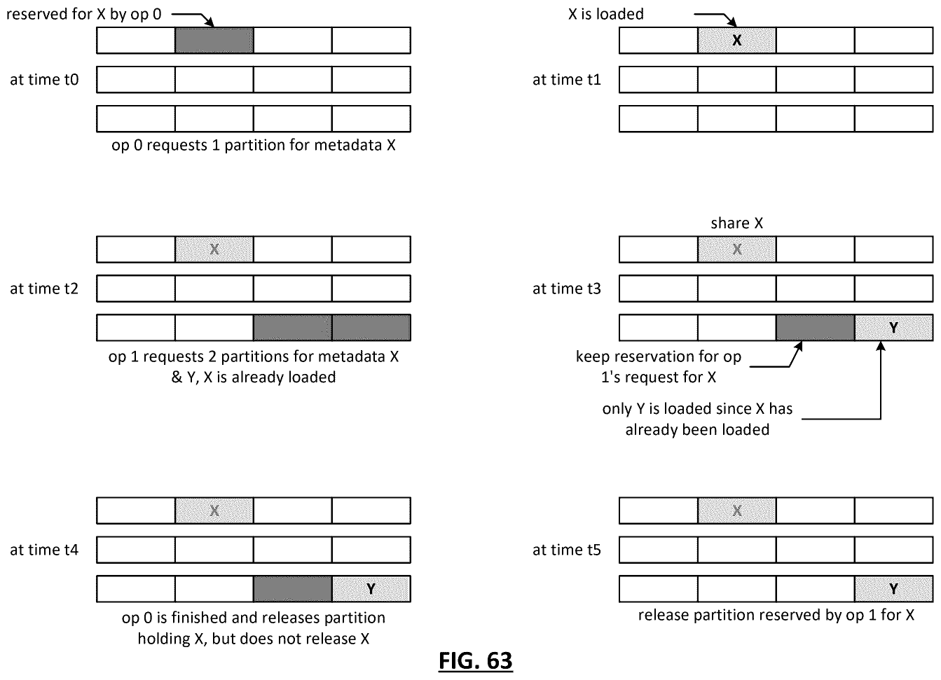

FIG. 63 is a schematic block diagram of another example of a partition allocator allocating partitions of the allocated memory of main memory to requesting operations. In an example at time to a single partition is reserved by an operation (op 0) for particular content, in this case metadata X. At time t1 metadata X has been loaded in main memory for the requesting operation. At time t2 another operation (op 1) requests two (2) partitions to be allocated for each of metadata X, which has already been loaded and metadata Y. At time t3 op 0 and op 1 share the already loaded metadata X and metadata Y is loaded (metadata X is not loaded again, since it has already been loaded) and the reservation for op 1 request for metadata X is maintained.

At time t4 op 0 has completed execution of the operation for which metadata x was loaded and releases the allocated partition for metadata X, but metadata X is not released, because op 1 may still be using it. At time t5 both op 0 and op 1 are complete, so the partition reserved by op 1 for X is released.

FIG. 64 is a schematic block diagram of an example of compressing data. Conventional data compression can disturb the structure of raw data, which negatively affects database processing for the data by, for example eliminating the address for the data. FIG. 64 illustrates a form of compression to allow for more efficient processing in a massively parallel database system. Uncompressed data slab k (and data slab k+1) is a column of a table that has been sorted based on a key, such as the table illustrated in FIGS. 23 through 25. In an example each data slab includes 156 32-byte data values, however data slabs can be of any reasonable size and include any reasonable number of data values. In an example, logical data block addresses (LBAs) are assigned. Each uncompressed sorted data slab could be each of a portion of a logical block address (LBA), aligned with a LBA, or in an example a given uncompressed sorted data slab could span a plurality of LBAs. In an example an uncompressed sorted data slab could span thousands of LBAs.

Each LBA includes a number of fixed size data fields positioned within the LBA. In an example LBAi through LBAi +x (e.g., LBAi through LBAi+1) includes 27 (128) positions and each block of data includes 4,096 positions. In practice, the number of positions, data value, and data fields can be any reasonable value. In the example of FIG. 64 uncompressed data slabs k and k+1 are compressed and compression information can be included at the front or rear of to create compressed sorted data slabs k and k+1 along with compressed sorted data slabs n and n+1 etc. to produce 128 positions of compressed data for LBAi. A footer at the end of LBAi can include at least one of a) raw uncompressed data: 2) null elimination and run length encoding (RLE) information: 3) RLE alone: 4) identity of data included within the block: 5) a count of compressed blocks stored in block: 6) the size of a compressed data slab: 7) size of compression information: and 8) a number of entries in compression information. The footer can be of varying size and can include information indicating why it is a footer. Additionally, the footer may consume one or more of the data value fields (e.g., field 127, 126, etc.) instead of being appended to the 128 position LBA.

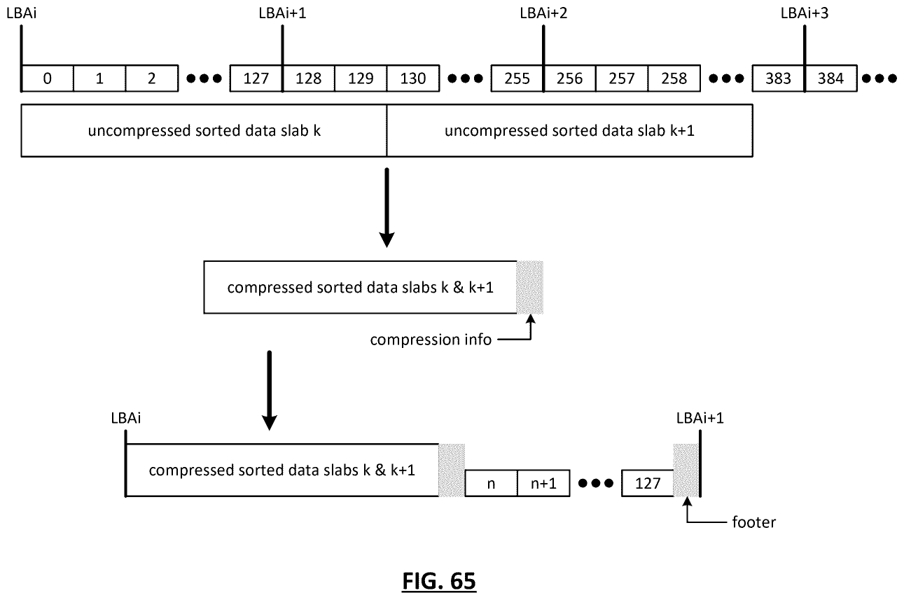

FIG. 65 is a schematic block diagram of an example of compressing data where two (or more) uncompressed sorted data slabs are compressed into one compressed data “section”. In the example the compressed sorted data slabs k and k+1 occupy one data section with other compressed data in the remaining 128 positions of LBAi.

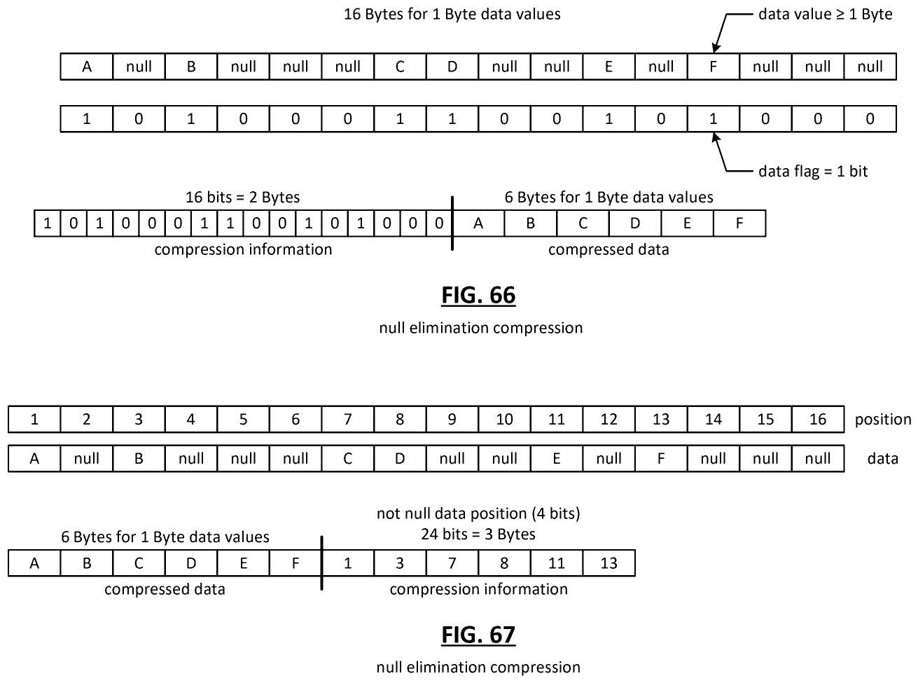

FIG. 66 is a schematic block diagram of an example of compressing data using null elimination. In the example a series of data values includes null values interspersed between not-null data values. In an example each data value is one (1) byte of a 16 byte section of data that includes data values A-F, along with 10 null values. In an example each not-null data value is assigned a data flag of “1” and each null value is assigned a “0” data flag. Compression information in this example is used to eliminate null values by including only not-null data values in the compressed data.

FIG. 67 is a schematic block diagram of another example of compressing data using null elimination. In an example data values in positions 1-16 are compressed to the data containing data values A-F, and the compression information is appended, where the compression indicates which positions of the 16-byte data sections include not-null data. Accordingly, decompression may be achieved by providing null values in each data value of the 16-byte data section with the indicated not-null data values in indicated positions (without including the “0” data flag of FIG. 66).

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provide an industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

While transistors may be shown in one or more of the above-described figure(s) as field effect transistors (FETs), as one of ordinary skill in the art will appreciate, the transistors may be implemented using any type of transistor structure including, but not limited to, bipolar, metal oxide semiconductor field effect transistors (MOSFET), N-well transistors, P-well transistors, enhancement mode, depletion mode, and zero voltage threshold (VT) transistors.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, a quantum register or other quantum memory and/or any other device that stores data in a non-transitory manner. Furthermore, the memory device may be in a form of a solid-state memory, a hard drive memory or other disk storage, cloud memory, thumb drive, server memory, computing device memory, and/or other non-transitory medium for storing data. The storage of data includes temporary storage (i.e., data is lost when power is removed from the memory element) and/or persistent storage (i.e., data is retained when power is removed from the memory element). As used herein, a transitory medium shall mean one or more of: (a) a wired or wireless medium for the transportation of data as a signal from one computing device to another computing device for temporary storage or persistent storage: (b) a wired or wireless medium for the transportation of data as a signal within a computing device from one element of the computing device to another element of the computing device for temporary storage or persistent storage: (c) a wired or wireless medium for the transportation of data as a signal from one computing device to another computing device for processing the data by the other computing device: and (d) a wired or wireless medium for the transportation of data as a signal within a computing device from one element of the computing device to another element of the computing device for processing the data by the other element of the computing device. As may be used herein, a non-transitory computer readable memory is substantially equivalent to a computer readable memory. A non-transitory computer readable memory can also be referred to as a non-transitory computer readable storage medium.

As applicable, one or more functions associated with the methods and/or processes described herein can be implemented via a processing module that operates via the non-human “artificial” intelligence (AI) of a machine. Examples of such AI include machines that operate via anomaly detection techniques, decision trees, association rules, expert systems and other knowledge-based systems, computer vision models, artificial neural networks, convolutional neural networks, support vector machines (SVMs), Bayesian networks, genetic algorithms, feature learning, sparse dictionary learning, preference learning, deep learning and other machine learning techniques that are trained using training data via unsupervised, semi-supervised, supervised and/or reinforcement learning, and/or other AI. The human mind is not equipped to perform such AI techniques, not only due to the complexity of these techniques, but also due to the fact that artificial intelligence, by its very definition-requires “artificial” intelligence—i.e., machine/non-human intelligence.

As applicable, one or more functions associated with the methods and/or processes described herein can be implemented as a large-scale system that is operable to receive, transmit and/or process data on a large-scale. As used herein, a large-scale refers to a large number of data, such as one or more kilobytes, megabytes, gigabytes, terabytes or more of data that are received, transmitted and/or processed. Such receiving, transmitting and/or processing of data cannot practically be performed by the human mind on a large-scale within a reasonable period of time, such as within a second, a millisecond, microsecond, a real-time basis or other high speed required by the machines that generate the data, receive the data, convey the data, store the data and/or use the data.

As applicable, one or more functions associated with the methods and/or processes described herein can require data to be manipulated in different ways within overlapping time spans. The human mind is not equipped to perform such different data manipulations independently, contemporaneously, in parallel, and/or on a coordinated basis within a reasonable period of time, such as within a second, a millisecond, microsecond, a real-time basis or other high speed required by the machines that generate the data, receive the data, convey the data, store the data and/or use the data.

As applicable, one or more functions associated with the methods and/or processes described herein can be implemented in a system that is operable to electronically receive digital data via a wired or wireless communication network and/or to electronically transmit digital data via a wired or wireless communication network. Such receiving and transmitting cannot practically be performed by the human mind because the human mind is not equipped to electronically transmit or receive digital data, let alone to transmit and receive digital data via a wired or wireless communication network.

As applicable, one or more functions associated with the methods and/or processes described herein can be implemented in a system that is operable to electronically store digital data in a memory device. Such storage cannot practically be performed by the human mind because the human mind is not equipped to electronically store digital data.

The preceding technical discussion may include a discussion regarding one or more of: an advantage(s) of a solution(s) to a problem(s), a benefit(s) of a solution(s) to a problem(s), an issue(s) giving rise to a problem(s), a market need(s) for a solution(s) to a problem(s), a value proposition(s) of a solution(s) to a problem(s), and/or the like. As may be applicable, the determining of an advantage(s) of a solution(s) to a problem(s), the determination of a benefit(s) of a solution(s) to a problem(s), the determination of an issue(s) giving rise to a problem(s), the determination of a market need(s) for solving a problem(s), the determination of a value proposition(s) for solving a problem(s), and/or the like can be deemed as one or more discoveries that constitute an invention and/or constitute part of an inventive step to create an invention.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A parallelized data input sub-system of a database system, wherein the parallelized data input sub-system comprises:
pluralities of computing nodes of a plurality of computing device clusters, wherein a computing device cluster of the plurality of computing device clusters includes a plurality of computing devices, wherein a computing device of the plurality of computing devices includes a plurality of computing nodes of the pluralities of computing nodes, wherein the pluralities of computing nodes includes a first set of loader nodes, wherein the first set of loader nodes is operable to ingest at least a portion of a dataset, and wherein the first set of loader nodes includes:
a plurality of memory devices, wherein a set of memory devices of the plurality of memory devices is operable to temporarily store the at least the portion of the dataset in a raw data format; and
a plurality of processing modules, wherein a set of processing modules of the plurality of processing modules is operable to:
determine whether the at least the portion of the dataset is regarding a database query;
when the at least the portion of the dataset is regarding the database query:
provide the at least the portion of the dataset to a query and response sub-system of the database system; and
when the at least the portion of the dataset is not regarding the database query:
determine long term storage parameters for the at least the portion of the dataset;
process the at least the portion of the dataset in accordance with the long term storage parameters to produce long term storage formatted data; and
provide the long term storage formatted data to a plurality of storage computing nodes of pluralities of storage computing nodes of a store and compute sub-system of the database system for storage therein.

2. The parallelized data input sub-system of claim 1, wherein the first set of loader nodes comprises a set of batch data loader nodes, wherein the at least the portion of the dataset is a full dataset, and wherein the set of batch data loader nodes is operable to:
ingest the full dataset; and
wherein the set of processing modules is further operable to:
provide the full dataset to the set of memory devices.

3. The parallelized data input sub-system of claim 1, wherein the first set of loader nodes comprises a set of streaming data loader nodes, wherein the at least the portion of the dataset is a portion of a full dataset, and wherein the set of streaming data loader nodes is operable to:
ingest the portion of the full dataset; and
wherein the set of processing modules is further operable to:
provide the portion of the full dataset to the set of memory devices.

4. The parallelized data input sub-system of claim 1, wherein the set of processing modules is further operable to:
convert the at least the portion of the dataset from an initial raw data format to the raw data format based on a raw data format preference; and
provide the at least the portion of the dataset in the raw data format to the set of memory devices.

5. The parallelized data input sub-system of claim 1, wherein the long term storage parameters comprises one or more of:
a partitioning scheme;
a data encoding scheme;
a data sorting scheme; and
a data compression scheme.

6. The parallelized data input sub-system of claim 1, wherein the set of processing modules is operable to:
determine database system parameters; and
generate the long term storage parameters based on the database system parameters and the at least the portion of the dataset.

7. The parallelized data input sub-system of claim 1, wherein the set of processing modules is operable to provide the long term storage formatted data to the store and compute sub-system by:
providing a segment group of a partition of a plurality of partitions of the long term storage formatted data to a first computing device of a first computing device cluster of a plurality of computing device clusters of the store and compute sub-system, wherein the first computing device includes a plurality of storage computing nodes, and wherein a first segment of the segment group is provided to a first storage computing node of the plurality of storage computing nodes.

8. The parallelized data input sub-system of claim 1 further comprises:
wherein the first set of loader nodes is further operable to:
ingest a second portion of the dataset;
wherein the set of memory devices is further operable to:
temporarily store the second portion of the dataset in the raw data format; and
wherein the set of processing modules is further operable to:
determine whether the second portion of the dataset is regarding a current database query;
when the second portion of the dataset is regarding the current database query:
provide the second portion of the dataset to the query and response sub-system; and
when the second portion of the dataset is not regarding the current database query:
determine second long term storage parameters for the second portion of the dataset;
process the second portion of the dataset in accordance with the second long term storage parameters to produce second long term storage formatted data; and
provide the second long term storage formatted data to the store and compute sub-system of the database system for storage therein.

9. The parallelized data input sub-system of claim 1 further comprises:
wherein the first set of loader nodes is further operable to:
ingest at least a portion of a second dataset;
wherein the set of memory devices is further operable to:
temporarily store the at least the portion of the second dataset in a second raw data format; and
wherein the set of processing modules is further operable to:
determine whether the at least the portion of the second dataset is regarding a current database query;
when the at least the portion of the second dataset is regarding the current database query:
provide the at least the portion of the second dataset to the query and response sub-system; and
when the at least the portion of the second dataset is not regarding the current database query:
determine second long term storage parameters for the at least the portion of the second dataset;
process the at least the portion of the second dataset in accordance with the second long term storage parameters to produce second long term storage formatted data; and
provide the second long term storage formatted data to the store and compute sub-system of the database system for storage therein.

10. The parallelized data input sub-system of claim 1 further comprises:
wherein the pluralities of computing nodes includes a second set of loader nodes, wherein the second set of loader nodes is operable to ingest at least a portion of a second dataset, and wherein the second set of loader nodes includes:
a second plurality of memory devices, wherein a second set of memory devices of the second plurality of memory devices is operable to temporarily store the at least the portion of the second dataset in a second raw data format; and
a second plurality of processing modules, wherein a second set of processing modules of the second plurality of processing modules is operable to:
determine whether the at least the portion of the second dataset is regarding a current database query;
when the at least the at least the portion of the second dataset is regarding the current database query:
provide the at least the portion of the second dataset to the query and response sub-system; and
when the at least the portion of the second dataset is not regarding the current database query:
determine second long term storage parameters for the at least the portion of the second dataset;
process the at least the portion of the second dataset in accordance with the second long term storage parameters to produce second long term storage formatted data; and
provide the second long term storage formatted data to the store and compute sub-system of the database system for storage therein.

11. A computer readable storage medium comprises:
a first memory section that stores operational instructions that when executed by a first set of loader nodes of pluralities of computing nodes of pluralities of computing devices of a plurality of computing device clusters of a parallelized data input sub-system of a database system, cause the first set of loader nodes to:
ingest at least a portion of a dataset;
a second memory section that stores operational instructions that when executed by a set of memory devices of a plurality of memory devices of the first set of loader nodes, cause the set of memory devices to:
temporarily store the at least the portion of the dataset in a raw data format; and
a third memory section that stores operational instructions that when executed by a set of processing modules of a plurality of processing modules of the first set of loader nodes, cause the set of processing modules to:
determine whether the at least the portion of the dataset is regarding a database query;
when the at least the portion of the dataset is regarding the database query:
provide the at least the portion of the dataset to a query and response sub-system of the database system; and
when the at least the portion of the dataset is not regarding the database query:
determine long term storage parameters for the at least the portion of the dataset;
process the at least the portion of the dataset in accordance with the long term storage parameters to produce long term storage formatted data; and
provide the long term storage formatted data to a plurality of storage computing nodes of pluralities of storage computing nodes of a store and compute sub-system of the database system for storage therein.

12. The computer readable storage medium of claim 11 further comprises
a fourth memory section that stores operational instructions that when executed by a set of batch data loader nodes as the first set of loader nodes, cause the set of batch data loader nodes to:
ingest the at least the portion of the dataset, wherein the at least the portion of the dataset is a full dataset; and
the third memory section further stores operational instructions that when executed by the set of processing modules, cause the set of processing modules to:
provide the full dataset to the set of memory devices.

13. The computer readable storage medium of claim 11 further comprises:
a fourth memory section that stores operational instructions that when executed by a set of streaming data loader nodes as the first set of loader nodes, cause the set of streaming data loader nodes to:
wherein the at least the portion of the dataset, wherein the at least the portion of the dataset is a portion of a full dataset,
the third memory section further stores operational instructions that when executed by the set of processing modules, cause the set of processing modules to:
provide the portion of the full dataset to the set of memory devices.

14. The computer readable storage medium of claim 11, wherein the third memory section further stores operational instructions that when executed by the set of processing modules, cause the set of processing modules to:
convert the at least the portion of the dataset from an initial raw data format to the raw data format based on a raw data format preference; and
provide the at least the portion of the dataset in the raw data format to the set of memory devices.

15. The computer readable storage medium of claim 11, wherein the long term storage parameters comprises one or more of:
a partitioning scheme;
a data encoding scheme;
a data sorting scheme; and
a data compression scheme.

16. The computer readable storage medium of claim 11, wherein the third memory section further stores operational instructions that when executed by the set of processing modules, cause the set of processing modules to:
determine database system parameters; and
generate the long term storage parameters based on the database system parameters and the at least the portion of the dataset.

17. The computer readable storage medium of claim 11, wherein the third memory section further stores operational instructions that, when executed by the set of processing modules, cause the set of processing modules to provide the long term storage formatted data to the store and compute sub-system by:
providing a segment group of a partition of a plurality of partitions of the long term storage formatted data to a first computing device of a first computing device cluster of a plurality of computing device clusters of the store and compute sub-system, wherein the first computing device includes a plurality of storage computing nodes, and wherein a first segment of the segment group is provided to a first storage computing node of the plurality of storage computing nodes.

18. The computer readable storage medium of claim 11 further comprises:
wherein the first memory section further stores operational instructions that when executed by the first set of loader nodes, cause the first set of loader nodes to:
ingest a second portion of the dataset;
wherein the second memory section further stores operational instructions that when executed by the set of memory devices, cause the set of memory devices to:
temporarily store the second portion of the dataset in the raw data format; and
wherein the third memory section further stores operational instructions that, when executed by the set of processing modules, cause the set of processing modules to:
determine whether the second portion of the dataset is regarding a current database query;
when the second portion of the dataset is regarding the current database query:
provide the second portion of the dataset to the query and response sub-system; and
when the second portion of the dataset is not regarding the current database query:
determine second long term storage parameters for the second portion of the dataset;
process the second portion of the dataset in accordance with the second long term storage parameters to produce second long term storage formatted data; and
provide the second long term storage formatted data to the store and compute sub-system of the database system for storage therein.

19. The computer readable storage medium of claim 11 further comprises:
wherein the first memory section further stores operational instructions that when executed by the first set of loader nodes, cause the first set of loader nodes to:
ingest at least a portion of a second dataset;
wherein the second memory section further stores operational instructions that when executed by the set of memory devices, cause the set of memory devices to:
temporarily store the at least the portion of the second dataset in a second raw data format; and
wherein the third memory section further stores operational instructions that, when executed by the set of processing modules, cause the set of processing modules to:
determine whether the at least the portion of the second dataset is regarding a current database query;
when the at least the portion of the second dataset is regarding the current database query:
provide the at least the portion of the second dataset to the query and response sub-system; and
when the at least the portion of the second dataset is not regarding the current database query:
determine second long term storage parameters for the at least the portion of the second dataset;
process the at least the portion of the second dataset in accordance with the second long term storage parameters to produce second long term storage formatted data; and
provide the second long term storage formatted data to the store and compute sub-system of the database system for storage therein.

20. The computer readable storage medium of claim 11 further comprises:
a fourth memory section that stores operational instructions that when executed by a second set of loader nodes of the pluralities of computing nodes, cause the second set of loader nodes to:
ingest at least a portion of a second dataset;
a fifth memory section that stores operational instructions that when executed by a second set of memory devices of a second plurality of memory devices of the second set of loader nodes, cause the second set of memory devices to:
temporarily store the at least the portion of the second dataset in a second raw data format; and
a sixth memory section that stores operational instructions that when executed by a second set of processing modules of a second plurality of processing modules of the second set of loader nodes, cause the second set of processing modules to:
determine whether the at least the portion of the second dataset is regarding a current database query;
when the at least the at least the portion of the second dataset is regarding the current database query:
provide the at least the portion of the second dataset to the query and response sub-system; and
when the at least the portion of the second dataset is not regarding the current database query:
determine second long term storage parameters for the at least the portion of the second dataset;
process the at least the portion of the second dataset in accordance with the second long term storage parameters to produce second long term storage formatted data; and
provide the second long term storage formatted data to the store and compute sub-system of the database system for storage therein.
